(19) United States
(12) Patent Application Publication
(10) Pub. No.: US 2017/0047437 A1
(43) Pub. Date: Feb. 16, 2017

(54) SEMICONDUCTOR DEVICE AND A MANUFACTURING METHOD THEREOF

(71) Applicant: Renesas Electronics Corporation, Tokyo (JP)

(72) Inventors: Tatsuo NAKAYAMA, Ibaraki (JP); Hironobu MIYAMOTO, Ibaraki (JP); Ichiro MASUMOTO, Ibaraki (JP); Shinichi MIYAKE, Ibaraki (JP); Hiroshi KAWAGUCHI, Ibaraki (JP)

(73) Assignee: Renesas Electronics Corporation, Tokyo (JP)

(21) Appl. No.: 15/216,817

(22) Filed: Jul. 22, 2016

(30) Foreign Application Priority Data
Aug. 11, 2015 (JP) 2015-158812

(51) Int. Cl. H01L 29/778; H01L 29/205; H01L 29/06; H01L 29/66; H01L 29/808; H01L 21/02; H01L 21/324; H01L 29/20; H01L 29/423

(52) U.S. Cl. CPC H01L 29/7783; H01L 29/2003; H01L 29/205; H01L 29/0649; H01L 29/4236; H01L 29/808; H01L 21/0254; H01L 21/3245; H01L 21/0217; H01L 29/66462; H01L 29/66924

(57) ABSTRACT

The characteristics of a semiconductor device are improved. A semiconductor device has an impurity-containing potential fixed layer, and a gate electrode. A drain electrode and a source electrode are formed on the opposite sides of the gate electrode. An interlayer insulation film is formed between the gate electrode and the drain electrode, and between the gate electrode and the source electrode. The concentration of the inactivating element in the portion of the potential fixed layer under the drain electrode is higher than the concentration of the inactivating element in the portion of the potential fixed layer under the source electrode. The film thickness of the portion of the interlayer insulation film between the gate electrode and the drain electrode is different from the film thickness of the portion of the interlayer insulation film between the gate electrode and the source electrode.

### CROSS-REFERENCE TO RELATED APPLICATIONS

The disclosure of Japanese Patent Application No. 2015-158812 filed on Aug. 11, 2015 including the specification, drawings and abstract is incorporated herein by reference in its entirety.

### BACKGROUND

The present invention relates to a semiconductor device, and is preferably applicable to, for example, a semiconductor device using a nitride semiconductor.

In recent years, attention has been paid to semiconductor devices each using a III-V group compound having a larger bandgap than that of silicon (Si). Among them, a MISFET (Metal Insulator Semiconductor Field Effect Transistor) using gallium nitride (GaN) has advantages such as 1) large breakdown electric field, 2) large saturated electron velocity, 3) large thermal conductivity, 4) being able to form a favorable hetero junction between AlGaN and GaN, and 5) being a nontoxic and high-safety material.

For example, in Patent Document 1 (Japanese Unexamined Patent Application Publication No. 2010-109086), there is disclosed a nitride semiconductor element in which a p-GaN layer is arranged under a channel layer formed of an undoped GaN layer. Then, the p-GaN layer is electrically coupled with a source electrode, thereby to achieve a high avalanche resistance and high reliability.

### PATENT DOCUMENT

### [Patent Document 1]

### Japanese Unexamined Patent Application Publication No. 2010-109086

### SUMMARY

The present inventors have been involved in research and development of the semiconductor devices using a nitride semiconductor as described above, and have conducted a close study on the improvement of the characteristics. During the process thereof, it has been proved that there is room for further improvement of the characteristics of the semiconductor device using a nitride semiconductor.

Other objects and novel features will be apparent from the description of this specification and the accompanying drawings.

Summaries of the representative ones of the embodiments disclosed in the present application will be described in brief as follows.

A semiconductor device shown in one embodiment disclosed in the present application has a potential fixed layer containing an impurity, and a gate electrode. A drain electrode and a source electrode are formed on the opposite sides of the gate electrode, respectively. An insulation film is formed between the gate electrode and the drain electrode, and between the gate electrode and the source electrode. The potential fixed layer has an inactivated region containing an inactivating element on the drain side with respect to the gate electrode. The concentration of the inactivating element in the portion of the potential fixed layer under the drain electrode is higher than the concentration of the inactivating element in the portion of the potential fixed layer under the source electrode. Further, the film thickness of the portion of the insulation film between the gate electrode and the drain electrode is different from the film thickness of the portion of the insulation film between the gate electrode and the source electrode.

A method for manufacturing a semiconductor device shown in one embodiment disclosed in the present application has a step of forming a potential fixed layer containing an impurity, and a gate electrode. Then, the method for manufacturing a semiconductor device has a step of forming a first insulation film containing an inactivating element on the opposite sides with respect to the gate electrode, performing a heat treatment with the first side with respect to the gate electrode covered with the second insulation film, and doping the inactivating element contained in the first insulation film into the potential fixed layer on the first side with respect to the gate electrode. Further, the method for manufacturing a semiconductor device has a step of forming a drain electrode over the potential fixed layer on the first side of the gate electrode, and forming a source electrode over the potential fixed layer opposite to the first side of the gate electrode.

A method for manufacturing a semiconductor device shown in another embodiment disclosed in the present application has a step for forming a potential fixed layer containing an impurity, and a gate electrode. Further, the method for manufacturing a semiconductor device has a step of performing a heat treatment in the following state: a second insulation film containing an inactivating element is formed on a first side with respect to the gate electrode via a first insulation film; and the second insulation film is formed on the side opposite to the first side with respect to the gate electrode not via the first insulation film. In the step of performing a heat treatment, the inactivating element contained in the first insulation film is doped into the potential fixed layer on the first side with respect to the gate electrode. Further, the method for manufacturing a semiconductor device has a step of forming a drain electrode over the potential fixed layer on the first side of the gate electrode, and forming a source electrode over the potential fixed layer on the opposite side of the gate electrode to the first side.

In accordance with a semiconductor device shown in the following representative embodiments disclosed in the present application, it is possible to improve the characteristics of the semiconductor device.

In accordance with a method for manufacturing a semiconductor device shown in the following representative embodiments disclosed in the present application, it is possible to manufacture a semiconductor device having favorable characteristics.

### BRIEF DESCRIPTION OF THE DRAWINGS

FIG. 1 is a cross sectional view schematically showing a configuration of a semiconductor device of First Embodiment;

FIG. 2 is a plan view showing a configuration of the semiconductor device of First Embodiment;

FIG. 3 is a cross sectional view showing a configuration of the semiconductor device of First Embodiment;

FIG. 4 is a cross sectional view showing a configuration of the semiconductor device of First Embodiment;

FIG. 5 is a cross sectional view showing the semiconductor device of First Embodiment during a manufacturing step;

FIG. 6 is a cross sectional view showing the semiconductor device of First Embodiment during a manufacturing step;

FIG. 7 is a cross sectional view showing the semiconductor device of First Embodiment during a manufacturing step;

FIG. 8 is a plan view showing the semiconductor device of First Embodiment during a manufacturing step;

FIG. 9 is a cross sectional view showing the semiconductor device of First Embodiment during a manufacturing step;

FIG. 10 is a cross sectional view showing the semiconductor device of First Embodiment during a manufacturing step;

FIG. 11 is a plan view showing the semiconductor device of First Embodiment during a manufacturing step;

FIG. 12 is a cross sectional view showing the semiconductor device of First Embodiment during a manufacturing step;

FIG. 13 is a cross sectional view showing the semiconductor device of First Embodiment during a manufacturing step;

FIG. 14 is a plan view showing the semiconductor device of First Embodiment during a manufacturing step;

FIG. 15 is a cross sectional view showing the semiconductor device of First Embodiment during a manufacturing step;

FIG. 16 is a cross sectional view showing the semiconductor device of First Embodiment during a manufacturing step;

FIG. 17 is a plan view showing the semiconductor device of First Embodiment during a manufacturing step;

FIG. 18 is a cross sectional view showing the semiconductor device of First Embodiment during a manufacturing step;

FIG. 19 is a cross sectional view showing the semiconductor device of First Embodiment during a manufacturing step;

FIG. 20 is a cross sectional view showing the semiconductor device of First Embodiment during a manufacturing step;

FIG. 21 is a cross sectional view showing the semiconductor device of First Embodiment during a manufacturing step;

FIG. 22 is a plan view showing the semiconductor device of First Embodiment during a manufacturing step;

FIG. 23 is a cross sectional view showing the semiconductor device of First Embodiment during a manufacturing step;

FIG. 24 is a cross sectional view showing the semiconductor device of First Embodiment during a manufacturing step;

FIG. 25 is a graph showing the current voltage characteristics between the drain electrode and the source electrode in the semiconductor device of First Embodiment;

FIG. 26 is a cross sectional view schematically showing a configuration of a semiconductor device of Modified Example of First Embodiment;

FIG. 27 is a cross sectional view schematically showing a configuration of a semiconductor device of Second Embodiment;

FIG. 28 is a cross sectional view showing a configuration of a semiconductor device of Applied Example 2 of First Embodiment;

FIG. 29 is a cross sectional view showing a configuration of the semiconductor device of Second Embodiment;

FIG. 30 is a cross sectional view showing the semiconductor device of Second Embodiment during a manufacturing step;

FIG. 31 is a cross sectional view showing the semiconductor device of Second Embodiment during a manufacturing step;

FIG. 32 is a cross sectional view showing the semiconductor device of Second Embodiment during a manufacturing step;

FIG. 33 is a cross sectional view showing the semiconductor device of Second Embodiment during a manufacturing step;

FIG. 34 is a plan view showing the semiconductor device of Second Embodiment during a manufacturing step;

FIG. 35 is a cross sectional view showing the semiconductor device of Second Embodiment during a manufacturing step;

FIG. 36 is a cross sectional view showing the semiconductor device of Second Embodiment during a manufacturing step;

FIG. 37 is a cross sectional view showing the semiconductor device of Second Embodiment during a manufacturing step;

FIG. 38 is a cross sectional view showing a semiconductor device of First Modified Example of Second Embodiment during a manufacturing step;

FIG. 39 is a cross sectional view schematically showing a configuration of a semiconductor device of Second Modified Example of Second Embodiment;

FIG. 40 is a cross sectional view showing the semiconductor device of Second Modified Example of Second Embodiment during a manufacturing step;

FIG. 41 is a cross sectional view schematically showing a configuration of a semiconductor device of Third Embodiment;

FIG. 42 is a cross sectional view showing a configuration of the semiconductor device of Third Embodiment;

FIG. 43 is a cross sectional view showing a configuration of the semiconductor device of Third Embodiment;

FIG. 44 is a cross sectional view showing the semiconductor device of Third Embodiment during a manufacturing step;

FIG. 45 is a cross sectional view showing the semiconductor device of Third Embodiment during a manufacturing step;

FIG. 46 is a cross sectional view showing the semiconductor device of Third Embodiment during a manufacturing step;

FIG. 47 is a cross sectional view showing the semiconductor device of Third Embodiment during a manufacturing step;

FIG. 48 is a cross sectional view showing the semiconductor device of Third Embodiment during a manufacturing step;

FIG. 49 is a cross sectional view schematically showing a configuration of a semiconductor device of Fourth Embodiment;

FIG. 50 is a cross sectional view schematically showing a configuration of the semiconductor device of Fourth Embodiment;

FIG. 51 is a cross sectional view showing the semiconductor device of Fourth Embodiment during a manufacturing step;

FIG. 52 is a cross sectional view showing the semiconductor device of Fourth Embodiment during a manufacturing step;

FIG. 53 is a cross sectional view schematically showing a configuration of a semiconductor device of Fifth Embodiment;

FIG. 54 is a cross sectional view showing a configuration of of the semiconductor device of Fifth Embodiment;

FIG. 55 is a cross sectional view showing another configuration of the semiconductor device of Fifth Embodiment;

FIG. 56 is a cross sectional view showing a still other configuration of the semiconductor device of Fifth Embodiment; and

FIG. 57 is a cross sectional view showing a further configuration of the semiconductor device of Fifth Embodiment.

### DETAILED DESCRIPTION

In description of the following embodiment, the embodiment may be described in a plurality of divided sections or embodiments for convenience, if required. However, unless otherwise specified, these are not independent of each other, but are in a relation such that one is a modification example, an applied example, a detailed description, complementary explanation, or the like of a part or the whole of the other. Further, in the following embodiments, when a reference is made to the number of elements, and the like (including number, numerical value, quantity, range, or the like), the number of elements is not limited to the specific number, but may be greater than or less than the specific number, unless otherwise specified, except for the case where the number is apparently limited to the specific number in principle, or except for other cases.

Further, in the following embodiments, the constitutional elements (including element steps, or the like) are not always essential, unless otherwise specified, except for the case where they are apparently considered essential in principle, or except for other cases. Similarly, in the following embodiments, when a reference is made to the shapes, positional relationships, or the like of the constitutional elements, or the like, it is assumed that they include ones substantially analogous or similar to the shapes or the like, unless otherwise specified, unless otherwise considered apparently in principle, or except for other cases. This also applies to the foregoing numbers and the like (including numbers, numerical values, ranges, and the like).

Below, embodiments will be described in details by reference to the accompanying drawings. Incidentally, in all the drawings for describing the following embodiments, the members having the same function are given the same or related reference signs and numerals, and a repeated description thereon is omitted. Further, when a plurality of similar members (portions) are present, a sign may be added to a generic reference numeral to denote an individual or specific portion. Further, in the following embodiments, unless particularly necessary, the same or similar portions will not be repeatedly described.

Further, in the accompanying drawings used in embodiments, hatching may be omitted even in a cross sectional view for ease of understanding of the drawings. Whereas, hatching may be added even in a plan view for ease of understanding of the drawings.

Further, in a cross sectional view and a plan view, the dimensions of each part are not intended to correspond to those of an actual device. For ease of understanding of the drawing, a specific part may be shown on a relatively larger scale. Further, also when a cross sectional view and a plan view correspond to each other, for ease of understanding of the drawings, a specific part may be shown on a relatively larger scale.

### First Embodiment

Below, with reference to the accompanying drawings, a semiconductor device of the present embodiment will be described in details.

[Structure Description]

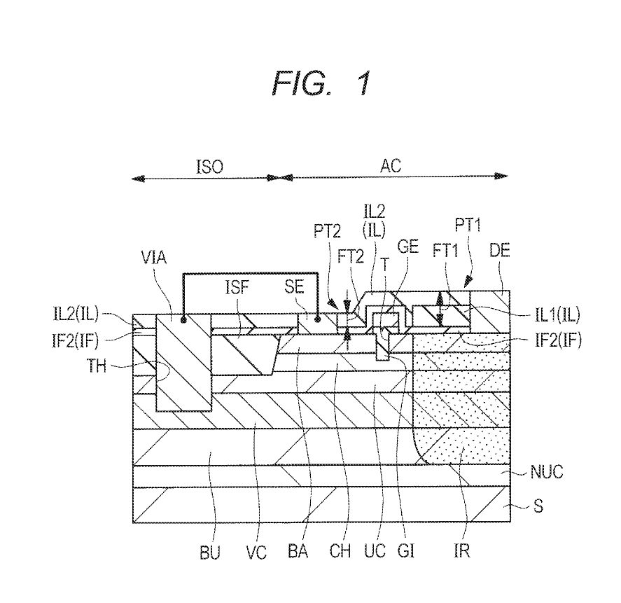

FIG. 1 is a cross sectional view schematically showing a configuration of a semiconductor device of First Embodiment.

The semiconductor device (semiconductor element) of the present First Embodiment is a MIS (Metal Insulator Semiconductor) type FET; Field Effect Transistor, namely, a MISFET using a nitride semiconductor. The semiconductor device of the present First Embodiment is a so-called recess gate type semiconductor device.

The semiconductor device of the present First Embodiment has a substrate S. A nucleation layer NUC, a buffer layer BU, a potential fixed layer VC, a channel base layer UC, a channel layer (also referred to as an electron running layer) CH, and a barrier layer BA are sequentially formed over the substrate S.

The nucleation layer NUC is formed of a nitride semiconductor layer. The buffer layer BU is formed of a singlelayered or multilayered nitride semiconductor layer doped with an impurity for forming a deep level in a nitride semiconductor. Herein, a superlattice structure (also referred to as a superlattice layer) formed of a multilayered nitride semiconductor layer is used. The potential fixed layer VC is formed of a nitride semiconductor layer obtained by doping a p type impurity into a nitride semiconductor, and has a conductivity. The channel base layer UC is formed of a nitride semiconductor layer smaller in electron affinity than the channel layer CH. The channel layer CH is formed of a nitride semiconductor layer larger in electron affinity than the channel base layer UC. The barrier layer BA is formed of a nitride semiconductor layer smaller in electron affinity than the channel layer CH, and smaller in electron affinity than the channel base layer UC.

An insulation film IF is formed over the barrier layer BA, and an interlayer insulation film IL is formed over the insulation film IF. Incidentally, a cap layer may be provided between the insulation film IF and the barrier layer BA. The cap layer is formed of a nitride semiconductor layer larger in electron affinity than the barrier layer BA.

The semiconductor device of the present First Embodiment has a gate electrode GE formed over the barrier layer BA via a gate insulation film GI, and a source electrode SE and a drain electrode DE formed over the barrier layer BA on the opposite sides of the gate electrode GE. The drain electrode DE is arranged on a first side with respect to the gate electrode in a plan view, and the source electrode SE is arranged on the side opposite to the first side with respect to the gate electrode GE in a plan view. Incidentally, the wording “in a plan view” means the case of the view from the direction perpendicular to the top surface as the main surface of the substrate S.

Further, the substrate S includes an active region AC provided on the top surface side of the substrate S, and an element isolation region ISO provided on the top surface side of the substrate S. The active region AC is defined by element isolation regions ISO. The gate electrode GE, the drain electrode DE, and the source electrode SE are formed in the active region AC. In the active region AC, a trench T is formed as a trench part penetrating through the barrier layer BA, and reaching some point of the channel layer CH. A gate insulation film GI is formed at the inner wall of the trench T. The gate electrode GE is formed over the gate insulation film GI. The gate electrode GE, the gate insulation film GI, the drain electrode DE, and the source electrode SE, and the barrier layer BA and the channel layer CH form a MISFET.

A two-dimensional electron gas is generated on the channel layer CH side in the vicinity of the interface between the channel layer CH and the barrier layer BA. Whereas, when the gate electrode GE is applied with a positive potential (threshold potential), a channel is formed in the vicinity of the interface between the gate insulation film GI and the channel layer CH.

The two-dimensional electron gas is generated by the following mechanism. The nitride semiconductor layers (herein, gallium nitride type semiconductor layers) forming the channel layer CH or the barrier layer BA respectively have different electron affinities (forbidden band widths (bandgaps)). The barrier layer BA is formed of a nitride semiconductor layer smaller in electron affinity than the channel layer CH. For this reason, a well type potential is formed at the junction surface of the semiconductor layers. The accumulation of electrons in the well type potential generates the two-dimensional electron gas in the vicinity of the interface between the channel layer CH and the barrier layer BA. Particularly, herein, the channel layer CH and the barrier layer BA are formed by epitaxial growth with a gallium (or aluminum) plane grown nitride semiconductor material. For this reason, positive fixed polarization charges are generated at the interface between the channel layer CH and the barrier layer BA. Thus, electrons are accumulated in order to neutralize the positive polarization charges. Accordingly, the two-dimensional electron gas becomes more likely to be formed.

Then, the two-dimensional electron gas formed in the vicinity of the interface between the channel layer CH and the barrier layer BA is divided by the trench T including the gate electrode GE formed thereover. For this reason, in the semiconductor device of the present First Embodiment, with the gate electrode GE not applied with a positive potential (threshold potential), the OFF state can be kept; and with the gate electrode GE applied with a positive potential (threshold potential), the ON state can be kept. Namely, in the semiconductor device of First Embodiment, the normally off operation can be performed. Incidentally, in the ON state and the OFF state, the potential of the source electrode SE is, for example, the ground potential.

Further, the channel layer CH is interposed between the barrier layer BA and the channel base layer UC smaller in electron affinity than the channel layer CH, resulting in an improvement of the electron confining effect. This enables the suppression of the short channel effect, the amplification factor improvement, or the improvement of the operation speed. Further, when the channel base layer UC undergoes a tensile strain, to be strained, negative charges due to the piezo polarization and the spontaneous polarization are induced at the interface between the channel base layer UC and the channel layer CH. Accordingly, the threshold potential moves to the positive side. This can improve the normally off operation property. Whereas, when the strain of the channel base layer UC is relaxed, negative charges due to the spontaneous polarization are induced at the interface between the channel base layer UC and the channel layer CH. Accordingly, the threshold potential moves to the positive side. This can improve the normally off operation property.

In the element isolation region ISO, an element isolation ISF as an element isolation part is formed in the barrier layer BA, in the channel layer CH, and in the channel base layer UC, and a through hole TH is formed as a trench part penetrating through the element isolation ISF and the channel base layer UC, and reaching the potential fixed layer VC. A coupling part (also referred to as a via) VIA is formed in the through hole TH.

Namely, in the element isolation region ISO, the coupling part VIA is provided as an electrode penetrating through the element isolation ISF, and reaching the underlying potential fixed layer VC. The coupling part VIA is electrically coupled with the source electrode SE. Further, the coupling part VIA is in contact with the potential fixed layer VC. Thus, the potential fixed layer VC is provided, and is coupled with the source electrode SE. As a result, it is possible to reduce the variations in characteristics such as threshold potential or ON resistance.

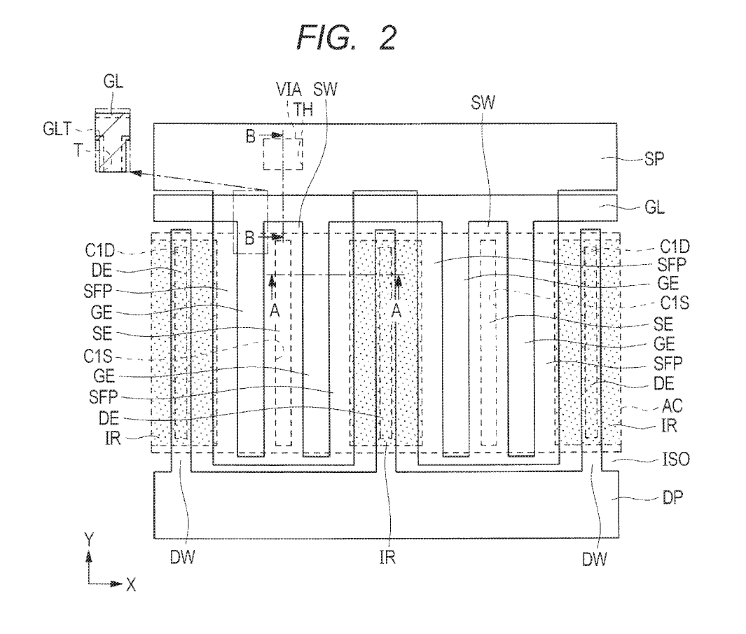

Further, in the present First Embodiment, the coupling part VIA in the through hole TH is arranged in the element isolation region ISO outside the active region AC in which electrons are conducted, and under the source pad SP (see FIG. 2 described later). As a result, it is possible to implement miniaturization or high integration of semiconductor elements. Further, it is possible to ensure a large active region AC in which electrons can be conducted. For this reason, it is possible to reduce the ON resistance per unit area.

Further, in the present First Embodiment, an inactivated region IR is provided under the drain electrode DE, and between the gate electrode GE and the drain electrode DE. The inactivated region IR reaches the potential fixed layer VC in the depth direction. Provision of such an inactivated region IR can improve the breakdown voltage between the drain electrode DE and the source electrode SE, namely, the drain breakdown voltage. Incidentally, an inactivating element means an element for inactivating a p type impurity.

The portion of the potential fixed layer VC under the drain electrode DE, and the portion of the potential fixed layer VC between the gate electrode GE and the drain electrode DE are doped with an inactivating element, and contain the doped inactivating element. For example, the content of the inactivating element in the portion of the potential fixed layer VC under the drain electrode DE is larger than the content of the inactivating element in the portion of the potential fixed layer VC under the source electrode SE. The inactivating element is, for example, hydrogen (H) or fluorine (F).

Herein, the term “inactivation” indicates the reduction of the ratio of the density of the acceptor to the density of the p type impurity, namely, the activation ratio. The activation ratio of the inactivated region IR is smaller than, and is preferably set at 1/10 or less the activation ratio of the region other than the inactivated region IR. In other words, in the potential fixed layer VC, the activation ratio of the potential fixed layer situated under the drain electrode DE (also referred to as a drain-side potential fixed layer) VC is smaller than, and is preferably 1/10 or less the activation ratio of the potential fixed layer situated under the source electrode SE (also referred to as a source-side potential fixed layer) VC.

As described later, when a gallium nitride layer heteroepitaxially grown while being doped with magnesium (Mg) which is a p type impurity is used as the potential fixed layer VC, the p type impurity is roughly uniformly doped into the potential fixed layer VC. Then, an inactivating element such as hydrogen (H) is doped into the drain-side potential fixed layer VC. As a result, the drain-side potential fixed layer VC is inactivated. In such a case, also in the drain-side potential fixed layer VC, a Mg element which is a p type impurity is doped at a density comparable to that of the source side, but ceases to contribute as an acceptor under the influence of H which is an inactivating element. Thus, in the drain-side potential fixed layer VC, the ratio of the density of the acceptor to the density of the p type impurity is lower than that of the source side. The activation ratio can be estimated by measuring, for example, the voltage dependency of the capacitance (CV).

In the present First Embodiment, an interlayer insulation film IL is formed over the barrier layer BA between the gate electrode GE and the drain electrode DE, and between the gate electrode GE and the source electrode SE. The film thickness FT1 of the portion PT1 of the interlayer insulation film IL situated between the gate electrode GE and the drain electrode DE is larger than the film thickness FT2 of the portion PT2 of the interlayer insulation film IL situated between the gate electrode GE and the source electrode SE. Namely, the film thickness FT1 is different from the film thickness FT2.

An insulation film IF2 containing silicon, nitrogen, and hydrogen such as a silicon nitride film containing hydrogen is formed over the barrier layer BA between the gate electrode GE and the drain electrode DE, and between the gate electrode GE and the source electrode SE. Then, an insulation film IL1 which is a part of the interlayer insulation film IL is formed over the insulation film IF2. At this step, the insulation film IL1 is formed over the insulation film IF2 between the gate electrode GE and the drain electrode DE. However, between the gate electrode GE and the source electrode SE, the insulation film IL1 is not formed over the insulation film IF2. Then, after the formation of the insulation film IL1, the substrate S is heat treated. As a result, the hydrogen contained in the insulation film IF2 is doped into the potential fixed layer VC. Then, an insulation film IL2 which is a part of the interlayer insulation film IL is formed over the insulation film IF2. At this step, between the gate electrode GE and the drain electrode DE, the insulation film IL2 is formed over the insulation film IF2 via the insulation film IL1. Whereas, between the gate electrode GE and the source electrode SE, the insulation film IL2 is formed over the insulation film IF2 not via the insulation film IL1.

As a result, as compared with the case where the potential fixed layer VC is doped with an inactivating element by ion implantation, the drain-side potential fixed layer VC can be inactivated without breaking the crystals of the nitride semiconductor layers such as the barrier layer BA, the channel layer CH, and the channel base layer UC.

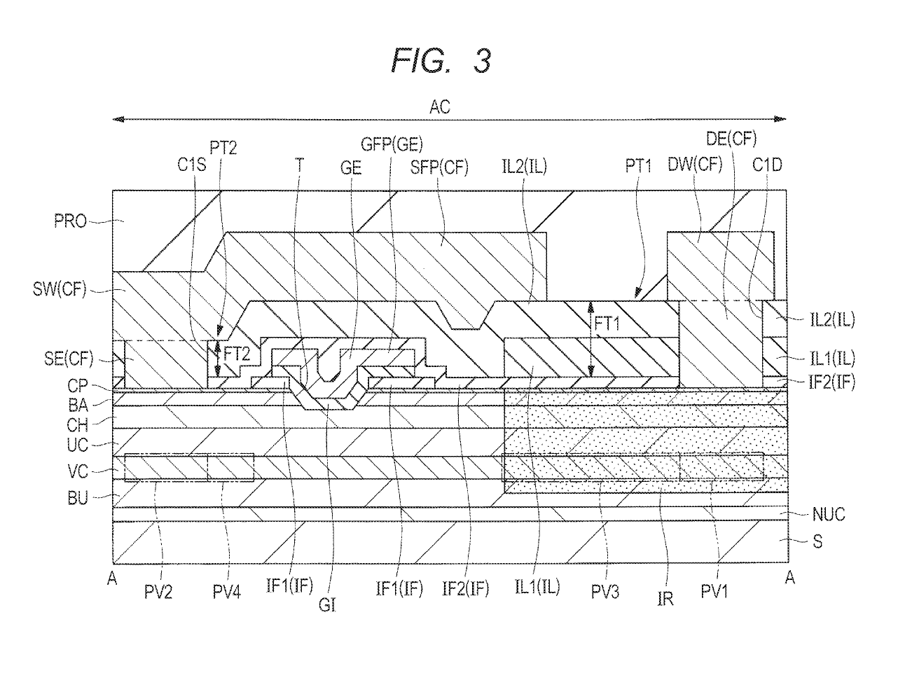

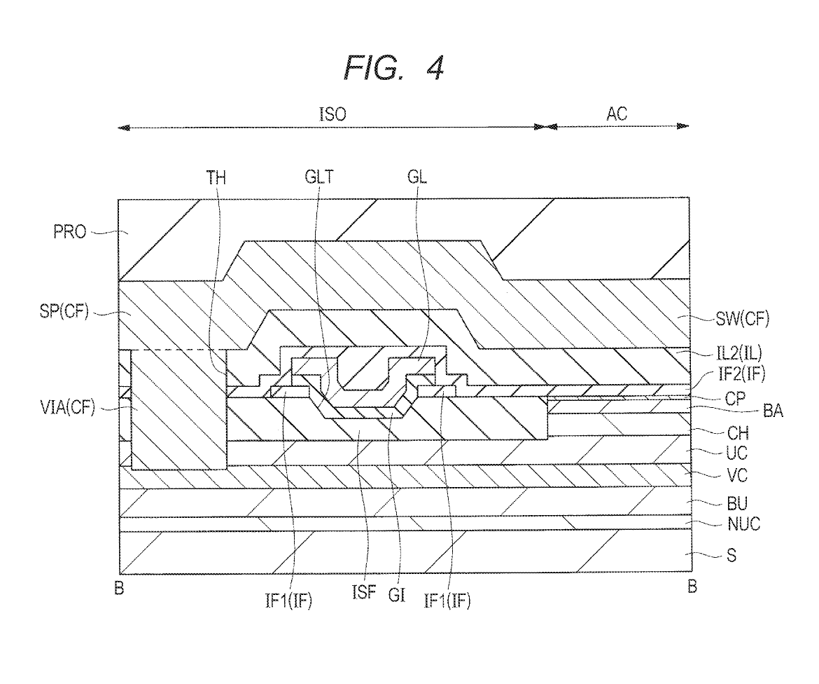

Then, with reference to FIGS. 2 to 4, the semiconductor device of the present First Embodiment will be described in more details. FIG. 2 is a plan view showing a configuration of the semiconductor device of First Embodiment. FIGS. 3 and 4 are each a cross sectional view showing a configuration of the semiconductor device of First Embodiment. FIG. 3 corresponds to the A-A cross section of FIG. 2. FIG. 4 corresponds to the B-B cross section of FIG. 2.

As shown in FIG. 2, the two directions crossing with each other, preferably orthogonal to each other in a plane are referred to as an X direction and a Y direction, respectively. Thus, the planar shape of the drain electrode DE is a rectangular shape having long sides in the Y direction. A plurality of drain electrodes DE each in a line shape are arranged at a given interval in the X direction. Whereas, the planar shape of the source electrode SE is a rectangular shape having long sides in the Y direction. A plurality of source electrodes SE each in a line shape are arranged at a given interval in the X direction. Then, the plurality of source electrodes SE and the plurality of drain electrodes DE are alternately arranged along the X direction, respectively.

The drain electrode DE is arranged in a contact hole C1D serving as the coupling part with the cap layer CP (barrier layer BA). The planar shape of the contact hole C1D is a rectangular shape having long sides in the Y direction. The source electrode SE is arranged in a contact hole C1S serving as the coupling part with the cap layer CP (barrier layer BA). The planar shape of the contact hole C1S is a rectangular shape having long sides in the Y direction.

Then, a gate electrode GE is arranged between the contact hole C1D and the contact hole C1S. The gate electrode GE has a rectangular shape having long sides in the Y direction.

The plurality of drain electrodes DE are coupled with a drain pad (also referred to as a terminal part) DP via a drain wire DW. The drain pad DP is arranged in such a manner as to extend in the X direction on one end side of the drain electrode DE (the lower side in FIG. 2). In other words, a plurality of drain electrodes DE are arranged in such a manner as to protrude in the Y direction from the drain pad DP extending in the X direction. Such a shape may be referred to as a comb shape.

The plurality of source electrodes SE are coupled with a source pad (also referred to as a terminal part) SP via a source wire SW. The source pad SP is arranged in such a manner as to extend in the X direction on the other end side of the source electrode SE (the upper side in FIG. 2). In other words, the plurality of source electrodes SE are arranged in such a manner as to protrude in the Y direction from the source pad SP extending in the X direction. Such a shape may be referred to as a comb shape.

The plurality of gate electrodes GE are coupled with a gate line GL. The gate line GL is arranged in such a manner as to extend in the X direction on one end side of the gate electrode GE (the upper side in FIG. 2). In other words, the plurality of gate electrodes GE are arranged in such a manner as to protrude in the Y direction from the gate line GL extending in the X direction. Incidentally, the gate line GL is coupled with, for example, the gate pads (not shown) provided on the opposite sides of the gate line GL in the X direction (the right side and the left side in FIG. 2).

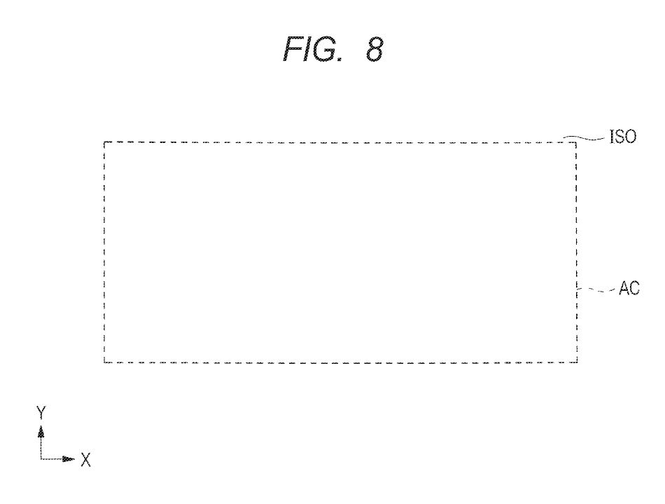

Herein, the source electrode SE, the drain electrode DE, and the gate electrode GE are mainly arranged over the active region AC surrounded by the element isolation regions ISO. The planar shape of the active region AC is a rectangular shape having long sides in the X direction (see FIG. 8). On the other hand, the drain pad DP, the gate line GL, and the source pad SP are formed over the element isolation ISF formed in the element isolation region ISO. The gate line GL is arranged between the active region AC and the source pad SP.

Then, a through hole (also referred to as a hole, opening, or concave part) TH is arranged under the source pad SP. A conductive film CF (see FIG. 4) is embedded in the through hole TH, and forms a coupling part VIA. As described later, the coupling part VIA is electrically coupled with the potential fixed layer VC. Accordingly, the source electrode SE and the potential fixed layer VC are electrically coupled with each other via the source pad SP and the coupling part VIA.

Herein, in the present First Embodiment, an inactivated region IR is provided under the drain electrode DE, and between the gate electrode GE and the drain electrode DE. The inactivated region IR is a region doped with an element (an inactivating element) for inactivating the impurity in the potential fixed layer VC.

As shown in FIGS. 3 and 4, the semiconductor device of the present First Embodiment has the gate electrode GE formed over the cap layer CP, and the source electrode SE and the drain electrode DE formed over the cap layer CP on the opposite sides of the gate electrode GE, and in the regions including the contact holes C1S and C1D formed therein, respectively, in the active region AC of the substrate S. A protective film (also referred to as an insulation film, a covering film, or a surface protective film) PRO is arranged over the source electrode SE and the drain electrode DE.

Over the substrate S, as described previously, the nucleation layer NUC, the buffer layer BU, the potential fixed layer VC, the channel base layer UC, the channel layer CH, the barrier layer BA, the cap layer CP, and the insulation film IF1 are sequentially formed. Then, a gate insulation film GI is formed in the inside of a trench T penetrating through the insulation film IF1, the cap layer CP, and the barrier layer BA, and reaching some point of the channel layer CH. The gate electrode GE is formed over the gate insulation film GI.

As the substrate S, a semiconductor substrate formed of, for example, silicon (Si) can be used. As the substrate S, a substrate formed of a nitride semiconductor such as GaN other than the silicon may be used, or a substrate formed of AlN, SiC, sapphire, or the like may be used. Especially, when a nitride semiconductor layer such as a GaN layer is formed over a silicon substrate, the buffer layer BU is often used as described later in order to improve the crystallinity thereof, or to relax the strain (internal stress) of the substrate. Accordingly, accumulation of electric charges described later tends to occur. For this reason, when a silicon substrate and a nitride semiconductor are used in combination, the semiconductor device of the present First Embodiment is effectively used.

The nucleation layer NUC is formed in order to generate the crystalline nucleus for the growth of a layer to be formed thereover such as the buffer layer BU. Further, the nucleation layer NUC is formed in order to prevent the deterioration of the substrate S due to diffusion of the constituent elements (such as Ga) of the layer formed thereover into the substrate S from the layer formed thereover. As the nucleation layer NUC, for example, an aluminum nitride (AlN) layer can be used. The film thickness of the AlN layer is about 200 nm. The material and the thickness of the nucleation layer NUC can be appropriately selected according to the material for the substrate S, or the use of the semiconductor device. Alternatively, the nucleation layer NUC can be omitted when a GaN substrate or the like is used as the substrate S, or when not necessary according to the deposition conditions for the buffer layer BU or the like.

The buffer layer BU is formed in order to adjust the lattice constant, to make favorable the crystallinity of the nitride semiconductor to be formed thereover, or to relax the film stress of the nitride semiconductor to be stacked. This improves the crystallinity of the nitride semiconductor. Further, the strain (internal stress) of the substrate S can be relaxed, so that the substrate S can be inhibited from undergoing warpage or cracks.

A superlattice structure in which lamination films (AlN/GaN films) each of a gallium nitride (GaN) layer and an aluminum nitride (AlN) layer are deposited a plurality of cycles can be used as the buffer layer BU. The superlattice structure includes two or more laminates of nitride semiconductor layers having different electron affinities repeatedly arranged therein. The superlattice structure is doped with carbon (C). For example, the film thickness of the GaN layer is set at about 20 nm, and the film thickness of the AlN layer is set at about 5 nm. A superlattice structure including the lamination films deposited 80 cycles can be used. The carbon concentration (dope amount) is, for example, about 1×10¹⁹ (1E19) cm⁻³. However, the material or the thickness of each film forming the lamination film may be appropriately selected according to the use of the semiconductor device.

Further, the buffer layer BU may include a layer other than the superlattice structure. For example, another material film may be formed over the superlattice structure. Alternatively, a singlelayer film not including a superlattice structure, or the like can also be used as the buffer layer BU.

As the materials for the superlattice structure and the singlelayer film, InN can be used other than AlN and GaN. Alternatively, a mixed crystal of the nitride semiconductors may also be used. For example, as the lamination film of the superlattice structure, an AlGaN/GaN film can be used other than an AlN/GaN film. Whereas, for example, an AlGaN layer or an InAlN layer can be used as the singlelayer film.

Further, in the foregoing description, the superlattice structure is doped (added) therein with carbon. However, other doping impurities may be used. As the doping impurities, elements forming a deep level are preferable. Other than carbon, a transition metal such as iron (Fe), magnesium (Mg), beryllium (Be), or the like may be used. The dope amount or the impurity element may be appropriately selected according to the use of the semiconductor device.

For example, an AlGaN layer doped with a p type impurity can be used as the potential fixed layer VC. A GaN layer, an AlN layer, or an InN layer may also be used other than the AlGaN layer. Alternatively, a mixed crystal of the nitride semiconductors may be used.

The potential fixed layer VC is doped with an impurity, and has a conductivity. For example, an AlGaN layer doped with Mg in an amount of about 5×10¹⁸ (5E18) cm⁻³ as an impurity can be used as the potential fixed layer VC. The film thickness of the potential fixed layer VC can be set at about 200 nm, and the composition of Al can be set at about 3%.

Thus, an impurity is required to be doped in an amount sufficient to cause the conductivity (e.g., with the layer structure of the present First Embodiment, the activated impurity concentration is 5×10¹⁶ (5E16) cm⁻³ or more). A p type impurity can be used as the doping impurity. As the p type impurity, for example, mention may be made of Be or C, other than Mg described previously. Whereas, from the viewpoint of the longitudinal breakdown voltage, the dope amount of the impurity is preferably 1×10¹⁸ (1E18) cm⁻³ or less in terms of the activated impurity concentration. For example, in the layer structure of the present First Embodiment, in order to ensure 500 V or more as the breakdown voltage in the longitudinal direction (the thickness direction), the dope amount is preferably set at 5×10¹⁷ (5E17) cm⁻³or less in terms of the activated impurity concentration.

As the channel base layer UC, for example, an AlGaN layer can be used. The channel base layer UC is not subjected to intentional impurity doping therein. Incidentally, the formation of a deep level by impurity doping causes variations in characteristics such as the threshold potential as described in details later. Accordingly, the dope amount of the impurity is preferably 1×10¹⁶ (1E16) cm⁻³ or less.

Whereas, the thickness of the AlGaN layer is, for example, about 1000 nm, and the composition of Al is about 3%. As the channel base layer UC, an InAlN layer, or the like can be used other than an AlGaN layer.

Further, in the present First Embodiment, the lattice constant in the in-plane direction of the channel base layer UC is taken over to the channel layer CH and the barrier layer BA thereover by epitaxial growth. For example, when a layer having a larger lattice constant than that of the channel base layer (AlGaN layer) UC such as a GaN layer, an InₓGa₍₁₋ₓ₎N layer (0≦X≦1), or an InAlN layer is formed at a layer over the channel base layer UC, the overlying layer is applied with a compressive strain. Conversely, when a layer having a smaller lattice constant than that of the channel base layer (AlGaN layer) UC such as an InAlN layer with a high Al composition ratio is formed at a layer over the channel base layer UC, the overlying layer is applied with a tensile strain.

As the channel layer CH, for example, a GaN layer can be used. The channel layer CH is not subjected to intentional impurity doping therein. Whereas, the thickness of the GaN layer is, for example, about 80 nm. As the materials for the channel layer CH, AlN, InN, and the like can be used other than GaN. Alternatively, a mixed crystal of the nitride semiconductors may be used. The material or the thickness of the channel layer CH can be appropriately selected according to the use of the semiconductor device. Incidentally, in the present First Embodiment, the nondoped channel layer CH was used. However, an impurity may be appropriately doped according to the use. As the doping impurity, an n type impurity or a p type impurity can be used. Examples of the n type impurity may include Si, S, or Se. Examples of the p type impurity may include Be, C, or Mg.

However, the channel layer CH is a layer in which electrons run. For this reason, when the dope amount of the impurity is too large, the mobility may be reduced by the Coulomb scattering. Thus, the dope amount of the impurity into the channel layer CH is preferably 1×10¹⁷ (1E17) cm⁻³ or less.

Further, for the channel layer CH, it is necessary to use a nitride semiconductor larger in electron affinity than the channel base layer UC or the barrier layer BA. As described above, an AlGaN layer is used as the channel base layer UC, and a GaN layer is used as the channel layer CH. Thus, when the lattice constants of the layers are different, the film thickness of the channel layer CH is required to be equal to, or smaller than the critical film thickness from which dislocation increases.

As the barrier layer BA, for example, an Al_{0.2}Ga_{0.8}N layer can be used. Whereas, the thickness of the Al_{0.2}Ga_{0.8}N layer is, for example, about 30 nm. As the materials for the barrier layer BA, an InAlN layer, and the like can be used other than the AlGaN layer. The composition ratio of Al, or the like may be appropriately adjusted. Alternatively, a barrier layer BA of a multilayer structure resulting from lamination of films having different Al composition ratios may be used. Further, as the materials for the barrier layer BA, a GaN layer, an AlN layer, an InN layer, and the like can be used. Alternatively, a mixed crystal of the nitride semiconductors may be used. The material or the thickness of the barrier layer BA, and the like can be appropriately selected according to the use of the semiconductor device.

Incidentally, a nondoped layer may be used as the barrier layer BA, and an impurity may be appropriately doped according to the use. An n type impurity or a p type impurity can be used as the doping impurity. Examples of the n type impurity may include Si, S, or Se. Examples of the p type impurity may include Be, C, or Mg.

However, when the dope amount of the impurity in the barrier layer BA is too large, in the vicinity of the gate electrode GE described later, the device becomes more likely to be affected by the potential of the drain electrode DE. This may result in a reduction of the breakdown voltage. Further, the impurity in the barrier layer BA may cause the Coulomb scattering in the channel layer CH. This may result in a reduction of the mobility of electrons. Thus, the dope amount of the impurity into the barrier layer BA is preferably 1×10¹⁷ (1E17) cm⁻³ or less. Further, it is more preferable to use a nondoped barrier layer BA.

Further, a GaN layer is used as the channel layer CH, and an AlGaN layer is used as the barrier layer BA. Thus, when the lattice constants of the layers are different, the film thickness of the barrier layer BA is required to be equal to, or smaller than the critical film thickness from which dislocation increases.

Further, as described previously, as the barrier layer BA, it is necessary to use a nitride semiconductor smaller in electron affinity than the channel layer CH. However, when a barrier layer BA of a multilayer structure is used, the multilayer may include therein a layer larger in electron affinity than the channel layer CH. It is essential only that at least one layer or more is a layer smaller in electron affinity than the channel layer CH.

For example, a GaN layer can be used as the cap layer CP. The thickness of the GaN layer is, for example, about 2 nm. Alternatively, as the cap layer CP, an AlN layer, an InN layer, or the like can be used other than a GaN layer. Alternatively, a mixed crystal of the nitride semiconductors (e.g., AlGaN or InAlN) may be used. Still alternatively, the cap layer CP may be omitted.

For the cap layer CP, it is necessary to use a nitride semiconductor larger in electron affinity than the barrier layer BA. Further, as the cap layer CP, a nondoped layer may be used, or an impurity may be appropriately doped according to the use. An n type impurity or a p type impurity can be used as the doping impurity. Examples of the n type impurity may include Si, S, or Se. Examples of the p type impurity may include Be, C, or Mg.

Whereas, an AlGaN layer is used as the channel base layer UC, and a GaN layer is used as the cap layer CP. Thus, when the lattice constants of the layers are different, the film thickness of the cap layer CP is required to be equal to, or smaller than the critical film thickness from which dislocation increases.

For example, a silicon nitride film can be used as the insulation film IF1. The thickness of the silicon nitride film is, for example, about 100 nm. Alternatively, an insulation film may be used other than a silicon nitride film. Still alternatively, a lamination structure of several kinds of insulation films may be used. The material or the thickness of the insulation film IF1 can be appropriately selected according to the use of the semiconductor device. As the insulation film IF1, preferable is a film larger in bandgap, and smaller in electron affinity than the underlying nitride semiconductor. As the film satisfying such conditions, mention may be made of, other than a silicon nitride film (SiN), a silicon oxide (SiO₂) film, a silicon oxynitride film, a silicon oxycarbide (SiOC) film, an aluminum oxide (Al₂O₃ or alumina) film, a hafnium oxide (HfO₂) film, a zirconium oxide (ZrO₂) film, or the like. Further, various organic films satisfy the conditions described above. Further, out of these, it is preferable to select a film low in interface state density formed at the interface with the underlying nitride semiconductor for current collapse inhibition.

The gate insulation film GI is formed in the inside of the trench (also referred to as a recess) T penetrating through the insulation film IF1, the cap layer CP, and the barrier layer BA, and dug into some point of the channel layer CH. The gate electrode GE is formed over the gate insulation film GI.

Incidentally, the portion protruding from the end of the trench T on the drain electrode DE side toward a first side (the right side in FIG. 3, i.e., the drain side) is a gate field plate electrode GFP. The gate field plate electrode GFP relaxes the concentration of the electric field distribution in each portion of respective nitride semiconductor layers such as the channel layer CH situated on the drain side with respect to the trench T.

As the gate insulation film GI, an aluminum oxide (Al₂O₃) film can be used. The thickness of the aluminum oxide film is, for example, about 50 nm. As the gate insulation film GI, an insulation film other than an aluminum oxide film may be used. Alternatively, a lamination structure of several kinds of insulation films may be adopted. The material or the thickness of the gate insulation film GI can be appropriately selected according to the use of the semiconductor device. As the gate insulation film GI, preferable is a film larger in bandgap, and smaller in electron affinity than the underlying nitride semiconductor. As films satisfying such conditions, mention may be made of, other than an aluminum oxide film, a silicon oxide (SiO₂) film, a silicon nitride film (SiN), a hafnium oxide (HfO₂) film, a zirconium oxide (ZrO₂) film, and the like. The gate insulation film GI affects the voltage applicable to the gate electrode GE, or the threshold voltage, and hence, is preferably set in consideration of the insulation breakdown voltage, the dielectric constant, or the film thickness.

A titanium nitride (TiN) film can be used as the gate electrode GE. The thickness of the titanium nitride film is, for example, about 200 nm. A conductive film other than a titanium nitride film may be used as the gate electrode GE.

A polycrystal silicon film doped with an impurity such as boron (B) or phosphorus (P) may be used. Alternatively, a metal including Ti, Al, Ni, Au, or the like may be used. Still alternatively, a compound film (metal silicide film) of a metal including Ti, Al, Ni, Au, or the like, and Si may be used. Further alternatively, a nitride of a metal film including Ti, Al, Ni, Au, or the like may be used. Alternatively, a lamination structure of several kinds of conductive films may be adopted. The material or the thickness of the gate electrode GE can be appropriately selected according to the use of the semiconductor device.

Further, as the gate electrode GE, it is preferable to select a material less likely to react with the underlying film (e.g., the gate insulation film GI), or the overlying film (e.g., the interlayer insulation film IF2 and the interlayer insulation film IL).

In the present First Embodiment, the inactivated region IR is provided under the drain electrode DE, and between the gate electrode GE and the drain electrode DE. The inactivated region IR is a region obtained by doping an inactivating element into the lamination part of the potential fixed layer VC, the channel base layer UC, the channel layer CH, and the barrier layer BA situated under the drain electrode DE, and between the gate electrode GE and the drain electrode DE. The inactivating element may be desirably doped into at least the potential fixed layer VC. Other layers (e.g., the channel base layer UC, the channel layer CH, and the barrier layer BA) are not required to contain an inactivating element in a high concentration. Accordingly, adjustment may be desirably achieved so that the inactivating element is contained in the potential fixed layer VC in a desired amount in consideration of the diffusion distance of the inactivating element.

For example, an inactivating element is doped so that the activation ratio of the p type impurity in the potential fixed layer VC in the inactivated region IR is lower than, and is preferably 1/10 or less the activation ratio of the p type impurity in the potential fixed layer VC under the source electrode SE not inactivated. However, an inactivating element may be diffused into the layer in the vicinity of the potential fixed layer VC. For example, an inactivating element may be diffused into the channel base layer UC, the channel layer CH, and the barrier layer BA. Alternatively, an inactivating element may be diffused into the layers below the potential fixed layer VC. Incidentally, the inactivating element is for inactivating the p type impurity, and does not eliminate the two-dimensional electron gas.

Specifically, the portion PV1 of the potential fixed layer VC situated under the drain electrode DE contains an inactivating element. For example, the content of the inactivating element in the portion PV1 is larger than the content of the inactivating element in the portion PV2 of the potential fixed layer VC situated under the source electrode SE. In other words, the portion PV2 contains an inactivating element in a lower concentration than the concentration of the inactivating element in the portion PV1, or does not contain an inactivating element. In such a case, the drain breakdown voltage can be improved, which can reduce the the capacitance between the source electrode SE and the drain electrode DE. This facilitates the high-speed operation of the semiconductor device.

Alternatively, the portion PV3 of the potential fixed layer VC situated between the gate electrode GE and the drain electrode DE contains an inactivating element. For example, the content of the inactivating element in the portion PV3 is larger than the content of the inactivating element in the portion PV4 of the potential fixed layer VC situated between the gate electrode GE and the source electrode SE. In other words, the portion PV4 contains an inactivating element in a lower concentration than the concentration of the inactivating element in the portion PV3, or does not contain an inactivating element. Also in such a case, the drain breakdown voltage can be improved, which can reduce the the capacitance between the source electrode SE and the drain electrode DE. This facilitates the high-speed operation of the semiconductor device.

Over the gate electrode GE, an interlayer insulation film IL is arranged via the insulation film IF2. The interlayer insulation film IL has a through hole TH, and contact holes C1S and C1D.

As the insulation film IF2, for example, a silicon nitride film can be used. Namely, the insulation film IF2 contains silicon and nitrogen. The thickness of the silicon nitride film is, for example, about 100 nm. The insulation film IF2 will be described later.

As the interlayer insulation film IL, for example, a silicon oxide film can be used. Namely, the interlayer insulation film IL contains silicon and oxygen. As described later, the interlayer insulation film IL includes the insulation films IL1 and IL2 each formed of a silicon oxide film. The thickness of each silicon oxide film is, for example, about 500 nm. Alternatively, an insulation film other than a silicon oxide film may be used. Alternatively, a lamination structure of several kinds of insulation films may be adopted. The material or the thickness of the interlayer insulation film IL1 can be appropriately selected according to the use of the semiconductor device. As the interlayer insulation film IL, preferable is a film larger in bandgap, and smaller in electron affinity than the underlying nitride semiconductor. Further, as the interlayer insulation film IL, it is preferable to select a material less likely to react with the gate electrode GE in contact therewith. As films satisfying such conditions, mention may be made of, other than a silicon oxide film, a silicon nitride film, a silicon oxynitride film, an aluminum oxide (Al₂O₃) film, a hafnium oxide (HfO₂) film, a zirconium oxide (ZrO₂) film, and the like.

A conductive film CF is formed over the interlayer insulation film IL1 including the through hole TH, and the contact holes C1S and C1D. Herein, a lamination film of a TiN film and an Al film is formed as the conductive film CF. Of the conductive film CF, the conductive film CF in the contact hole C1S serves as the source electrode SE, and the conductive film CF in the contact hole C1D serves as the drain electrode DE. On the other hand, the conductive film CF in the through hole TH serves as the coupling part VIA.

Namely, the source electrode SE is formed of the portion of the conductive film CF situated in the contact hole C1S, and the drain electrode DE is formed of the portion of the conductive film CF situated in the contact hole C1D. Whereas, the coupling part VIA is formed of the portion of the conductive film CF situated in the through hole TH.

Incidentally, the portion of the conductive film CF arranged outside the contact hole C1S, and formed integrally with the source electrode SE serves as a source wire SW, and the portion of the conductive film CF arranged outside the contact hole C1D, and formed integrally with the drain electrode DE serves as a drain wire DW.

Whereas, the portion outside the contact hole C1S, and protruding toward the first side with respect to the source electrode SE (the right side in FIG. 3, i.e., the drain side) is a source field plate electrode SFP. The source field plate electrode SFP is the portion of the conductive film CF arranged further closer to the drain side with respect to the end of the contact hole C1S on the drain electrode DE side. The source field plate electrode SFP relaxes the concentration of the electric field distribution in each portion of respective nitride semiconductor layers such as the channel layer CH situated on the drain side with respect to the gate electrode GE. Therefore, the end of the source field plate electrode SFP on the drain electrode DE side is preferably arranged further closer to the drain side with respect to the end of the gate electrode GE on the drain electrode DE side.

As the conductive film CF, a lamination film of a TiN film and an Al film thereover can be used. The thickness of the TiN film is, for example, about 50 nm. The thickness of the Al film is, for example, about 1000 nm. As the materials for the conductive film CF, any materials are acceptable so long as they are in ohmic contact with the nitride semiconductor layer (cap layer CP) at each bottom of the contact holes C1S and C1D. Particularly, when an n type impurity is doped into the nitride semiconductor layer (cap layer CP) at each bottom of the contact holes C1S and C1D, or the nitride semiconductor layer below this layer, the ohmic contact becomes more likely to be ensured. Accordingly, for the conductive film CF, selection from a wide range of material group becomes possible.

Further, as the materials forming the conductive film CF, it is preferable to select a material less likely to react with the interlayer insulation film IL in contact therewith. As the materials forming the conductive film CF, a metal film formed of titanium (Ti), aluminum (Al), molybdenum (Mo), niobium (Nb), vanadium (V), or the like may be used. Alternatively, mixtures (alloys) of the metals, compound films of the metals and silicon (Si) (metal silicide films), nitrides of the metals, and the like can be used. Still alternatively, lamination films of the materials may be used.

Incidentally, the materials forming the coupling part VIA may be different materials from those for the conductive film CF forming the source electrode SE and the drain electrode DE. For example, when the potential fixed layer VC contains a p type impurity, as the materials forming the coupling part VIA, a metal film formed of titanium (Ti), nickel (Ni), platinum (Pt), rhodium (Rh), palladium (Pd), iridium (Ir), copper (Cu), silver (Ag), or the like is preferably used. Alternatively, mixtures (alloys) of the metals, compound films of the metals and silicon (Si) (metal silicide films), nitrides of the metals, or the like are preferably used. Still alternatively, lamination films of the materials may be used.

Whereas, in the present First Embodiment, the bottom surface of the through hole TH is arranged at some point of the potential fixed layer VC, and the coupling part VIA is arranged in the inside of the through hole TH. However, it is essential only that the coupling part VIA is arranged so as to be in contact with the potential fixed layer VC. For example, the following configuration is also acceptable: the bottom surface of the through hole TH is arranged at the top surface of the potential fixed layer VC, so that the bottom of the coupling part VIA and the potential fixed layer VC are in contact with each other.

Alternatively, the following configuration is also acceptable: the bottom surface of the through hole TH is arranged below the bottom surface of the potential fixed layer VC, so that a part of the side surface of the coupling part VIA is in contact with the potential fixed layer VC. For example, the bottom surface of the through hole TH may be situated at the surface of the buffer layer BU, or some point of the buffer layer BU. Alternatively, the bottom surface of the through hole TH may be situated at the surface of the nucleation layer NUC, or some point of the nucleation layer NUC.

Alternatively, the bottom surface of the through hole TH may be situated at the surface of the substrate S, or some point of the substrate S. However, only contact between a part of the side surface of the coupling part VIA and the potential fixed layer VC may reduce the contact area. For this reason, the bottom surface of the through hole TH is preferably arranged from at the top surface of the potential fixed layer VC, or lower to above the lower surface of the potential fixed layer VC.

The source pad SP and the drain pad DP are formed integrally with the source electrode SE and the drain electrode DE, respectively. Accordingly, the source pad SP and the drain pad DP are formed of the same materials for the source electrode SE and the drain electrode DE, respectively. The coupling part VIA is arranged under the source pad SP (see FIG. 4).

As a protective film PRO, an insulation film such as a silicon oxynitride (SiON) film can be used.

In the present First Embodiment, the interlayer insulation film IL includes the insulation film IL1 and the insulation film IL2. The insulation film IL1 is formed between the gate electrode GE and the drain electrode DE. The insulation film IL2 is formed between the gate electrode GE and the drain electrode DE, and between the gate electrode GE and the source electrode SE. Further, the insulation film IL2 is formed over the insulation film IL1 between the gate electrode GE and the drain electrode DE. Incidentally, the insulation film IL2 is also formed over the gate electrode GE.

Accordingly, the film thickness FT1 of the portion PT1 of the interlayer insulation film IL situated between the gate electrode GE and the drain electrode DE is larger than the the film thickness FT2 of the portion PT2 of the interlayer insulation film IL situated between the gate electrode GE and the source electrode SE. Namely, the film thickness FT1 of the portion PT1 is different from the film thickness FT2 of the portion PT2. Whereas, the height position of the top surface of the portion PT1 is higher than the height position of the top surface of the portion PT2. Incidentally, the portion PV3 is the portion of the potential fixed layer VC situated below the portion PT1. The portion PV4 is the portion of the potential fixed layer VC situated below the portion PT2.

The insulation film IF2 is formed between the gate electrode GE and the drain electrode DE, and contains silicon and nitrogen. The insulation film IL1 is formed over the insulation film IF2 between the gate electrode GE and the drain electrode DE.

The insulation films IL1 and IL2 are each formed of, for example, a silicon oxide film. Namely, each of the insulation films IL1 and IL2 contains silicon and oxygen.

The insulation film IF2 containing silicon, nitrogen, and hydrogen such as a silicon nitride film containing hydrogen is formed over the portion of the barrier layer BA situated on the drain side with respect to the gate electrode GE. Then, the insulation film IL1 which is a part of the interlayer insulation film IL is formed over the insulation film IF2. At this step, the insulation film IL1 is not formed over the portion of the barrier layer BA situated on the source side with respect to the gate electrode GE. Then, after the formation of the insulation film IL1, the substrate S is heat treated. As a result, the hydrogen contained in the insulation film IF2 is doped into the potential fixed layer VC. Subsequently, over the portion of the insulation film IF2 situated on the drain side with respect to the gate electrode GE, the insulation film IL2 which is a part of the interlayer insulation film IL is formed via the insulation film IL1. On the other hand, over the portion of the insulation film IF2 situated on the source side with respect to the gate electrode GE, the insulation film IL2 is formed not via the insulation film IL1.

As a result, the drain-side potential fixed layer VC can be inactivated without more damaging the crystal of the nitride semiconductor layer such as the channel layer CH as compared with the case where the potential fixed layer VC is doped with an inactivating element by ion implantation.

Further, in the present First Embodiment, the insulation film IL1 contains an inactivating element, and the portion PT2 contains an inactivating element in a lower concentration than the concentration of the inactivating element in the insulation film IL1, or does not contain an inactivating element. This is due to the following: after the formation of the insulation film IL1, the inactivating element contained in the insulation film IF2 is partially doped into the insulation film IL1 when the substrate S is heat treated.

Incidentally, in the present First Embodiment, the film thickness FT1 of the portion PT1 is larger than the film thickness FT2 of the portion PT2. Accordingly, the depth dimension of the contact hole C1D is larger than the depth dimension of the contact hole C1S. For this reason, the height dimension of the drain electrode DE is larger than the height dimension of the source electrode SE.

[Manufacturing Method Description]

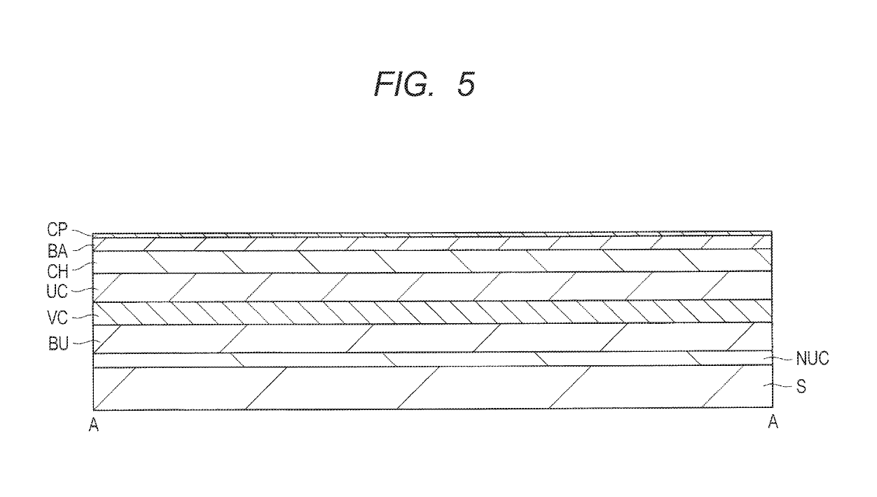

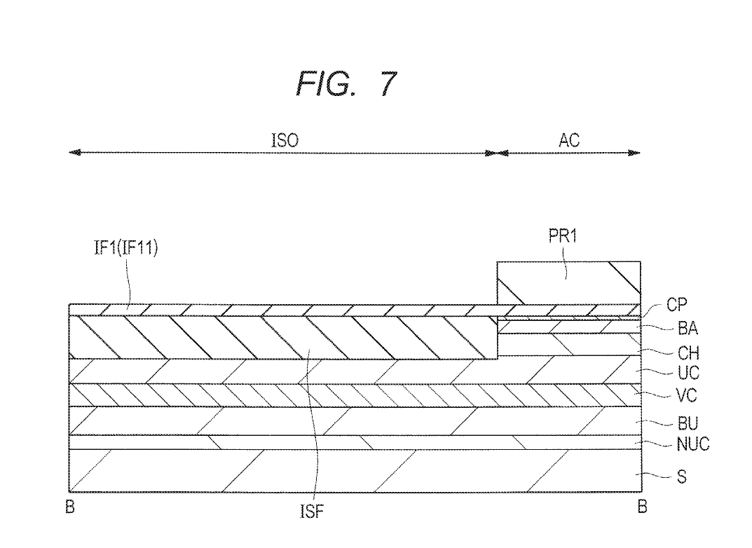

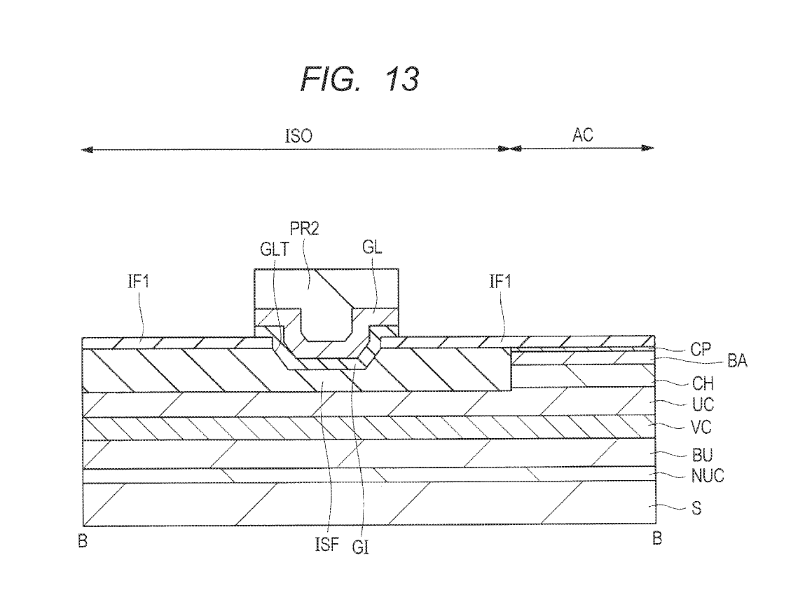

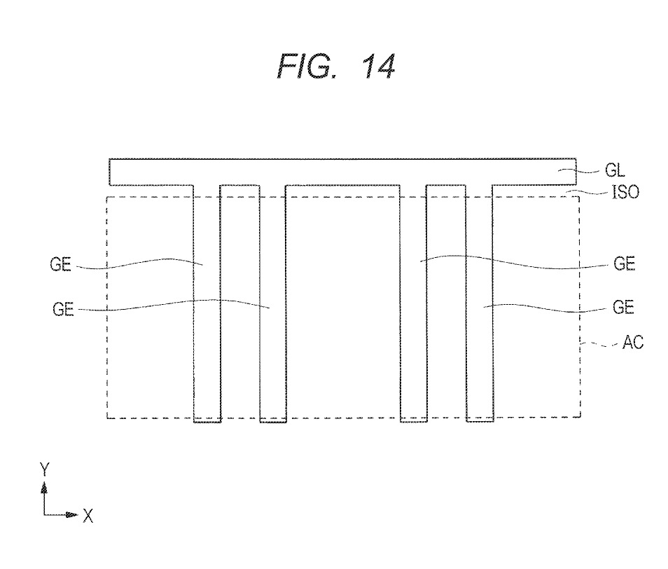

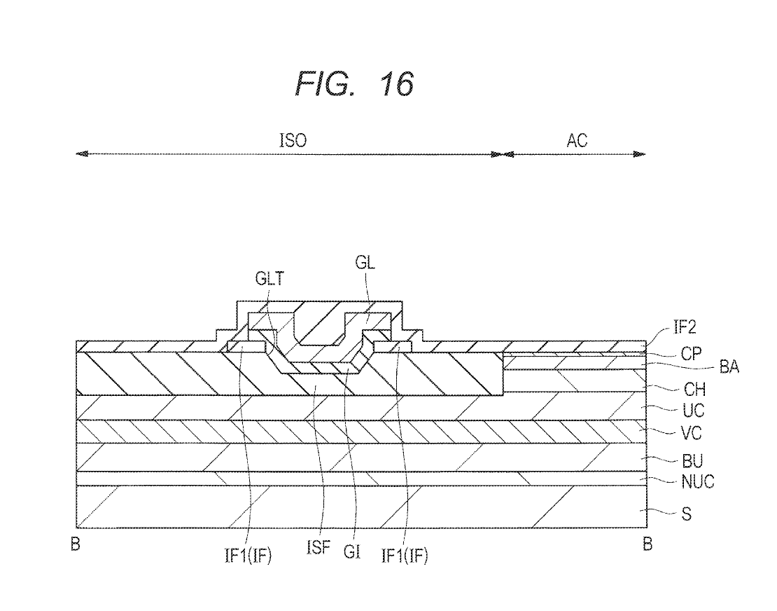

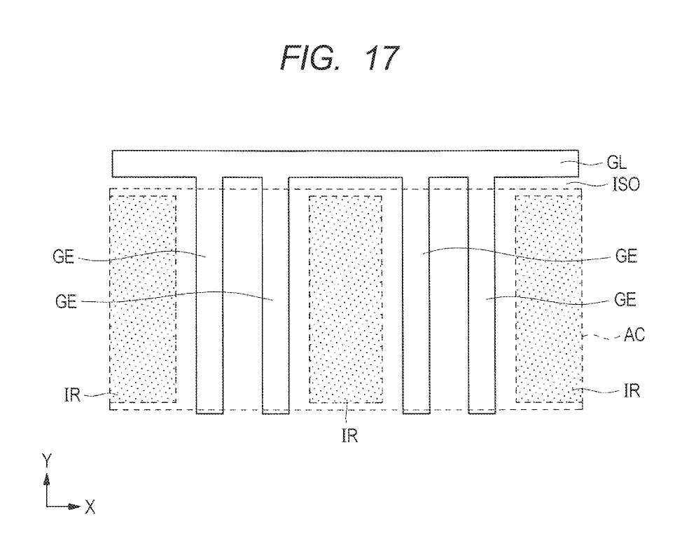

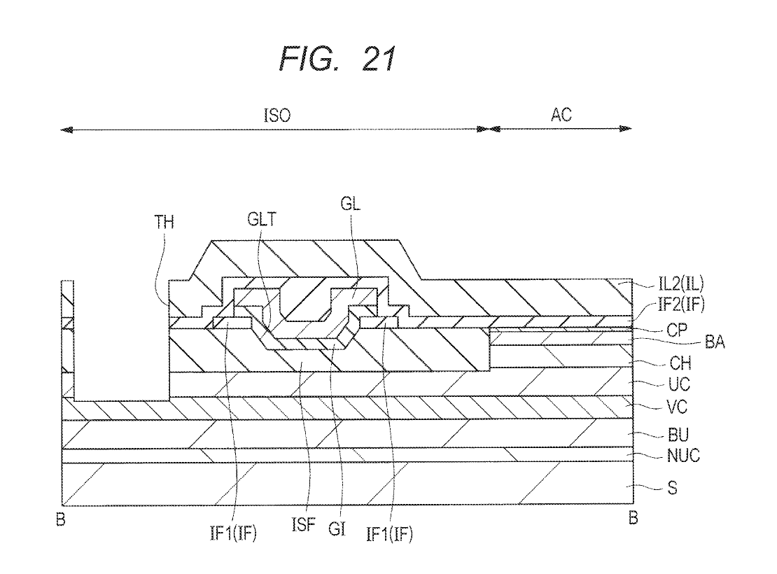

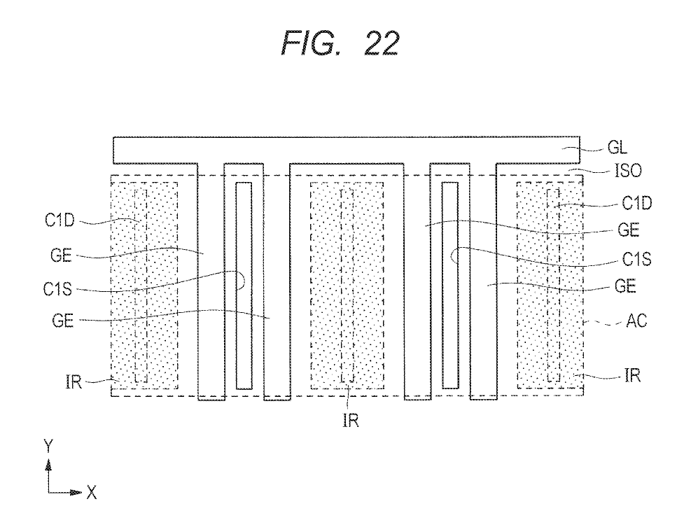

Then, with reference to FIGS. 5 to 24, a description will be given to a method for manufacturing the semiconductor device of the present First Embodiment. In addition, the configuration of the semiconductor device will be made clearer. FIGS. 5 to 24 are each a cross sectional view or a plan view showing the semiconductor device of First Embodiment during a manufacturing step.

As shown in FIG. 5, a substrate S is provided. A nucleation layer NUC and a buffer layer BU are sequentially formed over the provided substrate S. For example, a semiconductor substrate formed of silicon (Si) with a (111)-plane exposed is used as the substrate S. Further, as the nucleation layer NUC, for example, an aluminum nitride (AlN) layer is heteroepitaxially grown with a film thickness of about 200 nm at the top of the substrate S using a MOCVD: Metal Organic Chemical Vapor Deposition method, or the like.

Incidentally, a substrate formed of SiC, sapphire, or the like may be used as the substrate S other than the silicon. Further, generally, the nucleation layer NUS, and the nitride semiconductor layers (III-V group compound layers) subsequent to the nucleation layer NUS are all formed by III-group element plane growth (namely, in the present case, gallium plane growth or aluminum plane growth).

Then, over the nucleation layer NUC, a superlattice structure in which lamination films (AlN/GaN films) each of a gallium nitride (GaN) layer and an aluminum nitride (AlN) layer are repeatedly stacked is formed as the buffer layer BU. For example, gallium nitride (GaN) layers each with a film thickness of about 20 nm and aluminum nitride (AlN) layers each with a film thickness of about 5 nm are alternately heteroepitaxially grown using the metal organic chemical vapor deposition method or the like. For example, 40 layers of the lamination films are formed. When the lamination film is grown, the lamination film may be grown while being doped with carbon (C). Carbon is doped so that the carbon concentration in the lamination film is, for example, about 1×10¹⁹ (1E19) cm⁻³.

Further, over the buffer layer BU, as a part of the buffer layer BU, for example, an AlGaN layer may be heteroepitaxially grown using the metal organic chemical vapor deposition method or the like.

Then, over the buffer layer BU, as the potential fixed layer VC, for example, an AlGaN layer doped with a p type impurity is heteroepitaxially grown using the metal organic chemical vapor deposition method, or the like. For example, magnesium (Mg) is used as a p type impurity. For example, a gallium nitride layer is deposited about 200 nm thick while being doped with Mg. The Mg concentration in the deposited film is set at, for example, about 5×10¹⁸ (5E18) cm⁻³.

Then, a channel base layer UC is formed over the potential fixed layer VC. Over the potential fixed layer VC, as the channel base layer UC, for example, an AlGaN layer is heteroepitaxially grown using the metal organic chemical vapor deposition method, or the like. At this step, growth is achieved without performing intentional impurity doping. The thickness is set at, for example, about 1000 nm, and the composition of Al is set at about 3%.

Then, a channel layer CH is formed over the channel base layer UC. For example, over the channel base layer UC, a gallium nitride layer (GaN layer) is heteroepitaxially grown using the metal organic chemical vapor deposition method, or the like. At this step, growth is achieved without performing intentional impurity doping. The film thickness of the channel layer CH is, for example, about 80 nm.

Then, over the channel layer CH, as the barrier layer BA, for example, an AlGaN layer is heteroepitaxially grown using the metal organic chemical vapor deposition method, or the like. For example, an Al_{0.2}Ga_{0.8}N layer is formed by setting the composition ratio of Al at 0.2, and the composition ratio of Ga at 0.8. The composition ratio of Al of the AlGaN layer of the barrier layer BA is set larger than the composition ratio of Al of the AlGaN layer of the channel base layer UC described previously.

In this manner, a laminate of the channel base layer UC, the channel layer CH, and the barrier layer BA is formed. A two-dimensional electron gas (2DEG) is generated in the vicinity of the interface between the channel layer CH and the barrier layer BA of the laminate.

Then, a cap layer CP is formed over the barrier layer BA. For example, over the barrier layer BA, a gallium nitride (GaN) layer is heteroepitaxially grown using the metal organic chemical vapor deposition method, or the like. At this step, growth is achieved without performing intentional impurity doping. The film thickness of the cap layer CP is, for example, about 2 nm.

Then, after completion of deposition of the GaN type semiconductor film such as a gallium nitride (GaN)layer, a heat treatment is performed in order to activate a p type impurity. For example, a heat treatment is performed at 750° C. for 30 minutes in a nitrogen atmosphere.

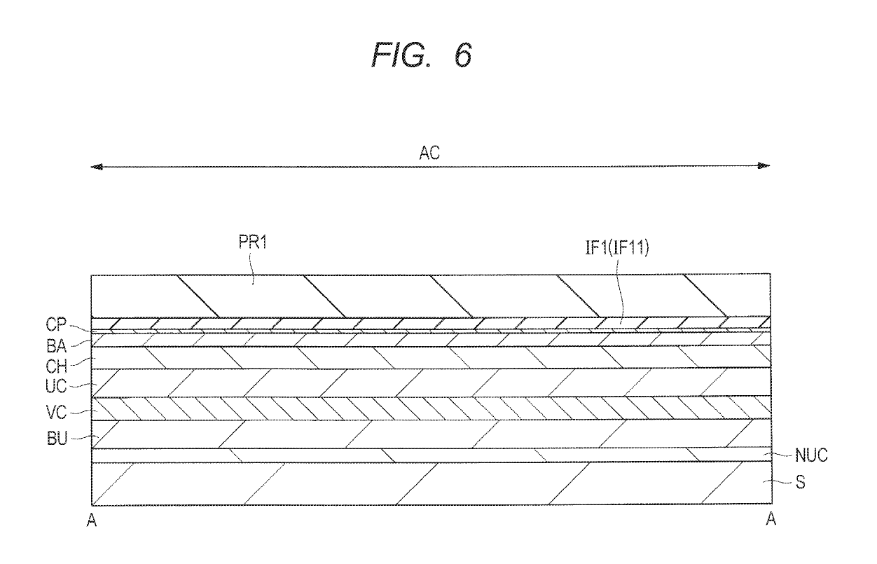

Then, as shown in FIGS. 6 to 8, over the cap layer CP, as the insulation film IF1, a silicon nitride film is deposited with a film thickness of, for example, about 100 nm using a PECVD: Plasma-Enhanced Chemical Vapor Deposition method, or the like.

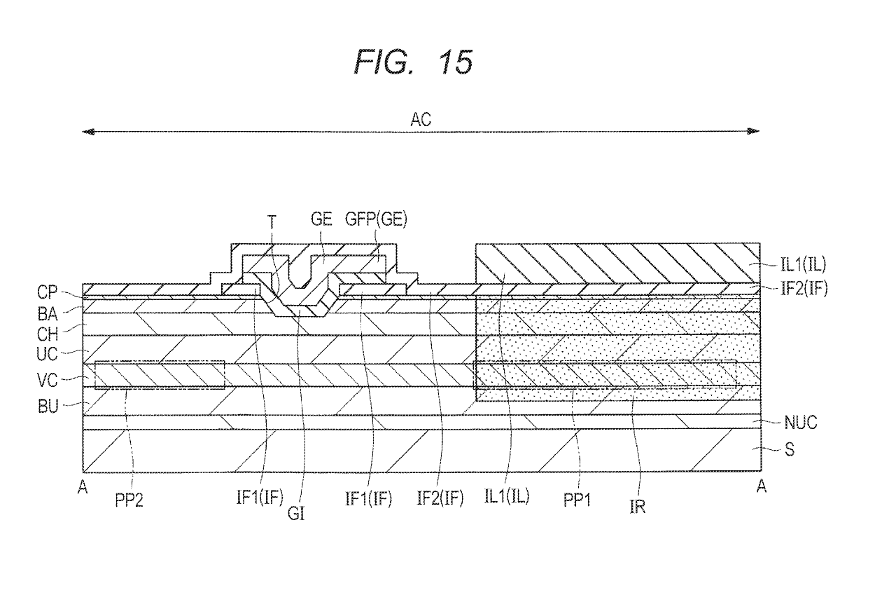

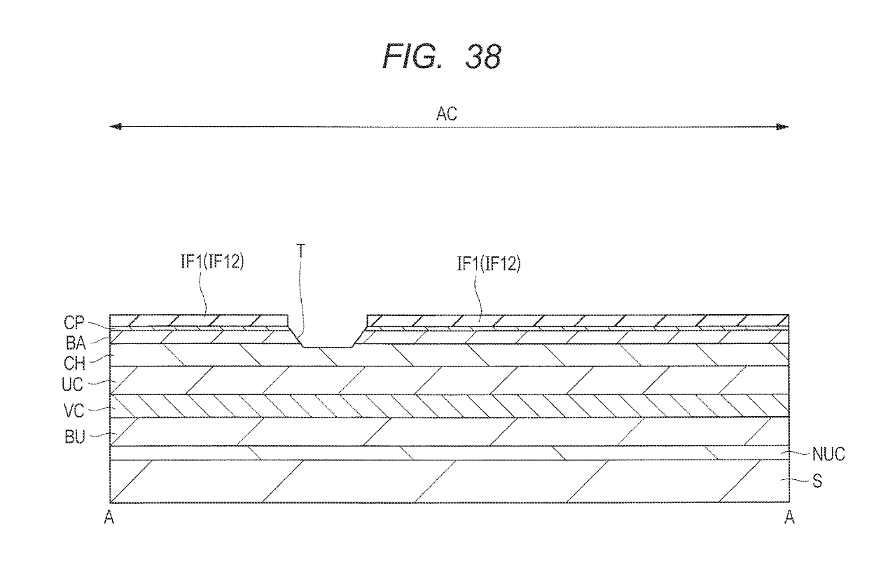

The insulation film IF1 contains hydrogen in a lower concentration than the concentration of hydrogen in the insulation film IF2 (see FIG. 15), or does not contain hydrogen. Such an insulation film IF1 can be formed in the following manner. An insulation film IF11 containing hydrogen in a high concentration is formed. Thus, the substrate S is subjected to a heat treatment with the insulation film IF11 exposed at the outermost surface. As a result, the hydrogen contained in the insulation film IF11 is released. This can form the insulation film IF1 formed of the insulation film IF11 containing hydrogen in a lower concentration. Alternatively, as described by reference to FIG. 38 described later, the following is also acceptable: an insulation film IF12 containing hydrogen in a low concentration, or not containing hydrogen is formed, and the insulation film IF1 formed of the insulation film IF12 is formed.

Then, by a photolithography treatment, a photoresist film PR1 including an opening formed in the element isolation region ISO is formed over the insulation film IF1. Then, using the photoresist film PR1 as a mask, for example, nitrogen ions are implanted, thereby to form an element isolation ISF in the element isolation region ISO. Thus, ion species such as nitrogen (N) or boron (B) is implanted, so that the crystal state is changed, resulting in an increase in resistance.

For example, nitrogen ions are implanted at a density of about 5×10¹⁴ (5E14) cm⁻² via the insulation film IF1 into a laminate formed of the channel base layer UC, the channel layer CH, and the barrier layer BA. The implantation energy is, for example, about 120 keV. Incidentally, the nitrogen ion implantation conditions are adjusted so that the depth of implantation, namely, the bottom of the element isolation ISF is situated below the bottom surface of the channel layer CH, and situated above the bottom surface of the potential fixed layer VC.

Incidentally, the bottom of the element isolation ISF is situated above the bottom of the through hole TH (coupling part VIA) described later. In this manner, the element isolation ISF is formed in the element isolation region ISO. The region surrounded by the element isolation regions ISO serves as an active region AC. As shown in FIG. 8, the active region AC is, for example, in a substantially rectangular shape having long sides in the X direction. Then, the photoresist film PR1 is removed by a plasma ashing treatment, or the like.

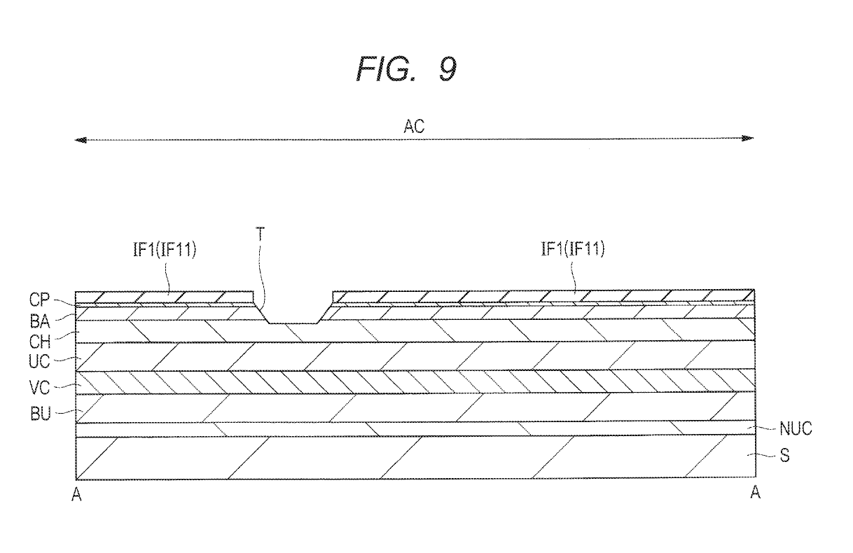

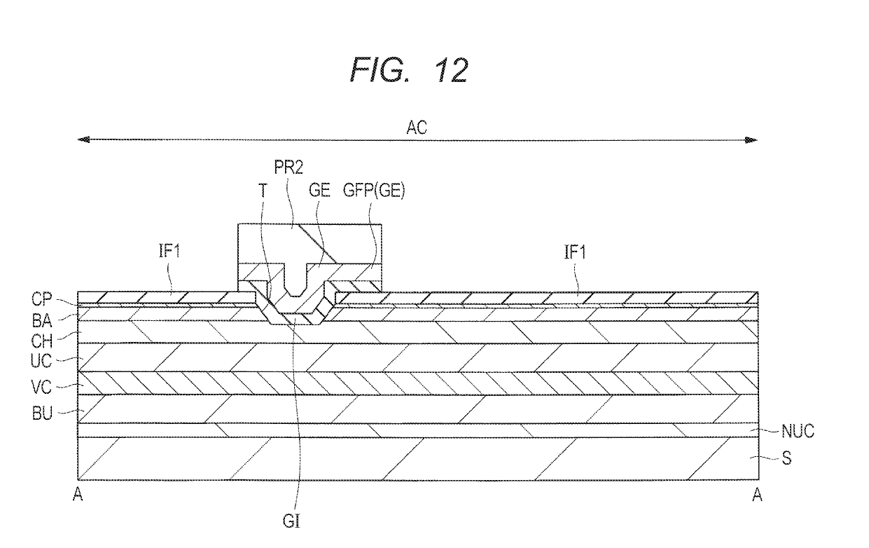

Then, as shown in FIGS. 9 to 11, using a photolithography technology and an etching technology, the insulation film IF1 is patterned. For example, a photoresist film (not shown) is formed over the insulation film IF1. The photoresist film (not shown) in the gate electrode (see FIG. 12) forming region is removed by a photolithography treatment. In other words, a photoresist film (not shown) having an opening in the gate electrode GE forming region is formed over the insulation film IF1. Then, using the photoresist film (not shown) as a mask, the insulation film IF1 is etched. When a silicon nitride film is used as the insulation film IF1, dry etching using a dry etching gas including a fluorine type gas such as SF₆ is performed. Then, the photoresist film (not shown) is removed by a plasma ashing treatment, or the like. In this manner, the insulation film IF1 having an opening in the gate electrode GE (see FIG. 12) forming region is formed over the cap layer CP.

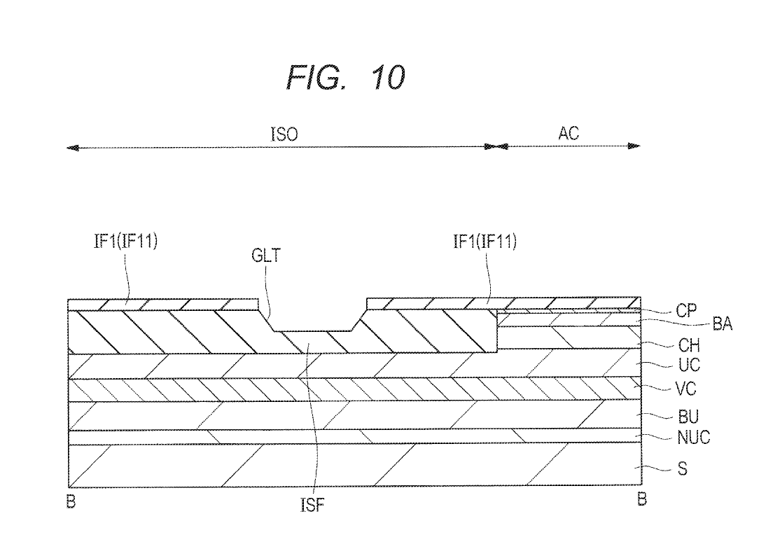

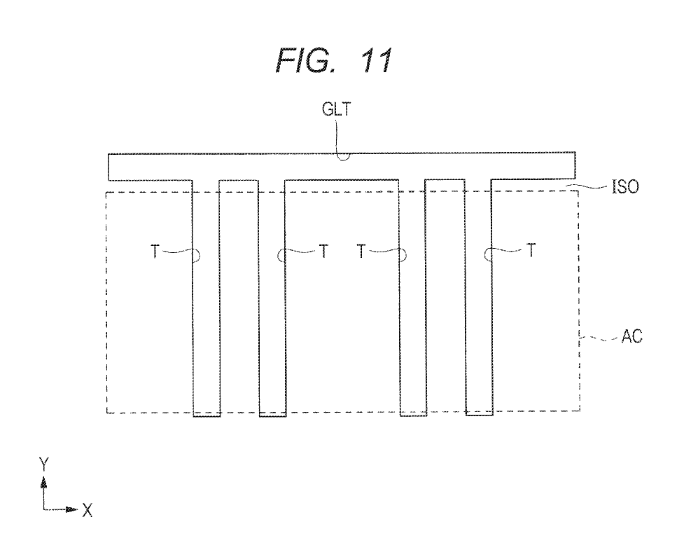

Then, using the insulation film IF1 as a mask, the cap layer CP, the barrier layer BA, and the channel layer CH are dry etched, thereby to form a trench T penetrating through the cap layer CP and the barrier layer BA, and reaching some point of the channel layer CH. A dry etching gas including a chlorine type gas such as BCl₃ is used as the etching gas. At this step, a trench GLT for the gate line GL is formed in the element isolation ISF (see FIGS. 10 and 11).

Then, as shown in FIGS. 12 to 14, over the inner wall of the trench T and the insulation film IF1, a gate insulation film GI is formed. Over the gate insulation film GI, a gate electrode GE is formed. Namely, the gate electrode GE is formed over the potential fixed layer VC. For example, over the inner wall of the trench T and the insulation film IF1, as the gate insulation film GI, an aluminum oxide film is deposited with a film thickness of about 50 nm using an ALD (Atomic Layer Deposition) method, or the like.

As the gate insulation film GI, a silicon oxide film, or a high dielectric constant film higher in dielectric constant than a silicon oxide film may be used other than an aluminum oxide film. A SiN (silicon nitride) film, or a hafnium type insulation film such as a HfO₂ (hafnium oxide) film, a hafnium aluminate film, a HfON (hafnium oxynitride) film, a HfSiO (hafnium silicate) film, a HfSiON (hafnium silicon oxynitride) film, or a HfAlO film may be used as a high dielectric constant film.

Then, for example, over the gate insulation film GI, as a conductive film, for example, a TiN (titanium nitride) film is deposited with a film thickness of about 200 nm using a sputtering method, or the like. Then, using a photolithography technology, a photoresist film PR2 is formed in the gate electrode GE forming region. Using the photoresist film PR2 as a mask, the TiN film is etched. As a result, a gate electrode GE is formed. During the etching, the aluminum oxide film underlying the TiN film may be etched. For example, during processing of the TiN film, dry etching using a dry etching gas containing a chlorine type gas such as Cl₂ is performed. During processing of the aluminum oxide film, dry etching using a dry etching gas containing a chlorine type gas such as BCl₃ is performed.

Further, during the etching, the gate electrode GE is patterned in a shape protruding toward a first side (the right side in FIG. 12, i.e., the drain side). The protrusion part is a gate field plate electrode GFP. The gate field plate electrode GFP is a part of the gate electrode GE extending from the end of the trench T on the drain side further toward the drain side.

Then, as shown in FIGS. 15 to 17, using a photolithography technology and an etching technology, the insulation film IF1 is patterned. As a result, the insulation film IF1 is left at a portion thereof under the gate electrode GE, and at portions thereof adjacent to the gate electrode GE, and the insulation film IF1 is removed at portions thereof apart from the gate electrode GE. When a silicon nitride film is used as the insulation film IF1, dry etching using a dry etching gas containing a fluorine type gas such as CF₄ is performed. Then, a photoresist film (not shown) is removed by a plasma ashing treatment, or the like.

Then, over the cap layer CP, as the insulation film IF2, a silicon nitride film, namely, an insulation film containing silicon and nitrogen is deposited with a film thickness of, for example, about 100 nm using, for example, a PECVD method. The insulation film IF2 is formed over the cap layer CP in such a manner as to cover the insulation film IF1, the gate insulation film GI, and the gate electrode GE. The insulation film IF2 contains hydrogen, namely, an inactivating element in a higher concentration than that of, for example, the insulation film IF1. At this step, the insulation films IF1 and IF2 form the insulation film IF. Namely, the insulation film IF includes the insulation film IF1, and the insulation film IF2 formed over the insulation film IF1. The insulation film IF is formed over the portion PP1 of the potential fixed layer VC situated on the first side with respect to the gate electrode GE in a plan view, and the portion PP2 of the potential fixed layer VC situated on the side opposite to the first side with respect to the gate electrode GE.

Then, over the insulation film IF2, as the insulation film IL1, an insulation film containing silicon and oxygen such as a silicon oxide film is deposited with a thickness of about 500 nm using an atmospheric pressure CVD, or the like.

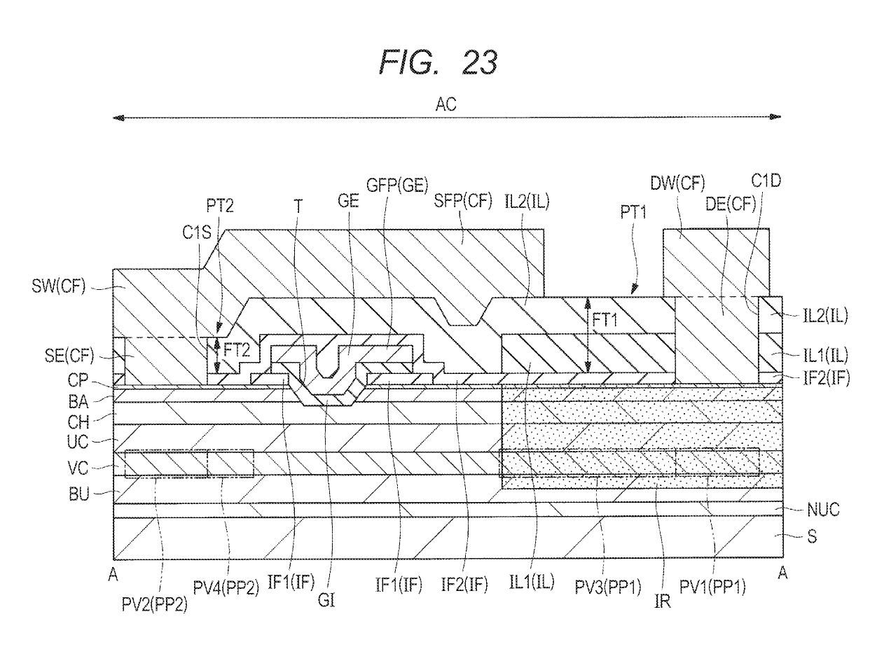

Then, using a photolithography technology and an etching technology, the insulation film IL1 is patterned. Then, of the insulation film IL1, in the drain electrode DE (see FIG. 23) forming region, and the region between the gate electrode GE formation region and the drain electrode DE forming region, the insulation film IL1 is left, and the insulation film IL1 is removed in other regions. Namely, the insulation film IL1 is formed over the portion of the insulation film IF2 situated over the portion PP1, and the insulation film IL1 is not formed over the portion of the insulation film IF2 situated over the portion PP2.

Then, after completion of patterning of the insulation film IL1, the substrate S is subjected to a heat treatment. A heat treatment is performed at 500 to 800° C. for 10 to 60 minutes such as at 500° C. for 30 minutes, for example, in a nitrogen atmosphere.

At this step, on the first side with respect to the gate electrode GE (the left side in FIG. 15, namely, the drain side), the inactivating element such as hydrogen contained in the portion of the insulation film IF2 situated over the portion PP1 is doped into the portion PP1 by diffusion. As a result, the inactivated region IR is formed. On the other hand, on the side opposite to the first side with respect to the gate electrode GE (the left side in FIG. 15, namely, the source side), the inactivating element contained in the insulation film IF2 is released into the nitrogen atmosphere, and is not doped into the portion PP2. As a result, the inactivated region IR is not formed. In other words, the inactivating element is doped into the portion PP2 so that the concentration of the inactivating element in the portion PP2 is lower than the concentration of the inactivating element in the portion PP1. Alternatively, the inactivating element is not doped.

Namely, in the present First Embodiment, of the insulation film IF2 formed over the potential fixed layer VC, and containing an inactivating element, the drain-side portion is covered with the insulation film IL1, and the source-side portion is exposed. In this state, the substrate S is subjected to a heat treatment. As a result, the inactivating element is doped into only the drain-side portion of the potential fixed layer VC.

In accordance with the present First Embodiment, only the drain-side portion of the potential fixed layer VC is inactivated. This eliminates the necessity of ion-implanting an inactivating element. Accordingly, the drain-side potential fixed layer VC can be inactivated without damaging the crystal of the nitride semiconductor layer such as the channel layer CH.

Incidentally, in FIG. 15, the end of the inactivated region IR is angular. However, for example, as shown in FIG. 1, the end of the inactivated region IR may be in a curved shape (the same also applies to other embodiments).

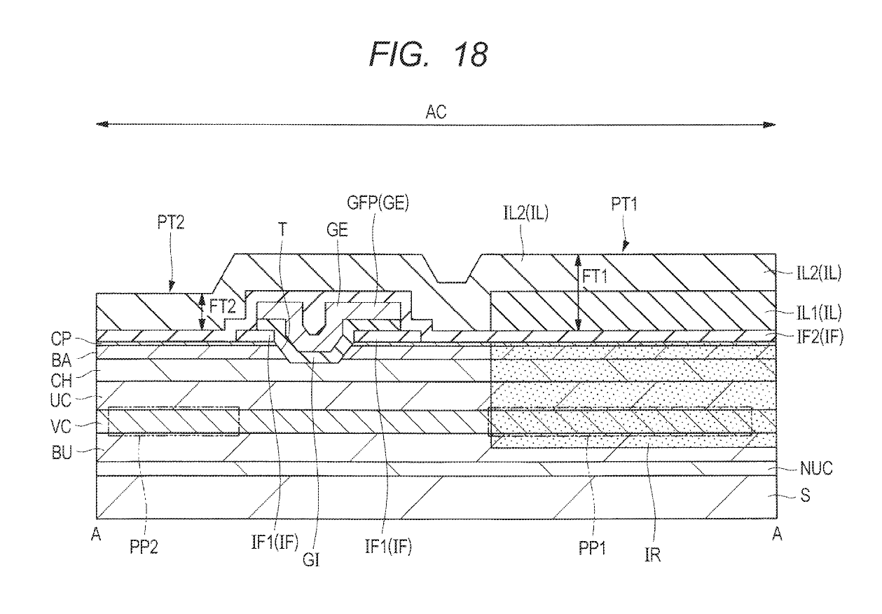

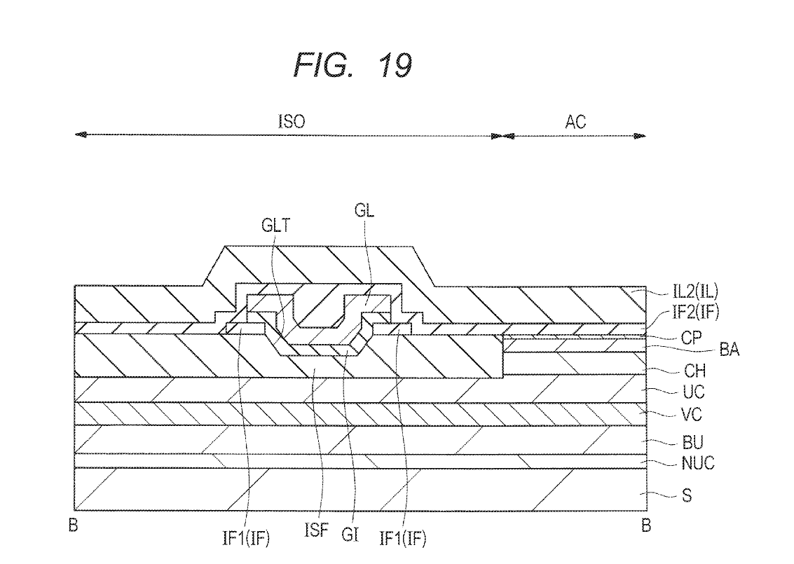

Then, as shown in FIGS. 18 and 19, over the insulation film IF2, and over the insulation film IL1, for example, a silicon oxide film is deposited with a thickness of about 500 nm as the insulation film IL2 by an atmospheric pressure CVD method, or the like. Namely, the insulation film IL2 is formed over the insulation film IF2 in such a manner as to cover the insulation film IL1. The insulation film IL1 and the insulation film IL2 form the interlayer insulation film IL. Namely, the interlayer insulation film IL includes the insulation film IL1 and the insulation film IL2. The film thickness FT1 of the portion PT1 of the interlayer insulation film IL situated between the gate electrode GE and the drain electrode DE (see FIG. 23) is larger than the film thickness FT2 of the portion PT2 of the interlayer insulation film IL situated between the gate electrode GE and the source electrode SE (see FIG. 23).

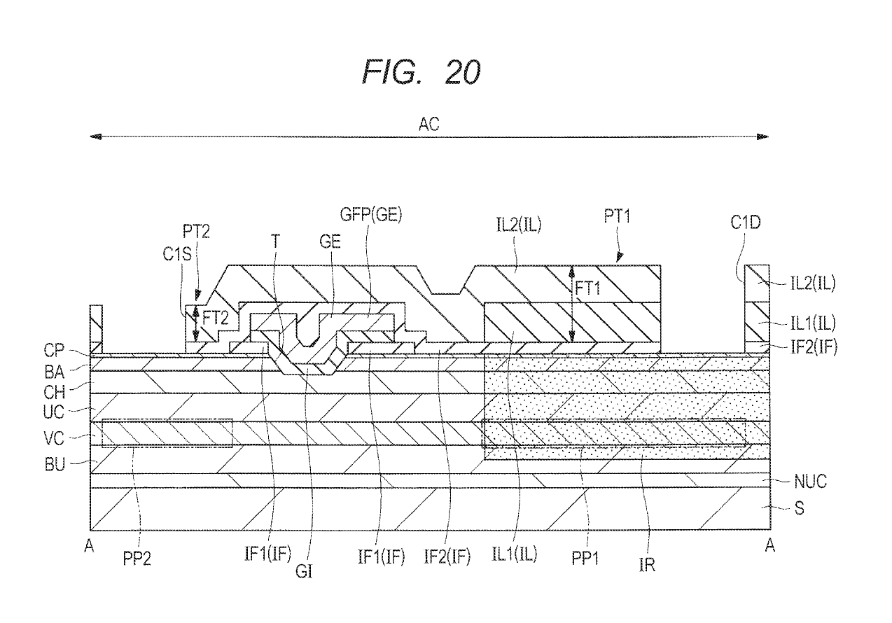

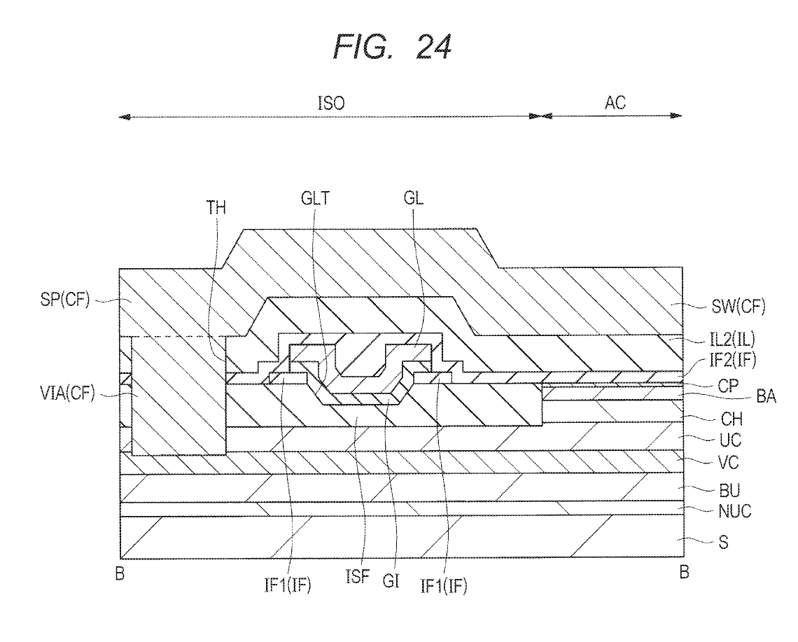

Then, as shown in FIGS. 20 to 22, using a photolithography technology and an etching technology, contact holes C1S and C1D, and a through hole TH are formed in the interlayer insulation film IL and the insulation film IF1. The contact hole C1S is formed over the portion PP2 and in the source electrode SE (see FIG. 23) forming region. The contact hole C1D is formed over the portion PP1, and in the drain electrode DE (see FIG. 23) forming region. Whereas, the through hole TH is formed in the coupling part VIA (see FIG. 24) forming region.

For example, a first photoresist film having openings in respective regions in which the contact hole C1S and the contact hole C1D are respectively formed (not shown) is formed over the interlayer insulation film IL1. Then, using the first photoresist film (not shown) as a mask, the interlayer insulation film IL1 and the insulation film IF1 are etched. As a result, the contact holes C1S and C1D as the hole parts are formed. Namely, the contact hole C1D penetrating through the insulation films IL2, IL1, and IF2 is formed over the portion PP1, and the contact hole C1S penetrating through the insulation films IL2 and IF2 is formed over the portion PP2.

When a silicon oxide film is used as the interlayer insulation film IL1, and a silicon nitride film is used as the insulation film IF1, dry etching using a dry etching gas containing a fluorine type gas such as SF₆ is performed for etching of the films.

Then, after removing the first photoresist film (not shown), a second photoresist film having an opening in the through hole TH forming region is formed over respective insides of the contact holes C1S and C1D and the interlayer insulation film IL1. Then, using the second photoresist film (not shown) as a mask, the interlayer insulation film IL, the insulation film IF2, the element isolation ISF, the channel base layer UC, and a part of potential fixed layer VC are etched. As a result, a through hole TH is formed. In other words, a through hole TH penetrating through the interlayer insulation film IL, the insulation film IF2, the element isolation ISF, and the channel base layer UC, and reaching some point of the potential fixed layer VC is formed.

As described previously, etching is performed so that the bottom of the through hole TH is situated in the potential fixed layer VC, and is situated below the bottom of the element isolation ISF.

When a silicon oxide film is used as the interlayer insulation film IL, and a silicon nitride film is used as the insulation film IF2, first, the films are removed by dry etching using a dry etching gas containing a fluorine type gas such as SF₆. Then, the element isolation ISF, the channel base layer (AlGaN layer) UC, and some part of the potential fixed layer (p-GaN layer) VC are removed by dry etching using a dry etching gas containing a chlorine type gas such as BCl₃.

Incidentally, the formation order of the contact holes C1S and C1D, and the through hole TH is not limited to that described above. After the formation of the through hole TH, the contact holes C1S and C1D may be formed. Thus, the formation steps of the contact holes C1S and C1D, and the through hole TH may assume various steps.

The cap layer CP is exposed from the bottom surfaces of the contact holes C1S and C1D formed in the steps described above, and the potential fixed layer VC is exposed from the bottom surface of the through hole TH.

Then, as shown in FIGS. 23 and 24, the source electrode SE and the drain electrode DE are formed over the cap layer CP on the opposite sides of the gate electrode GE. Further, a source pad SP is formed at the end of the source electrode SE, and a drain pad DP is formed at the end of the drain electrode DE (see FIG. 24). Incidentally, the plan view for forming the source electrode SE and the drain electrode DE can be described by reference to the plan view shown in FIG. 2.

For example, a conductive film CF is formed over respective insides of the contact holes C1S and C1D, and the through hole TH, and the interlayer insulation film IL1. For example, as the conductive film CF, a lamination film (Al/TiN) formed of a titanium nitride (TiN) film and an aluminum (Al) film thereover is formed using a sputtering method, or the like. The titanium nitride film has a film thickness of, for example, about 50 nm. The aluminum film has a film thickness of, for example, about 1000 nm.

Then, using a photolithography technology, a photoresist film (not shown) is formed in the region in which the source electrode SE, the drain electrode DE, the source pad SP, and the drain pad DP (see FIG. 2) are formed. Using the photoresist film (not shown) as a mask, the conductive film CF is etched. Dry etching using a dry etching gas containing a chlorine type gas such as BCl₃ is performed. By this step, a coupling part VIA formed of the conductive film embedded in the through hole TH is formed, and the source electrode SE, the drain electrode DE, the source pad SP, and the drain pad DP are formed. Namely, the drain electrode DE is formed in the contact hole C1D, and the source electrode SE is formed in the contact hole C1S.

Each planar shape of the source electrode SE and the drain electrode DE is a rectangular shape (line shape) having long sides in the Y direction as shown in FIG. 2. Whereas, each planar shape of the source pad SP and the drain pad DP is a rectangular shape (line shape) having long sides in the X direction. The source pad SP is arranged in such a manner as to ensure a coupling among a plurality of source electrodes SE. The drain pad DP is arranged in such a manner as to ensure a coupling among a plurality of drain electrodes DE.

Then, under the source pad SP, the through hole TH is situated, so that the source pad SP and the potential fixed layer VC are electrically coupled with each other via the coupling part VIA (see FIG. 24).

The part of the portion PP1 situated under the drain electrode DE is a portion PV1. The part of the portion PP2 situated between the gate electrode GE and the drain electrode DE is a portion PV3. Further, the part of the portion PP2 situated under the source electrode SE is a portion PV2. The part of the portion PP2 situated between the gate electrode GE and the source electrode SE is a portion PV4.

Then, a protective film (also referred to as an insulation film, a covering film, or a surface protective film) PRO is formed over the interlayer insulation film IL1 including over the source electrode SE, over the drain electrode DE, over the source pad SP, and over the drain pad DP. For example, over the interlayer insulation film IL, as the protective film PRO, for example, a silicon oxynitride (SiON) film is deposited using a sputtering method, or the like (see FIGS. 3 and 4).

By the steps up to this point, it is possible to form a semiconductor device of the present First Embodiment. Incidentally, the steps described above are examples. The semiconductor device of the present First Embodiment may also be manufactured by other steps than the steps described above. For example, after performing the ion implantation of an inactivating element, the gate electrode GE may be formed.

Thus, in accordance with the present First Embodiment, the potential fixed layer VC which is a conductive layer is provided between the buffer layer BU and the channel layer CH, and is coupled with the source electrode SE. This can reduce the characteristic variations of the semiconductor element. Namely, the potential fixed layer VC can prevent a change in potential due to a change in charge amount of the layers below this layer (e.g., the buffer layer BU) from affecting even the channel layer CH. This can reduce the variations in characteristics such as the threshold potential or the ON resistance.

Further, in the present First Embodiment, a p type nitride semiconductor layer is used as the potential fixed layer VC. Accordingly, when the drain electrode DE is applied with a positive potential (positive bias), the potential fixed layer VC is depleted, resulting in a high resistance layer. This can suppress the deterioration of, or can improve the drain breakdown voltage.

Further, in the present First Embodiment, the coupling part VIA in the through hole TH is arranged in the element isolation region ISO outside the active region AC in which electrons are conducted, and under the source pad SP. As a result, it is possible to implement miniaturization or high integration of semiconductor elements. Further, it is possible to ensure a large active region AC in which electrons can be conducted. For this reason, it is possible to reduce the ON resistance per unit area.

For example, when an impurity such as Fe is doped into the buffer layer for achieving a higher breakdown voltage (see Patent Document 1), the Fe forms a deep level. Such a deep level serves as the base point for trapping or releasing electrons or holes during the operation of a semiconductor element, and hence causes the variations in characteristics such as the threshold potential. Particularly, when the level is deep, the deep level may cause variations in characteristics such as the threshold potential during a period as very long as several minutes to several days according to the energy depth or position.

In contrast, in the present First Embodiment, the potential fixed layer VC which is a conductive layer is provided between the buffer layer BU and the channel layer CH, and is coupled with the source electrode SE. This can reduce the characteristic variations of the semiconductor element.

Whereas, when a superlattice structure is used as the buffer layer BU, the superlattice structure becomes a very deep quantum well (a very high barrier against the movement of electrons or holes). For this reason, when electric charges such as electrons or holes are trapped in the vicinity of the superlattice structure, it becomes difficult for the electric charges to move in the vertical direction to the substrate. Accordingly, when a superlattice structure is used, unnecessary electric charges are difficult to remove. This may cause variations in characteristics such as the threshold potential during a very long period.

In contrast, in the present First Embodiment, the potential fixed layer VC which is a conductive layer is provided between the buffer layer BU and the channel layer CH, and is coupled with the source electrode SE. This can reduce the characteristic variations of the semiconductor element.

Further, when a plasma treatment is performed during the manufacturing steps, electric charges tend to be doped into the semiconductor layer. Examples of the plasma treatment include PECVD, or the plasma ashing treatment of a photoresist film. The electric charges doped during such a treatment may cause variations in characteristics such as the threshold potential. Particularly, a nitride semiconductor has a large bandgap, and also a high insulation property. For this reason, the electric charges doped by a plasma treatment, or the like are less likely to be drained. This may also cause variations in characteristics such as the threshold potential during a very long period.

In contrast, in the present First Embodiment, the potential fixed layer VC which is a conductive layer is provided between the buffer layer BU and the channel layer CH, and is coupled with the source electrode SE. This can reduce the characteristic variations of the semiconductor element.

Further, in the present First Embodiment, an inactivated region IR is provided at the potential fixed layer VS under the drain electrode DE, and between the gate electrode GE and the drain electrode DE. Provision of such an inactivated region IR can improve the drain breakdown voltage.

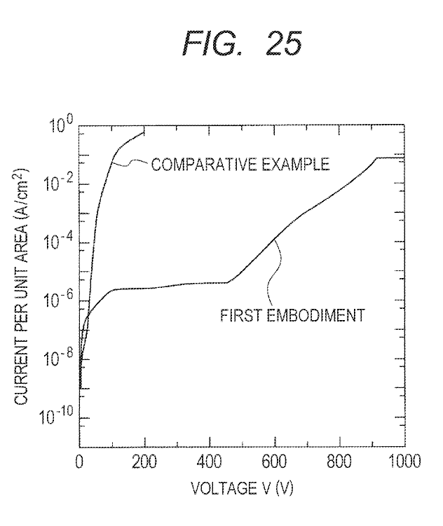

FIG. 25 is a graph showing the current voltage characteristics between the drain electrode and the source electrode in the semiconductor device of First Embodiment. The horizontal axis of FIG. 25 indicates the voltage V between the drain electrode and the source electrode. The vertical axis of FIG. 25 indicates the current I between the drain electrode and the source electrode as the current per unit area. FIG. 25 also shows the current voltage characteristics between the drain electrode and the source electrode in a semiconductor device of Comparative Example. In the manufacturing steps of the semiconductor device of Comparative Example, in the steps described by reference to FIGS. 15 to 17, a heat treatment is performed with the insulation film IL1 not formed. Incidentally, FIG. 25 shows the following cases: in the semiconductor devices of First Embodiment and Comparative Example, the potential fixed layer VC is doped with Mg as a p type impurity in a concentration of 5×10¹⁸ cm⁻³, and in both of First Embodiment and Comparative Example, a heat treatment at 550° C. for 30 minutes is performed in the steps described by reference to FIGS. 15 to 17.

In the manufacturing steps of the semiconductor device of Comparative Example, in the steps described by reference to FIGS. 15 to 17, a heat treatment is performed in, for example, a nitrogen atmosphere in the following state: neither of the insulation films IF2 on the drain side and the source side with respect to the gate electrode GE is covered with the insulation film IL1, and both of the insulation films IF2 are exposed at the outermost surface. Accordingly, at both of the drain side and the source side, the inactivating element such as hydrogen contained in the insulation film IF2 is released into the nitrogen atmosphere, and becomes less likely to be doped into the potential fixed layer VC. Namely, in the semiconductor device of Comparative Example, the inactivated region IR is not formed, or the p type impurity is not sufficiently inactivated in the inactivated region IR. Therefore, the drain breakdown voltage tends to be reduced, and the potential fixed layer VC with an electric potential equal to the electric potential of the source electrode SE is present to the vicinity of the drain electrode DE. For this reason, the capacitance between the source electrode SE and the drain electrode DE tends to increase, and the semiconductor device is less likely to be operated at a high speed.

In contrast, in the present First Embodiment, during the steps described by reference to FIGS. 15 to 17, a heat treatment is performed in, for example, a nitrogen atmosphere in the following state: the insulation film IF2 on the drain side with respect to the gate electrode GE is covered with the insulation film IL1, and is not exposed at the outermost surface. Accordingly, on the source side with respect to the gate electrode GE, the inactivating element such as hydrogen contained in the insulation film IF2 is released into the nitrogen atmosphere, and is not doped into the potential fixed layer VC. In contrast, on the drain side, the inactivating element such as hydrogen contained in the insulation film IF2 is not released into the nitrogen atmosphere, and is doped into the potential fixed layer VC. Therefore, it is possible to form the inactivated region IR on the drain side with reliability.

Therefore, in the present First Embodiment, while keeping the concentration of the p type impurity high on the source side, the p type impurity can be inactivated on the drain side. For this reason, the drain breakdown voltage can be improved, and the capacitance between the source electrode SE and the drain electrode DE can be reduced. This facilitates the high speed operation of the semiconductor device.

Further, the p type potential fixed layer VC in the region affecting the drain breakdown voltage can be thus inactivated. Accordingly, it becomes possible to raise the p type impurity concentration (acceptor concentration) on the source side independently of the breakdown voltage. For this reason, while keeping the breakdown voltage on the drain side, the electric charges such as electrons or holes can be removed to suppress the variations in the characteristics such as the threshold potential.

Particularly, as described previously, when a p type nitride semiconductor layer is used as the potential fixed layer VC, the potential fixed layer VC is depleted, and becomes a high resistance layer with the drain electrode DE applied with a positive potential (positive bias). For this reason, the conductivity type of the impurity of the potential fixed layer is preferably set as a p type. Further, Mg is useful as the p type impurity, and H is preferable as the inactivating element for reducing the activation ratio of Mg. Particularly, H has a small atomic weight, and hence can be implanted into a deep layer with ease, and is preferably used as an inactivating element.

Further, it is possible to individually control the drain-side p type impurity concentration (acceptor concentration) and the source-side p type impurity concentration (acceptor concentration). This enables an increase in thickness of the p type potential fixed layer VC. Thus, it is possible to reduce the coupling resistance between the p type potential fixed layer VC and the coupling part VIA. Further, it is possible to increase the process margin for forming the through hole TH in which the coupling part VIA is embedded by etching.

Incidentally, in FIG. 3, the end of the inactivated region IR on the source electrode SE side is arranged between the end of the gate electrode GE on the drain electrode DE side and the end of the source field plate electrode SFP on the drain electrode DE side. As a result, it is possible to surely form the inactivated region IR at the portion of the potential fixed layer VC situated on the drain side with respect to the source field plate electrode SFP in a plan view. However, the end of the inactivated region IR on the source electrode SE side may be allowed to correspond to the end of the gate electrode GE on the drain electrode DE side. Alternatively, the end of the inactivated region IR on the source electrode SE side may be arranged between the end of the trench T on the drain electrode DE side and the end of the gate electrode GE on the drain electrode DE side. Further, the end of the inactivated region IR on the source electrode SE side may be allowed to correspond to the end of the trench T on the drain electrode DE side (the same also applies to the following embodiments).

### Modified Example of First Embodiment

In the semiconductor device (see FIG. 1), a coupling part VIA is provided. The potential fixed layer VC is coupled with the source electrode SE via the coupling part VIA. However, the formation of the coupling part VIA may be omitted.

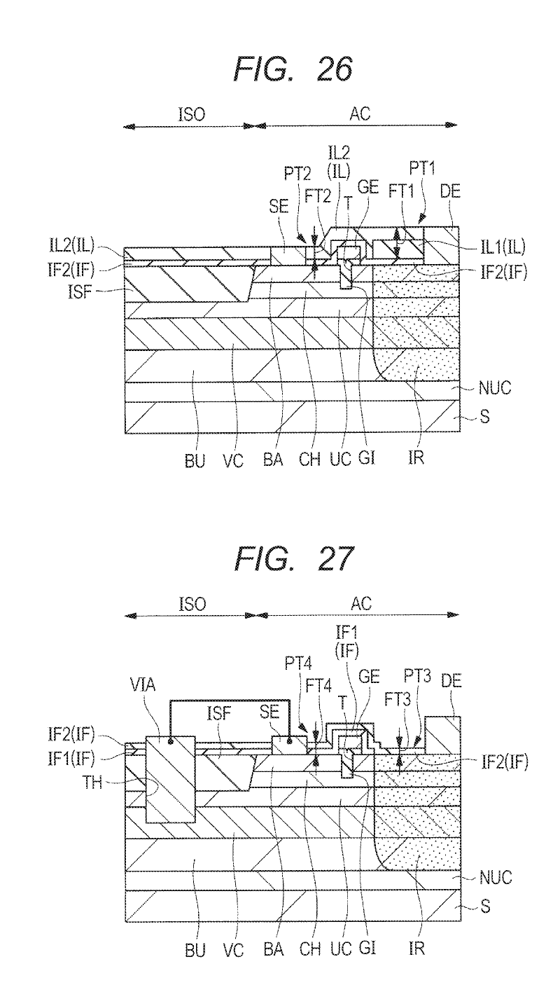

FIG. 26 is a cross sectional view schematically showing a configuration of the semiconductor device of Modified Example of First Embodiment.

The semiconductor device of the present modified example has a substrate S as with First Embodiment. Over the substrate S, a nucleation layer NUC, a buffer layer BU, a p type potential fixed layer VC, a channel base layer UC, a channel layer CH, and a barrier layer BA are sequentially formed. A two-dimensional electron gas is generated on the channel layer CH side in the vicinity of the interface between the channel layer CH and the barrier layer BA. Whereas, when the gate electrode GE is applied with a positive potential (threshold potential), a channel is formed in the vicinity of the interface between the gate insulation film GI and the channel layer CH.

In the present modified example, although the p type potential fixed layer VC is provided, the p type potential fixed layer VC is not fixed at the source potential. Only by thus arranging the p type potential fixed layer VC at a layer below the channel layer CH, it is possible to reduce the effects of the electric charges such as electrons or holes on the end of the gate electrode GE on the source electrode SE side which is the portion most affecting the threshold potential. As a result, it is possible to suppress the variations in the characteristics such as the threshold potential. However, when the electric potential of the p type potential fixed layer VC is fixed, the effective p type impurity concentration (acceptor concentration) becomes higher, resulting in a larger electric charge removing effect.

Accordingly, also when the coupling part VIA is not provided, the p type impurity of the potential fixed layer VC on the drain side is inactivated while increasing the p type impurity concentration (acceptor concentration) of the potential fixed layer VC on the source side. As a result, the breakdown voltage of the drain side can be improved while keeping the electric charge removing effect.

### Second Embodiment

In First Embodiment, the inactivating element was not doped from the portion of the insulation film containing the inactivating element exposed at the outermost surface into the potential fixed layer. However, the following is also acceptable: another insulation film is formed under a part of the insulation film containing the inactivating element, thereby to prevent the potential fixed layer from being doped with the inactivating element.

[Structure Description]

FIG. 27 is a cross sectional view schematically showing a configuration of the semiconductor device of Second Embodiment. Incidentally, the present Second Embodiment is the same as First Embodiment except for the configuration of the gate insulation film GI. For this reason, a detailed description on the same configuration will be omitted.

The semiconductor device (semiconductor element) of the present Second Embodiment has a substrate S as with First Embodiment. Over the substrate S, the nucleation layer NUC, the buffer layer BU, the potential fixed layer VC, the channel base layer UC, the channel layer CH, and the barrier layer BA are sequentially formed.

Over the barrier layer BA, an insulation film IF is formed. Incidentally, a cap layer may be provided between the insulation film IF and the barrier layer BA. The cap layer is formed of a nitride semiconductor layer larger in electron affinity than the barrier layer BA.

The semiconductor device of the present Second Embodiment has, as with First Embodiment, a gate electrode GE formed over the barrier layer BA via a gate insulation film GI, and a source electrode SE and a drain electrode DE formed over the barrier layer BA on the opposite sides of the gate electrode GE. Further, the gate insulation film GI is formed at the inner wall of the trench T penetrating through the barrier layer BA, and reaching some point of the channel layer CH. The gate electrode GE is formed over the gate insulation film GI.

In the present Second Embodiment, a coupling part VIA as an electrode penetrating through the element isolation ISF, and reaching the potential fixed layer VC thereunder is provided in the element isolation region ISO. The coupling part VIA is electrically coupled with the source electrode SE. Further, the coupling part VIA is in contact with the potential fixed layer VC. Thus, the potential fixed layer VC is provided, and coupled with the source electrode SE. This can reduce the variations in characteristic such as the threshold potential or the ON resistance.

Further, in the present Second Embodiment, the coupling part VIA in the through hole TH is arranged in the element isolation region ISO outside the active region AC in which electrons are conducted, and under the source pad SP (see FIG. 2). As a result, it is possible to implement miniaturization or high integration of semiconductor elements. Further, it is possible to ensure a large active region AC in which electrons can be conducted. For this reason, it is possible to reduce the ON resistance per unit area.

Further, in the present Second Embodiment, the inactivated region IR is provided under the drain electrode DE, and between the gate electrode GE and the source electrode SE. Provision of such an inactivated region IR can improve the drain breakdown voltage. The activation ratio of the inactivated region IR is smaller than, and is preferably set at 1/10 or less the activation ratio of the region other than the inactivated region IR.

In the present Second Embodiment, an insulation film IF is formed over the barrier layer BA between the gate electrode GE and the drain electrode DE, and between the gate electrode GE and the source electrode SE. The the film thickness FT3 of the portion PT3 of the insulation film IF situated between the gate electrode GE and the drain electrode DE is smaller than the film thickness FT4 of the portion PT4 of the insulation film IF situated between the gate electrode GE and the source electrode SE.

For example, an insulation film IF1 not containing hydrogen, or containing hydrogen in a lower concentration than the concentration of the hydrogen in the insulation film IF2 is formed over the barrier layer BA. At this step, between the gate electrode GE and the source electrode SE, the insulation film IF1 is formed over the barrier layer BA. However, between the gate electrode GE and the drain electrode DE, the insulation film IF1 is not formed over the barrier layer BA.

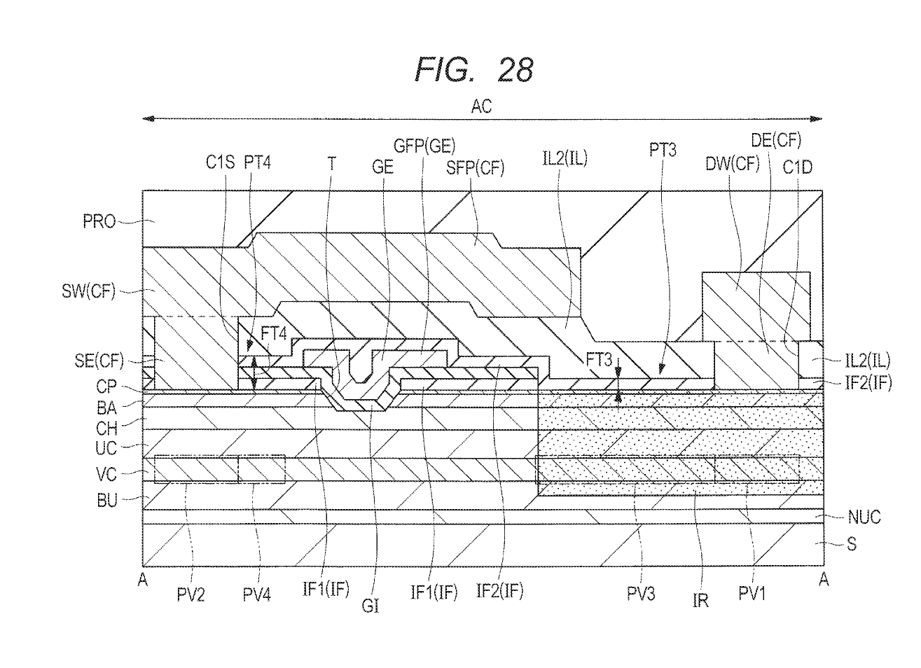

Then, after the formation of the insulation film IF1, an insulation film IF2 containing silicon, nitrogen, and hydrogen such as a silicon nitride film containing hydrogen is formed over the insulation film IF1. At this step, between the gate electrode GE and the source electrode SE, the insulation film IF2 is formed over the barrier layer BA via the insulation film IF1, and between the gate electrode GE and the drain electrode DE, the insulation film IF2 is formed over the barrier layer BA not via the insulation film IF1. Subsequently, an interlayer insulation film IL (see FIG. 28 described later) is formed over the insulation film IF2. Then, after the formation of the interlayer insulation film IL, the substrate S is heat treated. As a result, the hydrogen contained in the insulation film IF2 is doped into the potential fixed layer VC.

As a result, as compared with the case where the potential fixed layer VC is doped with an inactivating element by ion implantation, the drain-side potential fixed layer VC can be inactivated without more breaking the crystals of the nitride semiconductor layers such as the channel layer CH.

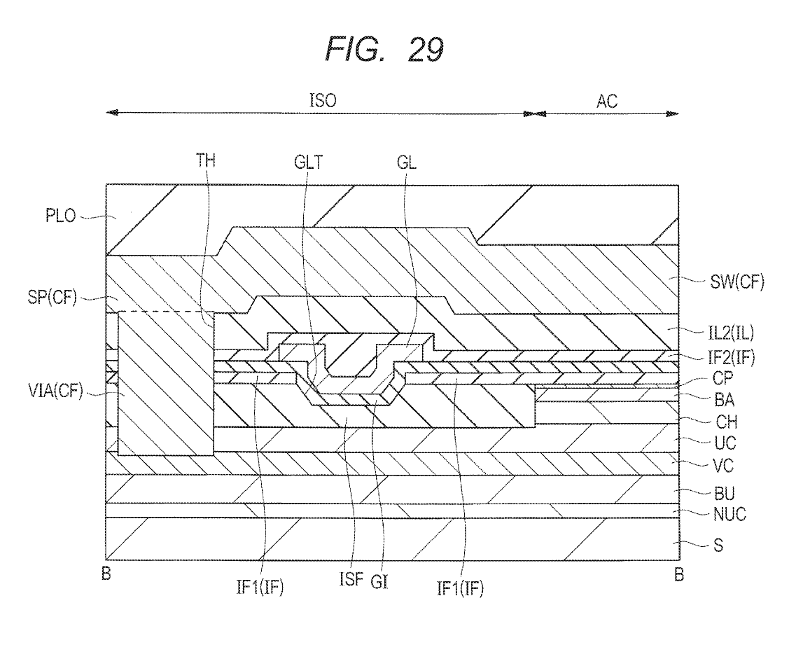

Then, with reference to FIGS. 28 and 29, the semiconductor device of the present Second Embodiment will be described in more details. FIGS. 28 and 29 are each a cross sectional view showing a configuration of the semiconductor device of Second Embodiment. Incidentally, the plan view showing the configuration of the semiconductor device of the present Second Embodiment can be set equal to FIG. 2. FIG. 28 corresponds to the A-A cross section of FIG. 2. FIG. 29 corresponds to the B-B cross section of FIG. 2.

As shown in FIGS. 28 and 29, the semiconductor device of the present Second Embodiment has a substrate S as with First Embodiment. The nucleation layer NUC, the buffer layer BU, the potential fixed layer VC, the channel base layer UC, the channel layer CH, and the barrier layer BA are sequentially formed over the substrate S. Respective thicknesses and constituent materials of the substrate S, the nucleation layer NUC, the buffer layer BU, the potential fixed layer VC, the channel base layer UC, the channel layer CH, and the barrier layer BA are as described in First Embodiment.

As the gate insulation film GI, an aluminum oxide (Al₂O₃) film can be used. The thickness of the aluminum oxide film is, for example, about 50 nm. As the gate insulation film GI, an insulation film other than an aluminum oxide film may be used. Alternatively, a lamination structure of several kinds of insulation films may be adopted. Incidentally, the gate insulation film GI may be left between the insulation film IF1 and the insulation film IF2.

As the gate electrode GE, a titanium nitride (TiN) film can be used. The thickness of the titanium nitride film is, for example, about 200 nm. As the gate electrode GE, a conductive film other than a titanium nitride film may be used.

Over the gate electrode GE, an interlayer insulation film IL is arranged via the insulation film IF2. The interlayer insulation film IL has a through hole TH, and contact holes C1S and C1D. The source pad SP and the drain pad DP (see FIG. 2) are formed integrally with the source electrode SE and the drain electrode DE, respectively. Accordingly, the source pad SP and the drain pad DP are formed of the same materials of the source electrode SE and the drain electrode DE, respectively. Under the source pad SP, a coupling part VIA is arranged (see FIG. 29). Further, over the source electrode SE and the drain electrode DE, a protective film PRO is arranged.

In the present Second Embodiment, as with First Embodiment, an inactivated region IR is provided under the drain electrode DE, and between the gate electrode GE and the drain electrode DE. The inactivated region IR reaches the potential fixed layer VC in the depth direction. Provision of such an inactivated region IR can improve the drain breakdown voltage.

Specifically, as with First Embodiment, the content of the inactivating element in the portion PV1 of the potential fixed layer VC situated under the drain electrode DE is larger than the content of the inactivating element in the portion PV2 of the potential fixed layer VC situated under the source electrode SE. Alternatively, the content of the inactivating element in the portion PV3 of the potential fixed layer VC situated between the gate electrode GE and the drain electrode DE is larger than the content of the inactivating element in the portion PV4 of the potential fixed layer VC situated between the gate electrode GE and the source electrode SE.

In the present Second Embodiment, the insulation film IF includes an insulation film IF1 and an insulation film IF2. The insulation film IF1 is formed between the gate electrode GE and the source electrode SE. The insulation film IF2 is formed between the gate electrode GE and the drain electrode DE, and between the gate electrode GE and the source electrode SE. Whereas, the insulation film IF2 is formed over the insulation film IF1 between the gate electrode GE and the source electrode SE.

Accordingly, the film thickness FT3 of the portion PT3 of the insulation film IF situated between the gate electrode GE and the drain electrode DE is smaller than the film thickness FT4 of the portion PT4 of the insulation film IF situated between the gate electrode GE and the source electrode SE. Namely, the film thickness FT3 is different from the film thickness FT4. Whereas, the height position of the top surface of the portion PT3 is lower than the height position of the top surface of the portion PT4.

The interlayer insulation film IL includes an insulation film IL2. The insulation film IL2 is formed between the gate electrode GE and the drain electrode DE, and contains silicon and oxygen. Between the gate electrode GE and the drain electrode DE, the insulation film IL2 is formed over the insulation film IF2. Incidentally, the insulation film IL2 is formed between the gate electrode GE and the source electrode SE, and also over the gate electrode GE.

The insulation film IL2 is formed of, for example, a silicon oxide film. Namely, the insulation film IL2 contains silicon and oxygen.

For example, between the gate electrode GE and the source electrode SE, the insulation film IF1 is formed as a part of the insulation film IF over the barrier layer BA. At this step, between the gate electrode GE and the drain electrode DE, the insulation film IF1 is not formed over the barrier layer BA. Subsequently, over the insulation film IF1, the insulation film IF2 containing silicon, nitrogen, and hydrogen such as a silicon nitride film containing hydrogen is formed as a part of the insulation film IF. At this step, between the gate electrode GE and the source electrode SE, the insulation film IF2 is formed over the barrier layer BA via the insulation film IF1. However, between the gate electrode GE and the drain electrode DE, the insulation film IF2 is formed over the barrier layer BA not via the insulation film IF1. Then, after the formation of the insulation film IF2, the insulation film IL2 is formed over the insulation film IF2. After the formation of the insulation film IL2, the substrate S is heat treated. As a result, the hydrogen contained in the insulation film IF2 is doped into the potential fixed layer VC.

As a result, as compared with the case where the potential fixed layer VC is doped with an inactivating element by ion implantation, the drain-side potential fixed layer VC can be inactivated without more breaking the crystals of the nitride semiconductor layers such as the channel layer CH.

Further, in the present Second Embodiment, the portion of the insulation film IF2 formed between the gate electrode GE and the drain electrode DE, namely, the portion PT3 contains an inactivating element. The insulation film IF1 contains an inactivating element in a lower concentration than the concentration of the inactivating element in the portion PT3, or does not contain an inactivating element. This is due to the following: for example, after the formation of the insulation film IF1 containing an inactivating element, the substrate S is heat treated; as a result, the inactivating element contained in the insulation film IF1 is released.

Incidentally, in the present Second Embodiment, the film thickness FT3 of the portion PT3 is smaller than the film thickness FT4 of the portion PT4. For this reason, the depth dimension of the contact hole C1D is smaller than the depth dimension of the contact hole C1S. For this reason, the height dimension of the drain electrode DE is smaller than the height dimension of the source electrode SE.

[Manufacturing Method Description]

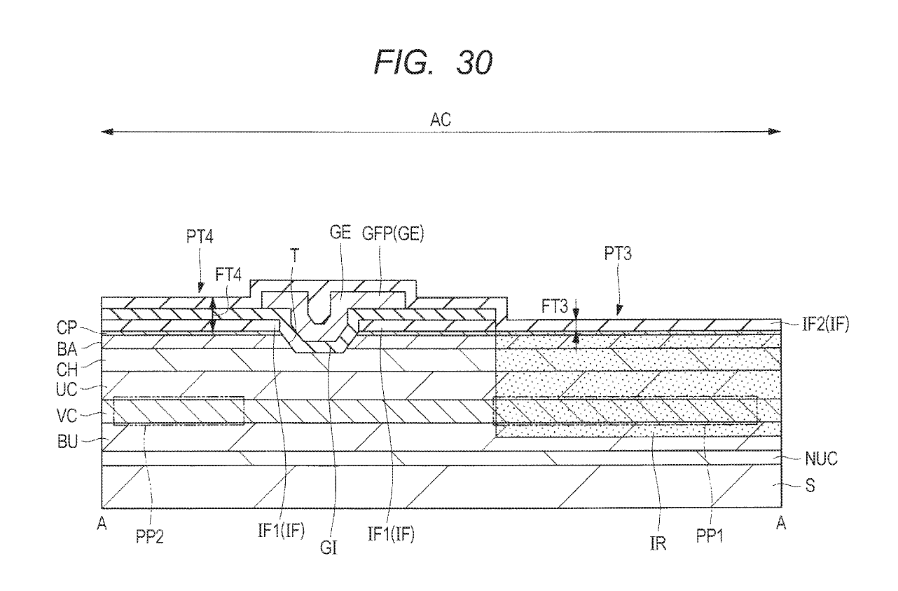

Then, with reference to FIGS. 30 to 37, a description will be given to a method for manufacturing the semiconductor device of the present Second Embodiment. In addition, the configuration of the semiconductor device will be made clearer. FIGS. 30 to 37 are each a cross sectional view showing the semiconductor device of the present Second Embodiment during a manufacturing step. Incidentally, other steps than the step of forming the inactivated region IR are the same as those of First Embodiment. For this reason, the step of forming the inactivated region IR will be mainly described in details.

First, as with First Embodiment, the same step as the step described by reference to FIG. 5 is performed, thereby to provide a substrate S. Over the provided substrate S, a nucleation layer NUC, a buffer layer BU, a potential fixed layer VC, a channel base layer UC, a channel layer CH, a barrier layer BA, and a cap layer CP are sequentially formed. These can be formed using the materials described in First Embodiment in the same manner as in First Embodiment.

Then, as with First Embodiment, the same steps as the steps described by reference to FIGS. 6 to 8 are performed. As a result, an insulation film IF1 is formed over the cap layer CP.

The insulation film IF1 contains hydrogen in a lower concentration than the concentration of hydrogen in the insulation film IF2 (see FIG. 30), or does not contain hydrogen as with First Embodiment. Such an insulation film IF1 can be formed in the following manner: an insulation film IF11 containing hydrogen in a high concentration is formed; the substrate S is subjected to a heat treatment with the insulation film IF11 exposed at the outermost surface; as a result, the hydrogen contained in the insulation film IF11 is released; as a result, it is possible to form an insulation film IF1 containing hydrogen in a low concentration. Namely, over at least the portion of the potential fixed layer VC situated on the source side with respect to the gate electrode GE (see FIG. 30), an insulation film IF11 containing an inactivating element is formed. Then, the substrate S is heat treated. As a result, the concentration of the inactivating element in the insulation film IF11 is reduced. At this step, the concentration of the inactivating element in the insulation film IF11 is reduced so that the concentration of the inactivating element in the insulation film IF11 is lower than the concentration of the inactivating element in the insulation film IF2.

Alternatively, as described by reference to FIG. 38 described later, an insulation film IF12 containing hydrogen in a low concentration, or not containing hydrogen may be formed, thereby to form the insulation film IF11 formed of the insulation film IF12.

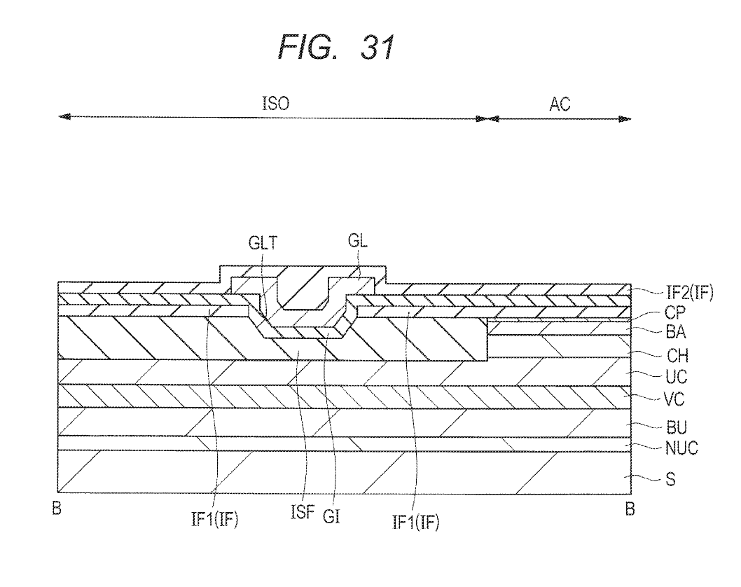

Then, as shown in FIGS. 30 and 31, as with First Embodiment, an element isolation ISF is formed in the element isolation region ISO. Then, a trench T is formed. At this step, in the element isolation region ISO, a trench GLT for the gate line GL is formed in the element isolation ISF.

Then, over the inner wall of the trench T, and the insulation film IF1, a gate insulation film GI is formed. Over the gate insulation film GI, as a conductive film CF, for example, a titanium nitride (TiN) film is deposited with a film thickness of about 200 nm using a sputtering method, or the like.

Then, over the conductive film CF, a photoresist film (not shown) is formed. Using a photolithography technology, the photoresist film (not shown) is left only in the gate electrode GE forming region. Then, using the photoresist film (not shown) as a mask, the conductive film CF is etched, thereby to form the gate electrode GE. Namely, the gate electrode GE is formed over the potential fixed layer VC. During the etching, the gate insulation film (aluminum oxide film) underlying the TiN film is left without being etched. For processing of the TiN film, a dry etching gas containing a chlorine type gas such as Cl₂ is used.

Then, using a photolithography technology and an etching technology, the gate insulation film GI and the insulation film IF1 are patterned. Then, of the gate insulation film GI and the insulation film IF1, the portions formed over the portions of the cap layer CP adjacent to the gate electrode GE, and the portion arranged on the source side with respect to the gate electrode GE are left. Of the gate insulation film GI and the insulation film IF1, the portion arranged on the drain side with respect to the gate electrode GE is removed. Namely, the insulation film IF1 is not formed over the portion PP1 of the potential fixed layer VC situated on the first side with respect to the gate electrode GE in a plan view, and is formed over the portion PP2 of the potential fixed layer VC situated on the side opposite to the first side with respect to the gate electrode GE in a plan view. Patterning of the insulation film IF1 can be performed in the same manner as the manner in First Embodiment.

Then, over the cap layer CP, as the insulation film IF2, a silicon nitride film, namely, an insulation film containing silicon and nitrogen is deposited with a film thickness of, for example, about 100 nm using, for example, a PECVD method. The insulation film IF2 is formed over the cap layer CP in such a manner as to cover the insulation film IF1, the gate insulation film GI, and the gate electrode GE. The insulation film IF2 contains hydrogen, namely, an inactivating element in a higher concentration than that of, for example, the insulation film IF1. At this step, the insulation films IF1 and IF2 form the insulation film IF. Namely, the insulation film IF includes the insulation film IF1, and the insulation film IF2 formed over the insulation film IF1.

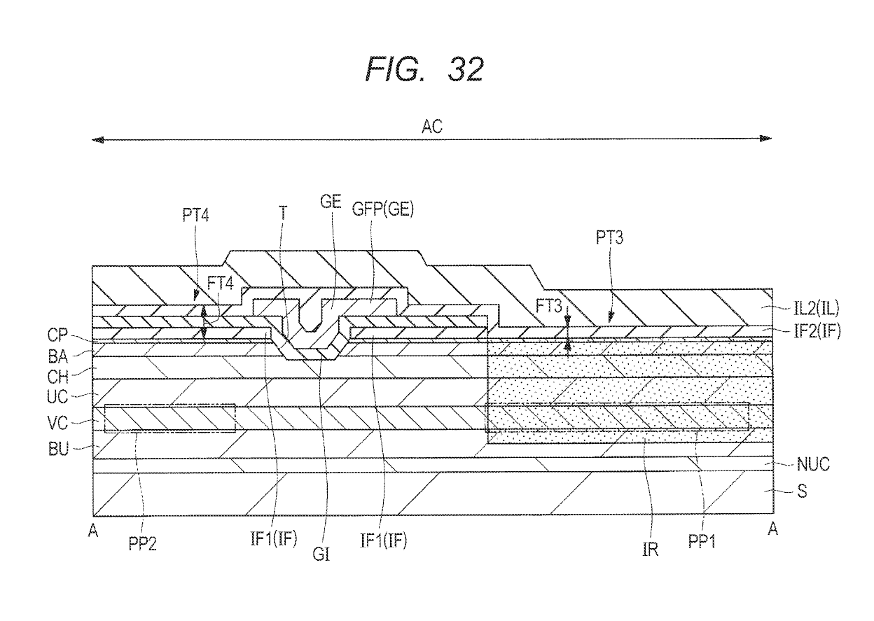

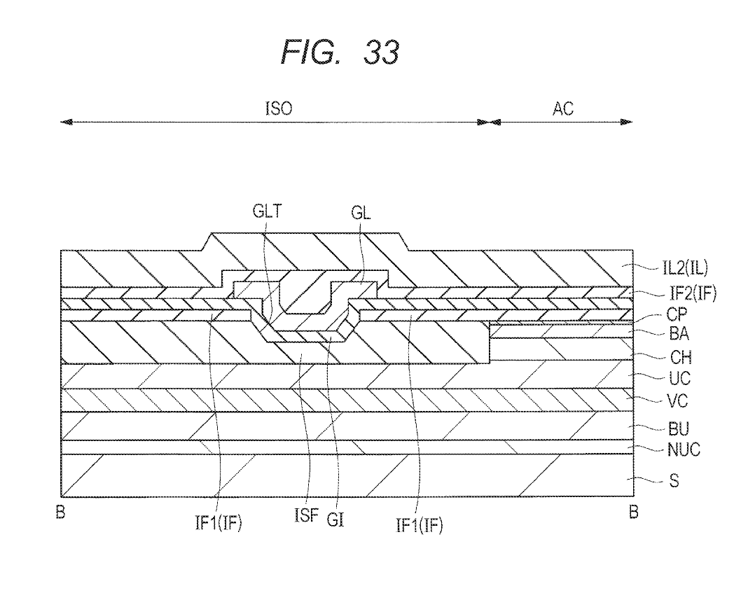

Then, as shown in FIGS. 32 and 33, over the insulation film IF2, as the insulation film IL2, for example, a silicon oxide film is deposited with a thickness of about 500 nm using an atmospheric pressure CVD method, or the like. At this step, an interlayer insulation film IL formed of the insulation film IL2 is formed. Incidentally, it is essential only that the insulation film IL2 is formed at least over the portion PP1 of the insulation film IF2.

Then, the substrate S is subjected to a heat treatment. For example, a heat treatment is performed at 500 to 800° C. for 10 to 60 minutes such as at 500° C. for 30 minutes, for example, in a nitrogen atmosphere.

At this step, on the first side with respect to the gate electrode GE (the right side in FIG. 32, namely, the drain side), the inactivating element such as hydrogen contained in the portion of the insulation film IF2 situated over the portion PP1 is doped into the portion PP1 by diffusion. As a result, the inactivated region IR is formed. On the other hand, on the side opposite to the first side with respect to the gate electrode GE (the left side in FIG. 32, namely, the source side), the inactivating element contained in the portion of the insulation film IF2 situated over the portion PP2 is inhibited by the insulation film IF1, and is not doped into the portion PP2. As a result, the inactivated region IR is not formed. In other words, the inactivating element is doped into the portion PP2 so that the concentration of the inactivating element in the portion PP2 is lower than the concentration of the inactivating element in the portion PP1. Alternatively, the inactivating element is not doped.

Namely, in the present Second Embodiment, of the insulation film IF2 formed over the potential fixed layer VC, and containing an inactivating element, the drain-side portion is in contact with the cap layer CP, and the source-side portion is not in contact with the cap layer CP. In this state, the substrate S is subjected to a heat treatment. As a result, the inactivating element is doped into only the drain-side portion of the potential fixed layer VC.

In accordance with the present Second Embodiment, only the drain-side portion of the potential fixed layer VC is inactivated. This eliminates the necessity of ion-implanting an inactivating element. Accordingly, the drain-side potential fixed layer VC can be inactivated without damaging the crystal of the nitride semiconductor layer such as the channel layer CH.

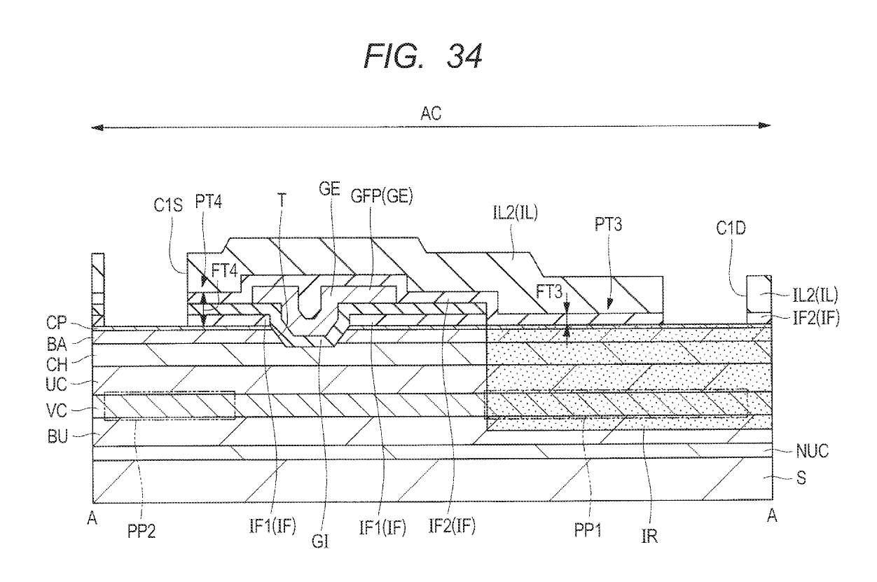

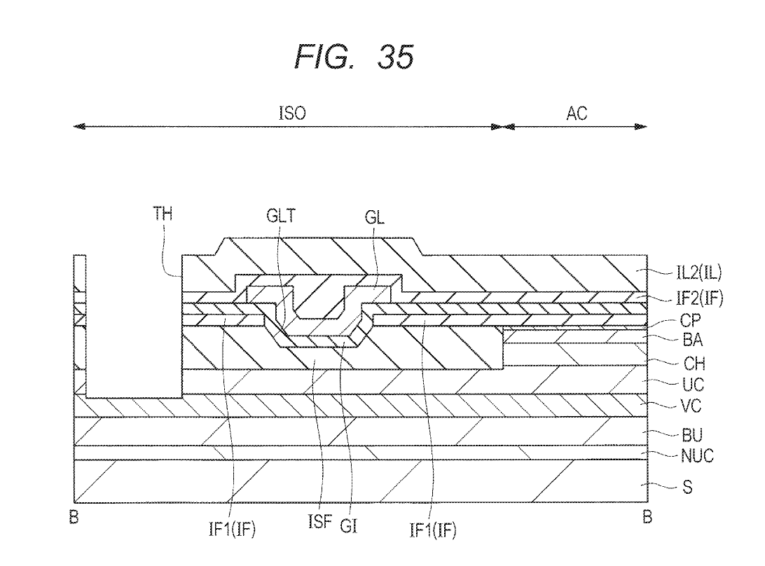

Then, as shown in FIGS. 34 and 35, contact holes C1S and C1D, and a through hole TH are formed in the interlayer insulation film IL in the same manner as in First Embodiment. At this step, the contact hole C1D penetrating through the insulation films IL2 and IF2 is formed over the portion PP1. Whereas, the contact hole C1S penetrating through the insulation films IL2 and IF2, the gate insulation film GI, and the insulation film IF1 is formed over the portion PP2.

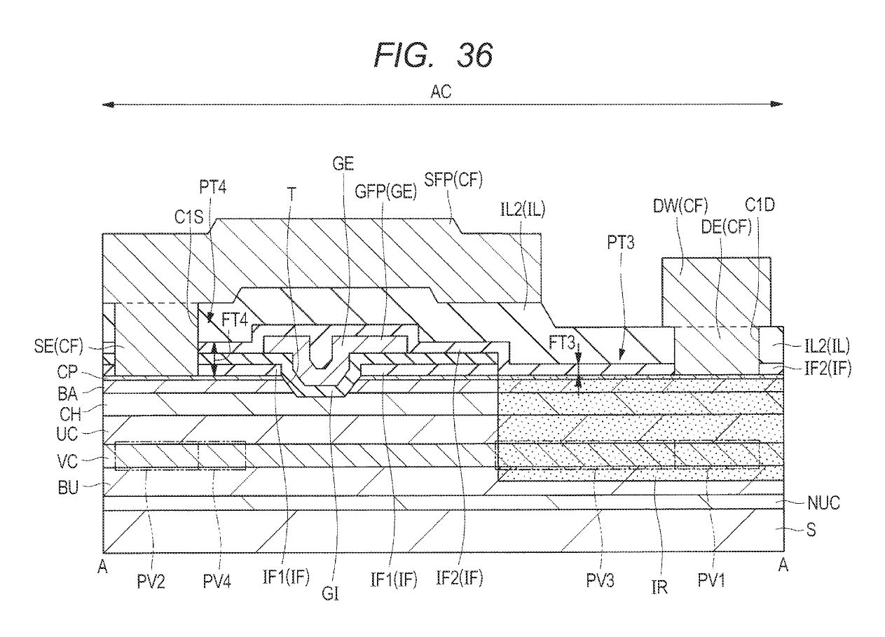

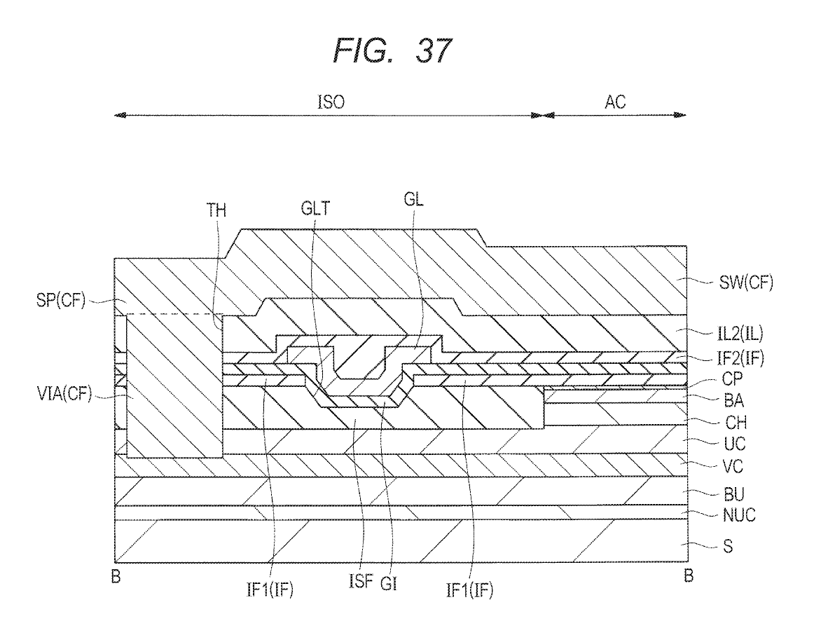

Then, as shown in FIGS. 36 and 37, in the same manner as in First Embodiment, a source electrode SE formed of the conductive film CF is formed in the contact hole C1S; a drain electrode DE formed of the conductive film CF is formed in the contact hole C1D; and a coupling part VIA formed of the conductive film CF is formed in the through hole TH. Further, as shown in FIGS. 28 and 29, a protective film PRO is formed over the source electrode SE, the drain electrode DE, and the like.

By the steps up to this point, it is possible to form the semiconductor device of the present Second Embodiment. Incidentally, the steps described above are examples. The semiconductor device of the present Second Embodiment may also be manufactured by other steps than the steps described above.

Thus, also in the present Second Embodiment, as with First Embodiment, a potential fixed layer VC is provided, and coupled with the source electrode SE. This can reduce the variations in characteristics of the semiconductor elements. Further, also in the present Second Embodiment, as with First Embodiment, the coupling part VIA in the through hole TH is arranged in the element isolation region ISO. As a result, it is possible to implement miniaturization or high integration of semiconductor elements. Further, it is possible to ensure a large active region AC in which electrons can be conducted. For this reason, it is possible to reduce the ON resistance per unit area.

Further, in the present Second Embodiment, the inactivated region IR is provided under the drain electrode DE, and between the gate electrode GE and the drain electrode DE. Provision of such an inactivated region IR can improve the drain breakdown voltage.

In the present Second Embodiment, in the step described by reference to FIGS. 32 and 33, the insulation film IF2 on the drain side with respect to the gate electrode GE is in contact with the cap layer CP, and the insulation film IF2 on the source side with respect to the gate electrode GE is not in contact with the cap layer CP. In this state, a heat treatment is performed in, for example, a nitrogen atmosphere. Accordingly, on the source side, the inactivating element such as hydrogen contained in the insulation film IF2 is not doped into the potential fixed layer VC. However, on the drain side, the inactivating element such as hydrogen contained in the insulation film IF2 is doped into the potential fixed layer VC. Therefore, it is possible to form the inactivated region IR on the drain side with reliability.

### First Modified Example of Second Embodiment

In the semiconductor device (see FIG. 28), after the formation of the insulation film containing hydrogen in a high concentration as the insulation film IF1, the hydrogen contained in the insulation film was released by the heat treatment. However, an insulation film having a low hydrogen concentration may be formed from the start.

FIG. 38 is a cross sectional view showing a semiconductor device of First Modified Example of Second Embodiment during a manufacturing step.

In the present First Modified Example, the same steps as the steps described by reference to FIGS. 5 to 8 are performed. As a result, an element isolation ISF is formed in the element isolation region ISO. Then, an insulation film IF12 containing hydrogen in a low concentration, or not containing hydrogen is formed. Thus, an insulation film IF1 formed of the insulation film IF12 is formed.

In Second Embodiment, as described by reference to FIGS. 6 to 8, an insulation film IF11 containing hydrogen in a high concentration is formed. Then, with the insulation film IF11 exposed at the outermost surface, the substrate S is subjected to a heat treatment. As a result, the hydrogen contained in the insulation film IF11 is released, thereby to form an insulation film IF1 containing hydrogen in a low concentration. For this reason, when the substrate S is subjected to a heat treatment, the hydrogen contained in the insulation film IF11 may be partially doped into the source-side potential fixed layer VC.

On the other hand, in the present First Modified Example, as shown in, for example, FIG. 38 for illustrating the step corresponding to FIG. 9, from the start, an insulation film IF12 containing hydrogen in a low concentration, or not containing hydrogen is formed. Thus, an insulation film IF1 formed of the insulation film IF12 is formed. This eliminates the necessity of subjecting the substrate S to a heat treatment for doping a part of the hydrogen contained in the insulation film IF11 (see FIG. 6) into the source-side potential fixed layer VC. This results in a large effect of reducing the risk of reduction of the acceptor concentration in the source-side potential fixed layer VC.

### Second Modified Example of Second Embodiment

For the semiconductor device, the heat treatment was performed with the insulation film IF2 in contact with the cap layer CP, and covered with the insulation film IL2 between the gate electrode GE and the drain electrode DE. Thus, the inactivated region IR was formed. However, the inactivated region IR may be formed in the following manner: between the gate electrode GE and the drain electrode DE, the insulation film IF2 is in contact with the cap layer CP, and the film thickness of the insulation film IF2 is thick; in this state, a heat treatment is performed.

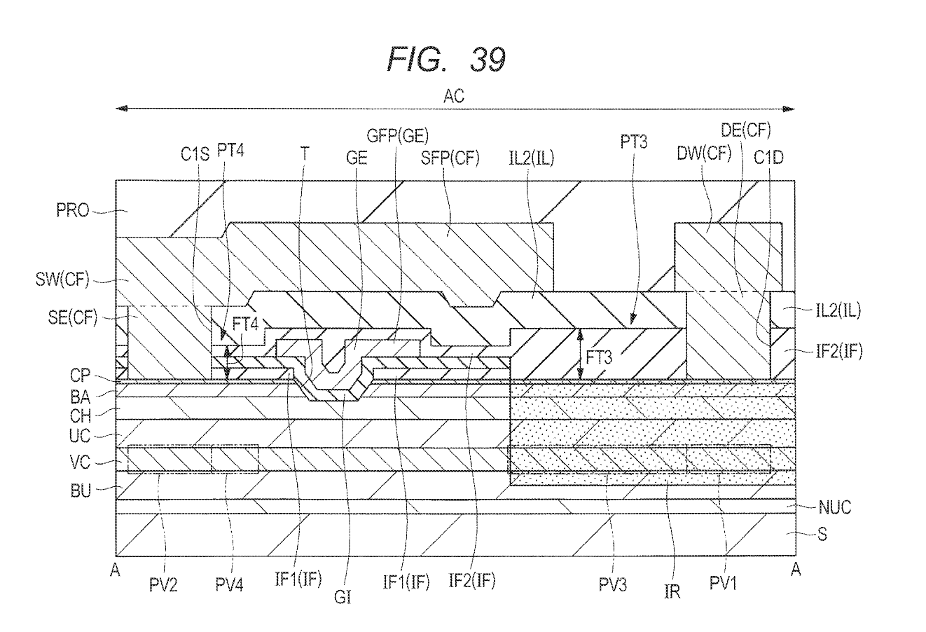

FIG. 39 is a cross sectional view schematically showing a configuration of a semiconductor device of Second Modified Example of Second Embodiment.

The semiconductor device of the present Second Modified Example has a substrate S as with Second Embodiment. Over the substrate S, a nucleation layer NUC, a buffer layer BU, a potential fixed layer VC, a channel base layer UC, a channel layer CH, and a barrier layer BA are sequentially formed.

The semiconductor device of the present Second Modified Example has, as with Second Embodiment, a gate electrode GE formed over the channel layer CH via a gate insulation film GI, and a source electrode SE and a drain electrode DE formed over the barrier layer BA on the opposite sides of the gate electrode GE. Further, the gate insulation film GI is formed at the inner wall of the trench T penetrating through the barrier layer BA, and reaching some point of the channel layer CH. The gate electrode GE is formed over the gate insulation film GI.

In the present Second Modified Example, an insulation film IF is formed over the barrier layer BA between the gate electrode GE and the drain electrode DE, and between the gate electrode GE and the source electrode SE. The film thickness FT3 of the portion PT3 of the insulation film IF situated between the gate electrode GE and the drain electrode DE is larger than the film thickness FT4 of the portion PT4 of the insulation film IF situated between the gate electrode GE and the source electrode SE.

In the present Second Modified Example, as with Second Embodiment (see FIG. 28), for example, an insulation film IF1 not containing hydrogen, or containing hydrogen in a lower concentration than the concentration of hydrogen in the insulation film IF2 is formed over the barrier layer BA. At this step, between the gate electrode GE and the source electrode SE, the insulation film IF1 is formed over the barrier layer BA. However, between the gate electrode GE and the drain electrode DE, the insulation film IF1 is not formed.

Then, after the formation of the insulation film IF1, over the insulation film IF1, an insulation film IF2 containing silicon, nitrogen, and hydrogen such as a silicon nitride film containing hydrogen is formed. At this step, between the gate electrode GE and the source electrode SE, an insulation film IF2 is formed over the barrier layer BA via the insulation film IF1. Between the gate electrode GE and the drain electrode DE, an insulation film IF2 is formed over the barrier layer BA not via the insulation film IF1. Then, the substrate S is heat treated, thereby to dope the hydrogen contained in the insulation film IF2 into the potential fixed layer VC.

As a result, as compared with the case where the potential fixed layer VC is doped with an inactivating element by ion implantation, the drain-side potential fixed layer VC can be inactivated without more breaking the crystals of the nitride semiconductors such as the channel layer CH.

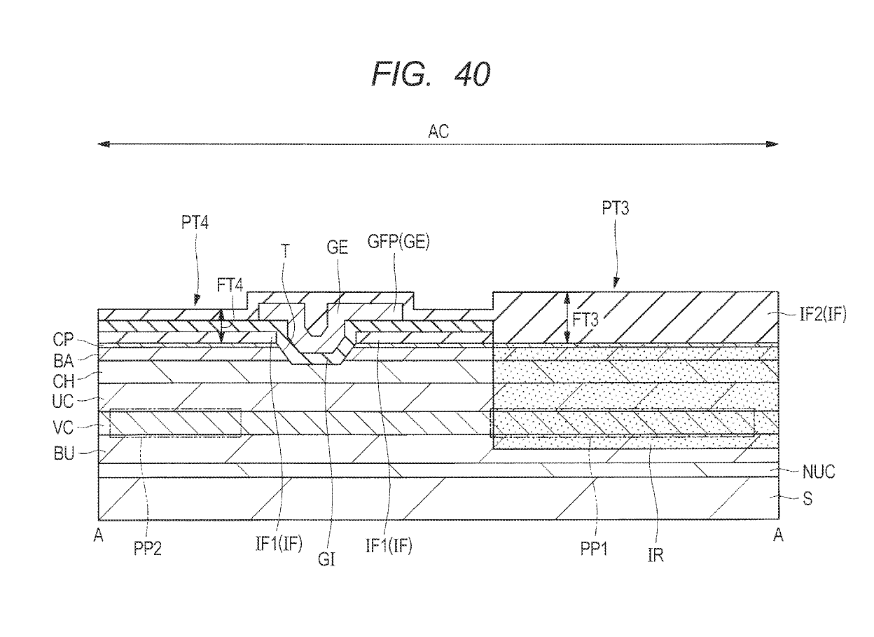

FIG. 40 is a cross sectional view showing the semiconductor device of Second Modified Example of Second Embodiment during a manufacturing step.

In the present Second Modified Example, the same steps as the steps described by reference to FIGS. 5 to 8 are performed, thereby to form an element isolation ISF in the element isolation region ISO. Then, a trench T is formed as shown in FIG. 40.

Then, a gate insulation film GI is formed over the inner wall of the trench T and the insulation film IF1. Over the gate insulation film GI, a gate electrode GE formed of a conductive film CF is formed.

Then, over the cap layer CP, as the insulation film IF2, a silicon nitride film is deposited with a film thickness of, for example, about 300 nm using, for example, a PECVD method. The insulation film IF2 is formed over the cap layer CP in such a manner as to cover the insulation film IF1, the gate insulation film GI, and the gate electrode GE. The insulation film IF2 contains hydrogen in a higher concentration than that of, for example, the insulation film IF1.

Then, the portions of the insulation film IF2 except for the portions thereof arranged in the region between the gate electrode GE formation region and the drain electrode DE (see FIG. 39) forming region, and the drain electrode DE forming region are thinned using, for example, a photolithography technology and an etching technology. Namely, the portion PT4 of the insulation film IF2 on the source side with respect to the gate electrode GE is thinned. Whereas, the portion PT3 of the insulation film IF2 on the drain side with respect to the gate electrode GE is not thinned. Further, the portion of the insulation film IF2 to be thinned is thinned so that, for example, the film thickness of about 300 nm is reduced to a film thickness of about 50 nm.

Then, the substrate S is subjected to a heat treatment. A heat treatment is performed at 500 to 800° C. for 10 to 60 minutes such as at 500° C. for 30 minutes, for example, in a nitrogen atmosphere.

At this step, on the first side with respect to the gate electrode GE (the right side in FIG. 40, namely, the drain side), the insulation film IF2 is not thinned. For this reason, on the drain side with respect to the gate electrode GE, the inactivating element contained in the portion of the insulation film IF2 on the surface side is released into the nitrogen atmosphere. Whereas, the inactivating element contained in the portion of the insulation film IF2 in the vicinity of the interface with the cap layer CP is doped into the potential fixed layer VC by diffusion. As a result, the inactivated region IR is formed. On the other hand, on the side opposite to the first side with respect to the gate electrode GE (the left side in FIG. 40, namely, the source side), the inactivating element contained in the insulation film IF2 is inhibited by the insulation film IF1, and is not doped into the potential fixed layer VC. As a result, the inactivated region IR is not formed.

In accordance with the present Second Modified Example, as with Second Embodiment, it is not necessary to ion-implant an inactivating element for inactivating only the drain-side portion of the potential fixed layer VC. For this reason, the drain-side potential fixed layer VC can be inactivated without damaging the crystal of the nitride semiconductor layers such as the channel layer CH.

Then, the same steps as the steps described by reference to FIGS. 34 and 35 are performed. As a result, an interlayer insulation film IL is formed over the gate electrode GE. Further, contact holes C1S and C1D, and a through hole TH are formed in the interlayer insulation film IL. Then, the same steps as the steps described by reference to FIGS. 36 and 37 are performed. As a result, a source electrode SE, a drain electrode DE, and the like are formed over the cap layer CP on the opposite sides of the gate electrode GE. Further, a protective film PRO is formed over the source electrode SE, the drain electrode DE, and the like. By the steps up to this point, the semiconductor device of the present Second Modified Example can be formed.

### Third Embodiment

In First and Second Embodiments, the semiconductor devices as MISFETs were exemplified. However, a semiconductor device of another configuration may also be adopted. For example, as in the present Third Embodiment, a semiconductor device may be adopted as a junction FET in which a gate junction layer is arranged under the gate electrode.

Below, with reference to the drawings, the semiconductor device of the present Third Embodiment will be described in details. Incidentally, below, a description will be given to the case where the present Third Embodiment is applied to the following case: the insulation film IF2 is in contact with the nitride semiconductor layer via the insulation film IF1 on the source side, and the insulation film IF2 is in contact with the nitride semiconductor layer not via the insulation film IF1 on the drain side, namely, Second Embodiment. However, as described previously, the present Third Embodiment may be applied to the case where the insulation film IF2 is covered with the insulation film IL1 (see FIG. 3) on the drain side, and the insulation film IF2 is not covered with the insulation film IL1 on the source side, namely, First Embodiment.

[Structure Description]

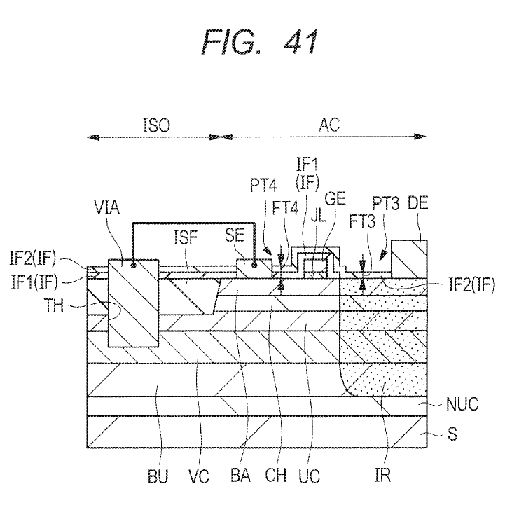

FIG. 41 is a cross sectional view schematically showing a configuration of the semiconductor device of Third Embodiment. The semiconductor device (semiconductor element) of the present Third Embodiment is a junction FET using a nitride semiconductor.

The semiconductor device of the present Third Embodiment has a substrate S as with the semiconductor device of Second Embodiment. Over the substrate S, a nucleation layer NUC, a buffer layer BU, a potential fixed layer VC, a channel base layer UC, a channel layer CH, and a barrier layer BA are sequentially formed. Further, an insulation film IF is formed over the barrier layer BA.

The semiconductor device of the present Third Embodiment has a gate electrode GE formed over the barrier layer BA via a gate junction layer JL, and a source electrode SE and a drain electrode DE formed over the barrier layer BA on the opposite sides of the gate electrode GE as distinct from Second Embodiment. The gate junction layer JL is doped with a p type impurity. Further, the gate junction layer JL and the gate electrode GE are preferably in ohmic contact with respect to holes. The gate electrode GE, the drain electrode DE, and the source electrode SE, and the barrier layer BA and the channel layer CH form the junction FET.

Incidentally, the semiconductor device of the present Third Embodiment can be configured equal to the semiconductor device of Second Embodiment, except that the gate electrode GE is formed over the barrier layer BA via the gate junction layer JL, and except that the trench T (recess) is not formed.

A two-dimensional electron gas is generated on the channel layer CH side in the vicinity of the interface between the channel layer CH and the barrier layer BA. However, under the gate junction layer JL, the conduction band of the channel layer CH is raised by the negative charges due to acceptor ionization. Accordingly, a two-dimensional electron gas is not formed. For this reason, in the semiconductor device of the present Third Embodiment, the OFF state can be kept with the gate electrode GE not applied with a positive potential (threshold potential), and the ON state can be kept with the gate electrode GE applied with a positive potential (threshold potential). Thus, the normally off operation can be performed.

Also in the present Third Embodiment, as with Second Embodiment, a coupling part VIA as an electrode penetrating through the element isolation ISF, and reaching the potential fixed layer VC thereunder is provided in the element isolation region ISO. The coupling part VIA is electrically coupled with the source electrode SE. Further, the coupling part VIA is in contact with the potential fixed layer VC. Thus, the potential fixed layer VC is provided, and coupled with the source electrode SE. This can reduce the variations in characteristic such as the threshold potential or the ON resistance.

Further, in the present Third Embodiment, an inactivated region IR is provided under the drain electrode DE, and between the gate electrode GE and the drain electrode DE. Provision of such an inactivated region IR can improve the drain breakdown voltage.

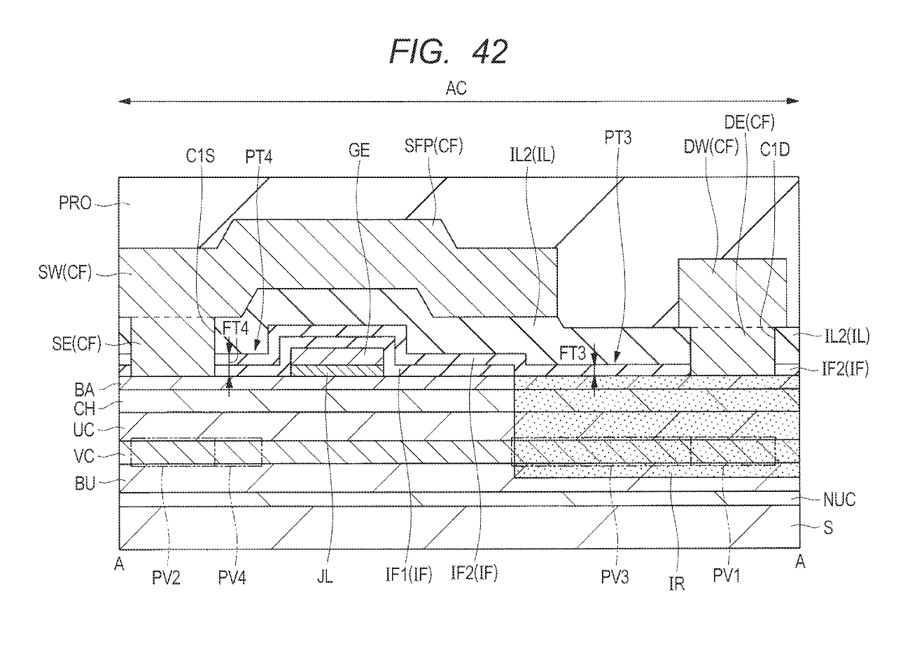

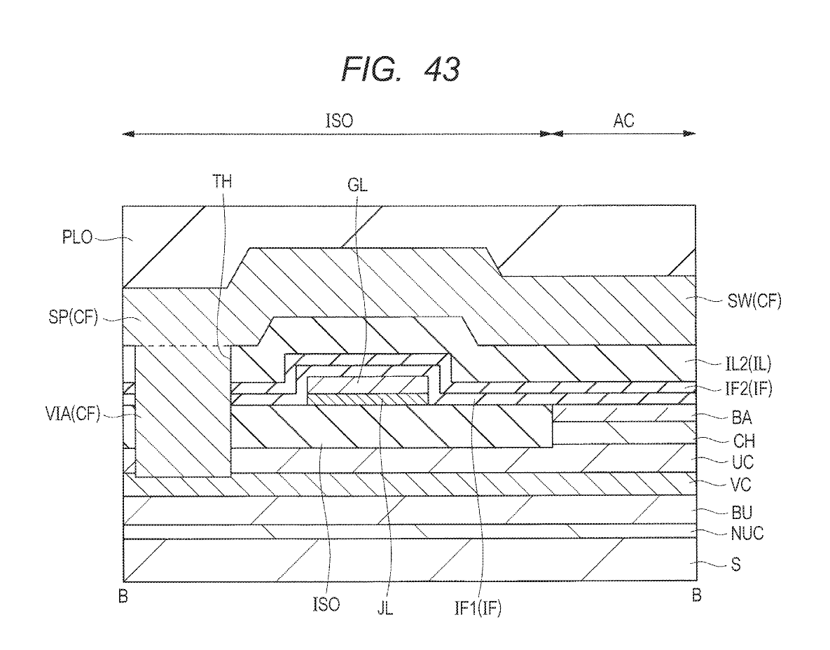

Then, with reference to FIGS. 42 and 43, the semiconductor device of the present Third Embodiment will be described in more details. FIGS. 42 and 43 are each a cross sectional view showing a configuration of the semiconductor device of Third Embodiment. Incidentally, the plan view showing a configuration of the semiconductor device of the present Third Embodiment can be set equal to FIG. 2. FIG. 42 corresponds to the A-A cross section of FIG. 2. FIG. 43 corresponds to the B-B cross section of FIG. 2.

As shown in FIGS. 42 and 43, the semiconductor device of the present Third Embodiment has a substrate S as with the semiconductor device of Second Embodiment. Over the substrate S, a nucleation layer NUC, a buffer layer BU, a potential fixed layer VC, a channel base layer UC, a channel layer CH, and a barrier layer BA are sequentially formed. Respective thicknesses and constituent materials of the substrate S, the nucleation layer NUC, the buffer layer BU, the potential fixed layer VC, the channel base layer UC, the channel layer CH, and the barrier layer BA are as described in First Embodiment.

The semiconductor device of the present Third Embodiment has a gate electrode GE formed over the barrier layer BA via a gate junction layer JL, and a source electrode SE and a drain electrode DE formed over the barrier layer BA on the opposite sides of the gate electrode GE as distinct from the semiconductor device of Second Embodiment.

As the gate junction layer JL, for example, a GaN layer can be used. Further, the thickness of the GaN layer can be set at a desirable thickness according to the objective characteristic, and is, for example, about 50 nm. As the materials for the gate junction layer JL, AlN, InN, and the like can be used other than GaN. Incidentally, the gate junction layer JL is preferably doped with a p type impurity. Examples of the p type impurity may include Be, C, or Mg. Further, the thickness and the constituent material of the gate electrode GE are as described in First Embodiment.

Over the gate electrode GE, an interlayer insulation film IL is arranged via the insulation film IF2. The interlayer insulation film IL has a through hole TH, and contact holes C1S and C1D. The source pad SP and the drain pad DP (see FIG. 2) are formed integrally with the source electrode SE and the drain electrode DE, respectively. Accordingly, the source pad SP and the drain pad DP are formed of the same materials as those of the source electrode SE and the drain electrode DE, respectively. Under the source pad SP, a coupling part VIA is arranged (see FIG. 43). Further, a protective film PRO is arranged over the source electrode SE and the drain electrode DE.

In the present Third Embodiment, as with Second Embodiment, an inactivated region IR is provided under the drain electrode DE, and between the gate electrode GE and the drain electrode DE. The inactivated region IR reaches the potential fixed layer VC in the depth direction. Provision of such an inactivated region IR can improve the drain breakdown voltage.

Specifically, as with Second Embodiment, the content of the inactivating element in the portion PV1 of the potential fixed layer VC situated under the drain electrode DE is larger than the content of the inactivating element in the portion PV2 of the potential fixed layer VC situated under the source electrode SE. Alternatively, the content of the inactivating element in the portion PV3 of the potential fixed layer VC situated between the gate electrode GE and the drain electrode DE is larger than the content of the inactivating element in the portion PV4 of the potential fixed layer VC situated between the gate electrode GE and the source electrode SE.

In the present Third Embodiment, as with Second Embodiment, the insulation film IF includes an insulation film IF1 and an insulation film IF2. The insulation film IF1 is formed between the gate electrode GE and the source electrode SE. The insulation film IF2 is formed between the gate electrode GE and the drain electrode DE, and between the gate electrode GE and the source electrode SE. Further, the insulation film IF2 is formed over the insulation film IF1 between the gate electrode GE and the source electrode SE.

For this reason, the film thickness FT3 of the portion PT3 of the insulation film IF situated between the gate electrode GE and the drain electrode DE is smaller than the film thickness FT4 of the portion PT4 of the insulation film IF situated between the gate electrode GE and the source electrode SE. Namely, the film thickness FT3 is different from the film thickness FT4. Further, the height position of the top surface of the portion PT3 is lower than the height position of the top surface of the portion PT4.

[Manufacturing Method Description]

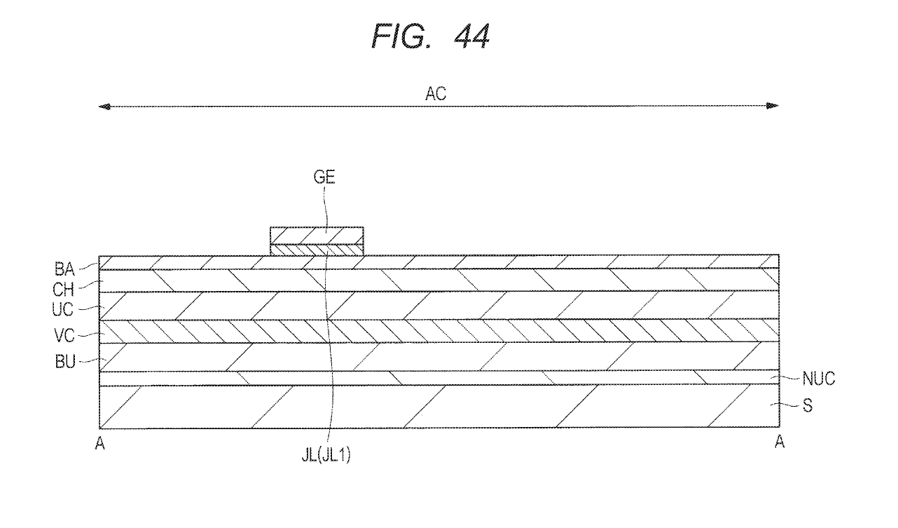

Then, with reference to FIGS. 44 to 48, a description will be given to a method for manufacturing the semiconductor device of the present Third Embodiment. In addition, the configuration of the semiconductor device will be made clearer. FIGS. 44 to 48 are each a cross sectional view showing the semiconductor device of the present Second Embodiment during a manufacturing step. Incidentally, other steps than the step of forming the gate junction layer JL are the same as those of Second Embodiment. For this reason, the step of forming the gate junction layer JL will be mainly described in details.

First, as with First Embodiment, the same step as the step described by reference to FIG. 5 is performed, thereby to provide a substrate S. Over the provided substrate S, a nucleation layer NUC, a buffer layer BU, a potential fixed layer VC, a channel base layer UC, a channel layer CH, and a barrier layer BA are sequentially formed. These can be formed using the materials described in First Embodiment in the same manner as in First Embodiment.

Then, as shown in FIG. 44, over the barrier layer BA, as a nitride semiconductor layer JL1, for example, a gallium nitride layer (p-GaN layer) containing a p type impurity is heteroepitaxially grown using a metal organic chemical vapor deposition method, or the like. For example, as a p type impurity, magnesium (Mg) is used. For example, a gallium nitride layer is deposited with a thickness of about 50 nm while being doped with magnesium (Mg).

Then, over the nitride semiconductor layer JL1, as a conductive film, for example, a TiN (titanium nitride) film is deposited with a film thickness of about 200 nm using a sputtering method, or the like. Then, a photoresist film (not shown) is formed in the gate electrode GE forming region. Using the photoresist film (not shown) as a mask, the conductive film and the nitride semiconductor layer JL1 are patterned by dry etching. This results in the formation of the gate electrode GE formed of the conductive film, and the gate junction layer JL formed of the portion of the nitride semiconductor layer JL1 between the gate electrode GE and the barrier layer BA.

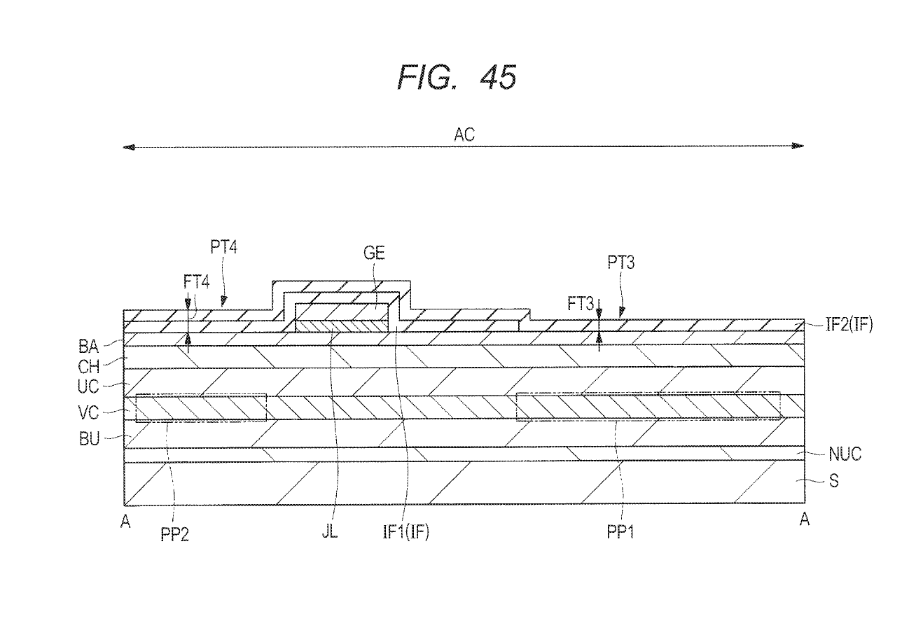

Then, as shown in FIG. 45, over the barrier layer BA, an insulation film IF1 is deposited with a film thickness of, for example, about 100 nm using, for example, a PECVD method. The insulation film IF1 is formed in such a manner as to cover the gate electrode GE and the gate junction layer JL. The insulation film IF1 can be formed using the materials described in Second Embodiment in the same manner as in Second Embodiment.

Then, using a photolithography technology and an etching technology, the insulation film IF1 is patterned. Then, of the insulation film IF1, the portion formed at the surface of the gate electrode GE and the gate junction layer JL, the portions formed over the portions of the barrier layer BA adjacent to the gate electrode GE, and the portion arranged on the source side with respect to the gate electrode GE are left. Whereas, the portion of the insulation film IF1 arranged on the drain side with respect to the gate electrode GE is removed. The patterning of the insulation film IF1 can be performed in the same manner as the manner in First Embodiment.

Then, over the barrier layer BA, as the insulation film IF2, a silicon nitride film, namely, an insulation film containing silicon and nitrogen is deposited with a film thickness of, for example, about 100 nm using, for example, a PECVD method. The insulation film IF2 is formed over the barrier layer BA in such a manner as to cover the insulation film IF1. The insulation film IF2 contains hydrogen, namely, an inactivating element in a higher concentration than that of, for example, the insulation film IF1. At this step, the insulation films IF1 and IF2 form the insulation film IF.

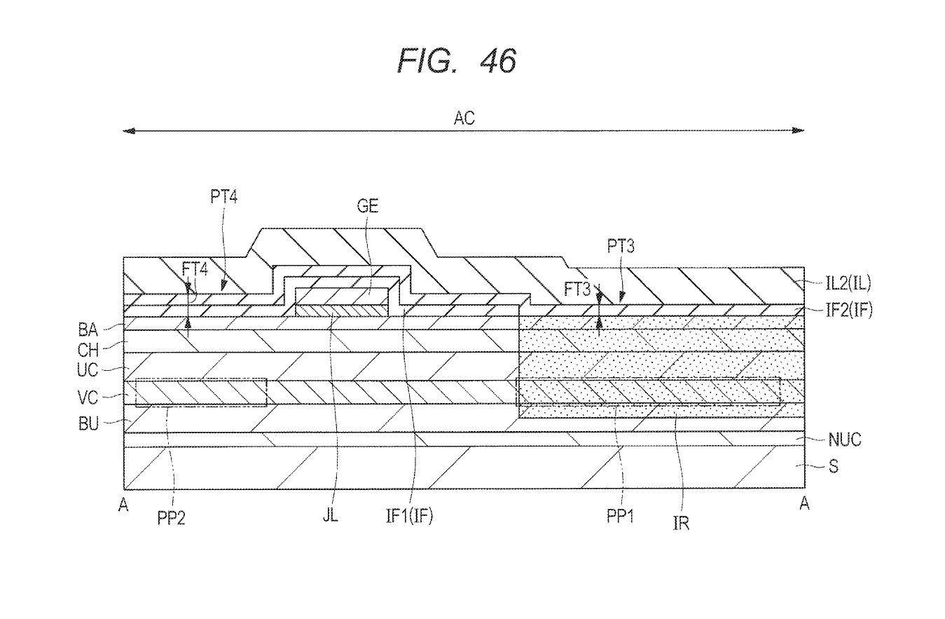

Then, as shown in FIG. 46, over the insulation film IF2, as the insulation film IL2, for example, a silicon oxide film is deposited with a film thickness of about 500 nm using an atmospheric pressure CVD method, or the like. At this step, an interlayer insulation film IL formed of the insulation film IL2 is formed.

Then, the substrate S is subjected to a heat treatment. A heat treatment is performed at 500 to 800° C. for 10 to 60 minutes such as at 500° C. for 30 minutes, for example, in a nitrogen atmosphere.

At this step, on the first side with respect to the gate electrode GE (the right side in FIG. 46, namely, the drain side), the inactivating element such as hydrogen contained in the portion of the insulation film IF2 situated over the portion PP1 is doped into the portion PP1 by diffusion. As a result, the inactivated region IR is formed. On the other hand, on the side opposite to the first side with respect to the gate electrode GE (the left side in FIG. 46, namely, the source side), the inactivating element contained in the portion of the insulation film IF2 situated over the portion PP2 is inhibited by the insulation film IF1, and is not doped into the portion PP2. As a result, the inactivated region IR is not formed.

Namely, in the present Third Embodiment, of the insulation film IF2 formed over the potential fixed layer VC, and containing an inactivating element, the drain-side portion is in contact with the barrier layer BA, and the source-side portion is in contact with the barrier layer BA. In this state, the substrate S is subjected to a heat treatment. As a result, the inactivating element is doped into only the drain-side portion of the potential fixed layer VC.

In accordance with the present Third Embodiment, only the drain-side portion of the potential fixed layer VC is inactivated. This eliminates the necessity of ion-implanting an inactivating element. Accordingly, the drain-side potential fixed layer VC can be inactivated without damaging the crystal of the nitride semiconductor layer such as the channel layer CH.

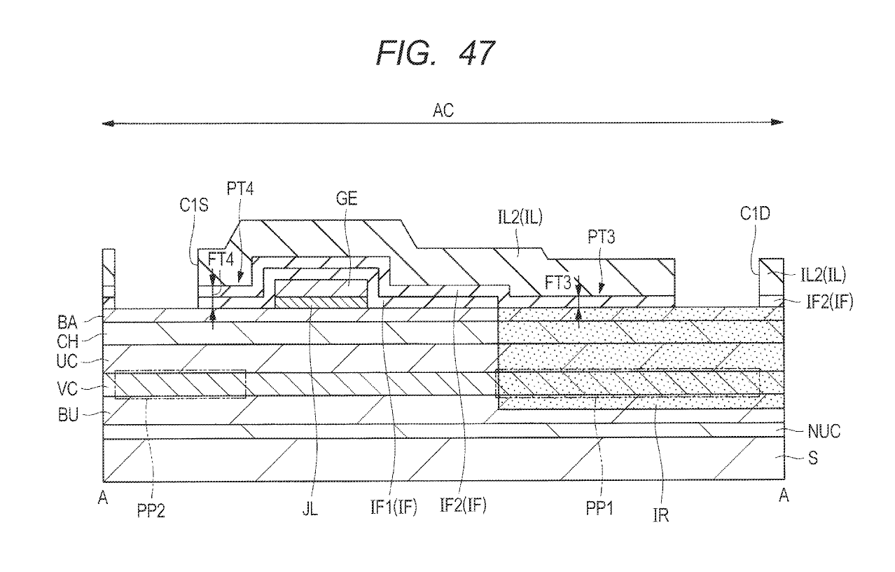

Then, as shown in FIG. 47, contact holes C1S and C1D, and a through hole TH are formed in the interlayer insulation film IL in the same manner as in First Embodiment.

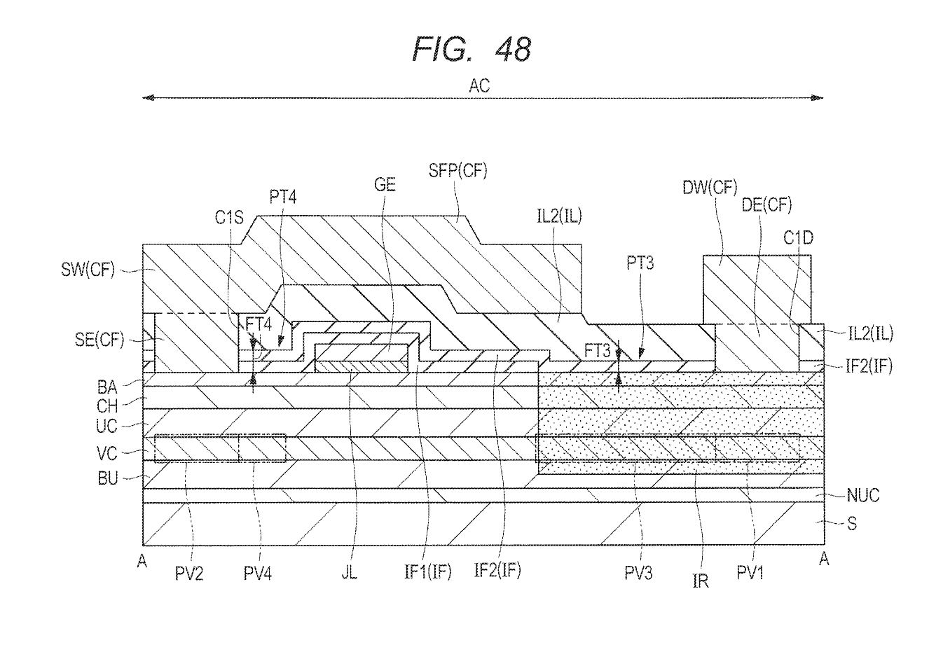

Then, as shown in FIG. 48, in the same manner as in First Embodiment, a source electrode SE formed of the conductive film CF is formed in the contact hole C1S; and a drain electrode DE formed of the conductive film CF is formed in the contact hole C1D. Further, as shown in FIG. 42, a protective film PRO is formed over the source electrode SE, the drain electrode DE, and the like.

By the steps up to this point, it is possible to form the semiconductor device of the present Third Embodiment. Incidentally, the steps described above are examples. The semiconductor device of the present Third Embodiment may also be manufactured by other steps than the steps described above.

### Fourth Embodiment

In First and Second Embodiments, a recess gate type semiconductor device was exemplified. However, a semiconductor device of another configuration may be adopted. For example, as in the present Fourth Embodiment, a semiconductor device not having a gate insulation film under the gate electrode may be adopted.

Below, with reference to the drawings, the semiconductor device of the present Fourth Embodiment will be described in details. Incidentally, below, a description will be given to the case where the present Fourth Embodiment is applied to the following case: the insulation film IF2 is in contact with the nitride semiconductor layer via the insulation film IF1 on the source side, and the insulation film IF2 is in contact with the nitride semiconductor layer not via the insulation film IF1 on the drain side, namely, Second Embodiment. However, as described previously, the present Fourth Embodiment may be applied to the case where the insulation film IF2 is covered with the insulation film IL1 (see FIG. 3) on the drain side, and the insulation film IF2 is not covered with the insulation film IL1 on the source side, namely, First Embodiment.

[Structure Description]

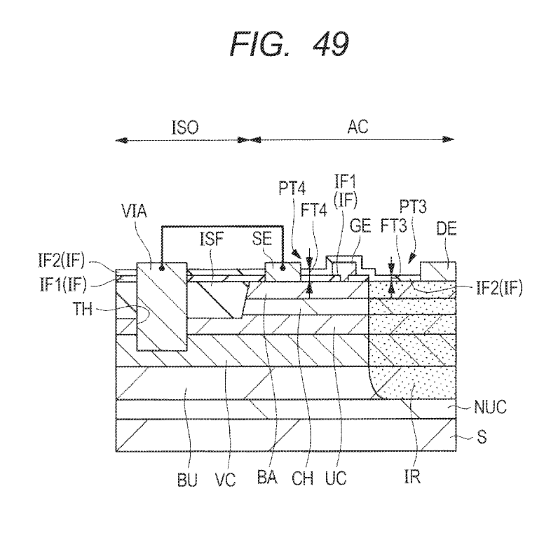

FIG. 49 is a cross sectional view schematically showing a configuration of the semiconductor device of Fourth Embodiment. The semiconductor device (semiconductor element) of the present Fourth Embodiment is a transistor using a nitride semiconductor. The semiconductor device can be used as a power transistor of a HEMT: High Electron Mobility Transistor type.

The semiconductor device of the present Fourth Embodiment has a substrate S as with the semiconductor device of Second Embodiment. Over the substrate S, a nucleation layer NUC, a buffer layer BU, a potential fixed layer VC, a channel base layer UC, a channel layer CH, and a barrier layer BA are sequentially formed.

The semiconductor device of the present Fourth Embodiment has a gate electrode GE formed over the barrier layer BA, and a source electrode SE and a drain electrode DE formed over the barrier layer BA on the opposite sides of the gate electrode GE.

A two-dimensional electron gas is generated on the channel layer CH side in the vicinity of the interface between the channel layer CH and the barrier layer BA. By applying the gate electrode GE with a prescribed electric potential, it is possible to eliminate the two-dimensional electron gas, resulting in an OFF state.

Also in the present Fourth Embodiment, as with Second Embodiment, a coupling part VIA as an electrode penetrating through the element isolation ISF, and reaching the potential fixed layer VC thereunder is provided in the element isolation region ISO. The coupling part VIA is electrically coupled with the source electrode SE. Further, the coupling part VIA is in contact with the potential fixed layer VC. Thus, the potential fixed layer VC is provided, and coupled with the source electrode SE. This can reduce the variations in characteristic such as the threshold potential or the ON resistance.

Further, in the present Fourth Embodiment, an inactivated region IR is provided under the drain electrode DE, and between the gate electrode GE and the drain electrode DE. The inactivated region IR reaches the potential fixed layer VC in the depth direction. Provision of such an inactivated region IR can improve the drain breakdown voltage.

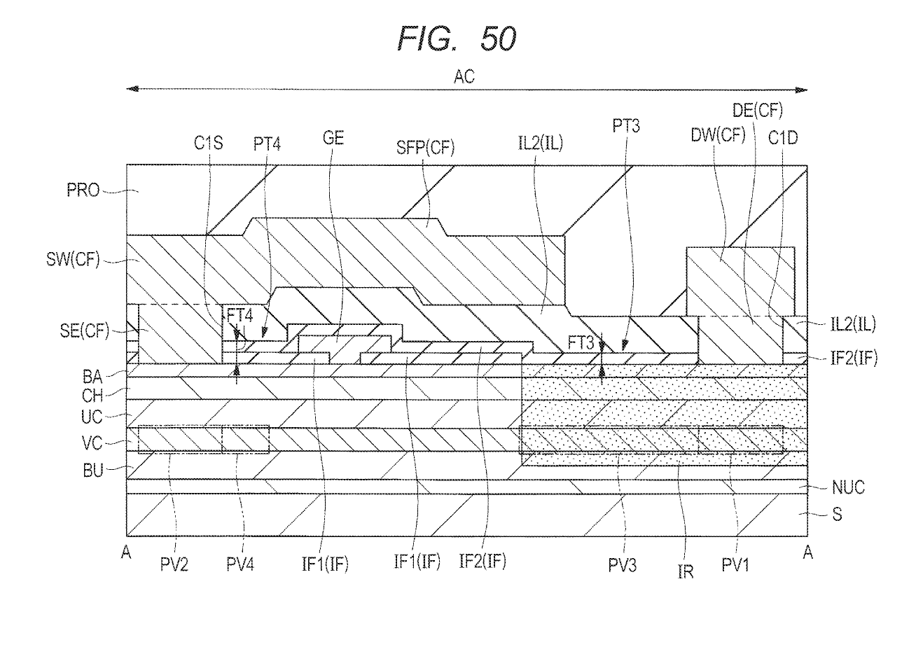

Then, with reference to FIG. 50, the semiconductor device of the present Fourth Embodiment will be described in more details. FIG. 50 is a cross sectional view showing a configuration of the semiconductor device of Fourth Embodiment. Incidentally, the plan view showing a configuration of the semiconductor device of the present Fourth Embodiment can be set equal to FIG. 2. FIG. 50 corresponds to the A-A cross section of FIG. 2.

As shown in FIG. 50, the semiconductor device of the present Fourth Embodiment has a substrate S as with the semiconductor device of Second Embodiment. Over the substrate S, a nucleation layer NUC, a buffer layer BU, a potential fixed layer VC, a channel base layer UC, a channel layer CH, and a barrier layer BA are sequentially formed. Then, the semiconductor device of the present Fourth Embodiment has a gate electrode GE formed over the barrier layer BA, and a source electrode SE and a drain electrode DE formed over the barrier layer BA on the opposite sides of the gate electrode GE. The gate electrode GE, the drain electrode DE, and the source electrode SE, and the barrier layer BA, and the channel layer CH form a HEMT.

In the interlayer insulation film IL and the insulation film IF, contact holes C1D and C1S are formed. In the contact hole C1D, a drain electrode DE is formed. In the contact hole C1S, a source electrode SE is formed. The drain electrode DE is coupled with the drain pad DP (see FIG. 2). The source electrode SE is coupled with the source pad SP (see FIG. 2). Further, a protective film PRO is arranged over the source electrode SE and the drain electrode DE.

In the present Fourth Embodiment, as with Second Embodiment, an inactivated region IR is provided under the drain electrode DE, and between the gate electrode GE and the drain electrode DE. The inactivated region IR reaches the potential fixed layer VC in the depth direction. Provision of such an inactivated region IR can improve the drain breakdown voltage.

Specifically, as with Second Embodiment, the content of the inactivating element in the portion PV1 of the potential fixed layer VC situated under the drain electrode DE is larger than the content of the inactivating element in the portion PV2 of the potential fixed layer VC situated under the source electrode SE. Alternatively, the content of the inactivating element in the portion PV3 of the potential fixed layer VC situated between the gate electrode GE and the drain electrode DE is larger than the content of the inactivating element in the portion PV4 of the potential fixed layer VC situated between the gate electrode GE and the source electrode SE.

In the present Fourth Embodiment, as with Second Embodiment, the insulation film IF includes an insulation film IF1 and an insulation film IF2. The insulation film IF1 is formed between the gate electrode GE and the source electrode SE. The insulation film IF2 is formed between the gate electrode GE and the drain electrode DE, and between the gate electrode GE and the source electrode SE. Whereas, the insulation film IF2 is formed over the insulation film IF1 between the gate electrode GE and the source electrode SE.

Accordingly, the film thickness FT3 of the portion PT3 of the insulation film IF situated between the gate electrode GE and the drain electrode DE is smaller than the film thickness FT4 of the portion PT4 of the insulation film IF situated between the gate electrode GE and the source electrode SE. Namely, the film thickness FT3 is different from the film thickness FT4. Whereas, the height position of the top surface of the portion PT3 is lower than the height position of the top surface of the portion PT4.

[Manufacturing Method Description]

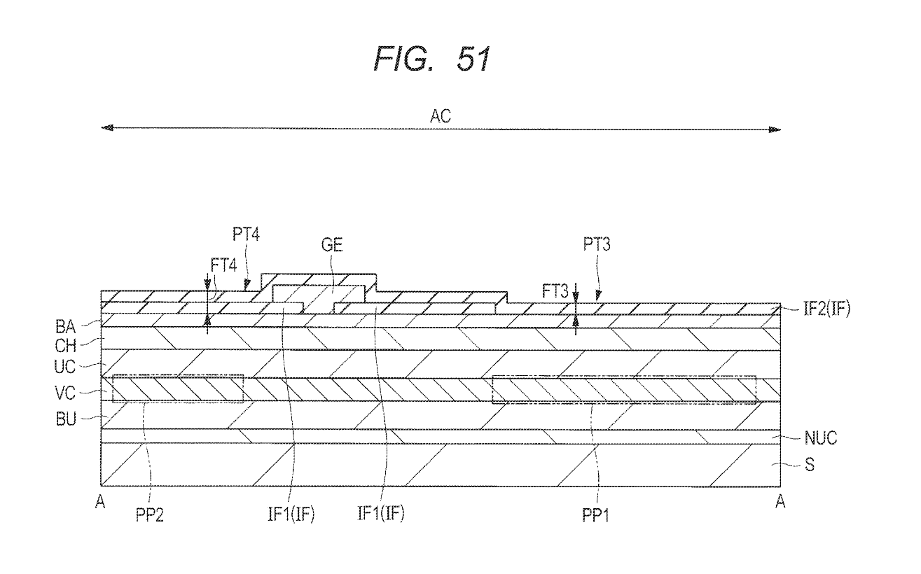

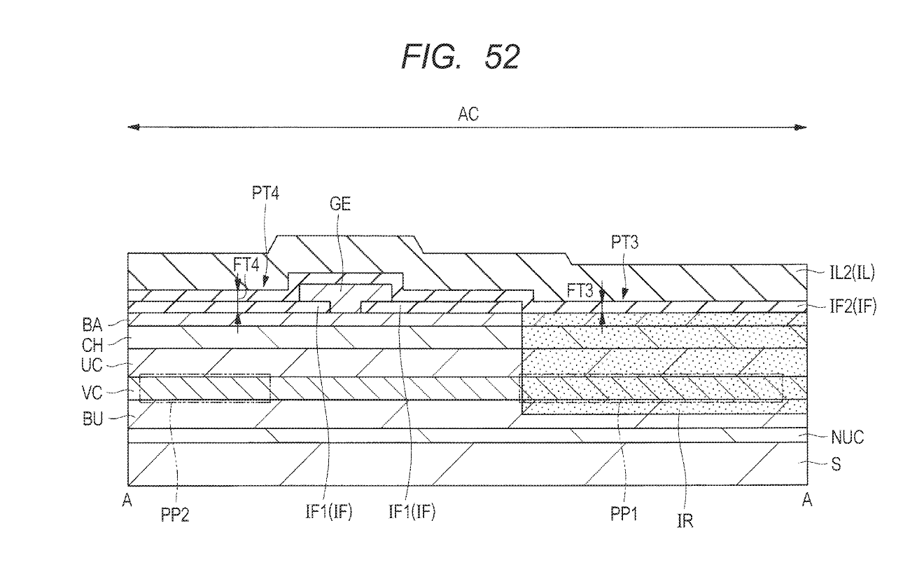

Then, with reference to FIGS. 51 and 52, a description will be given to a method for manufacturing the semiconductor device of the present Fourth Embodiment. In addition, the configuration of the semiconductor device will be made clearer. FIGS. 51 and 52 are each a cross sectional view showing the semiconductor device of the present Fourth Embodiment during a manufacturing step. Incidentally, other steps than the step of forming the gate electrode GE are the same as those of Second Embodiment. For this reason, the step of forming the gate electrode GE will be mainly described in details.

First, as with First Embodiment, the same step as the step described by reference to FIG. 5 is performed, thereby to provide a substrate S. Over the provided substrate S, a nucleation layer NUC, a buffer layer BU, a potential fixed layer VC, a channel base layer UC, a channel layer CH, and a barrier layer BA are sequentially formed. These can be formed using the materials described in First Embodiment in the same manner as in First Embodiment.

Then, as shown in FIG. 51, over the barrier layer BA, as the insulation film IF1, a silicon nitride film is deposited with a film thickness of, for example, about 100 nm using, for example, a PECVD method. The insulation film IF1 can be formed using the materials described in Second Embodiment in the same manner as in Second Embodiment.

Then, an opening is provided in the insulation film IF1. In the opening, and over the insulation film IF1, as a conductive film, for example, a titanium nitride (TiN) film is deposited with a film thickness of about 200 nm using a sputtering method, or the like. Then, a photoresist film (not shown) is formed in the gate electrode GE forming region. Using the photoresist film (not shown) as a mask, the conductive film and the nitride semiconductor layer JL1 are patterned by dry etching. This results in the formation of a gate electrode GE formed of the conductive film.

Then, using a photolithography technology and an etching technology, the insulation film IF1 is patterned. Then, of the insulation film IF1, the portions formed over the portions of the barrier layer BA adjacent to the gate electrode GE, and the portion arranged on the source side with respect to the gate electrode GE are left. Whereas, the portion of the insulation film IF1 arranged on the drain side with respect to the gate electrode GE is removed. The patterning of the insulation film IF1 can be performed in the same manner as the manner in Second Embodiment.

Then, over the barrier layer BA, as the insulation film IF2, a silicon nitride film, namely, an insulation film containing silicon and nitrogen is deposited with a film thickness of, for example, about 100 nm using, for example, a PECVD method. The insulation film IF2 is formed over the barrier layer BA in such a manner as to cover the insulation film IF1. The insulation film IF2 contains hydrogen, namely, an inactivating element in a higher concentration than that of, for example, the insulation film IF1. At this step, the insulation films IF1 and IF2 form the insulation film IF.

Then, as shown in FIG. 52, over the insulation film IF2, as the insulation film IL2, for example, a silicon oxide film is deposited with a film thickness of about 500 nm using an atmospheric pressure CVD method, or the like. At this step, an interlayer insulation film IL formed of the insulation film IL2 is formed.

Then, the substrate S is subjected to a heat treatment. A heat treatment is performed at 500 to 800° C. for 10 to 60 minutes such as at 500° C. for 30 minutes, for example, in a nitrogen atmosphere.

At this step, on the first side with respect to the gate electrode GE (the right side in FIG. 52, namely, the drain side), the inactivating element such as hydrogen contained in the portion of the insulation film IF2 situated over the portion PP1 is doped into the portion PP1 by diffusion. As a result, the inactivated region IR is formed. On the other hand, on the side opposite to the first side with respect to the gate electrode GE (the left side in FIG. 52, namely, the source side), the inactivating element contained in the portion of the insulation film IF2 situated over the portion PP2 is inhibited by the insulation film IF1, and is not doped into the portion PP2. As a result, the inactivated region IR is not formed.

Namely, in the present Fourth Embodiment, of the insulation film IF2 formed over the potential fixed layer VC, and containing an inactivating element, the drain-side portion is in contact with the barrier layer BA, and the source-side portion is not in contact with the barrier layer BA. In this state, the substrate S is subjected to a heat treatment. As a result, the inactivating element is doped into only the drain-side portion of the potential fixed layer VC.

In accordance with the present Fourth Embodiment, only the drain-side portion of the potential fixed layer VC is inactivated. This eliminates the necessity of ion-implanting an inactivating element. Accordingly, the drain-side potential fixed layer VC can be inactivated without damaging the crystal of the nitride semiconductor layer such as the channel layer CH.

Then, as shown in FIG. 50, contact holes C1S and C1D, and a through hole TH are formed in the interlayer insulation film IL in the same manner as in Second Embodiment.

Then, as shown in FIG. 50, in the same manner as in Second Embodiment, a source electrode SE formed of the conductive film CF is formed in the contact hole C1S; a drain electrode DE formed of the conductive film CF is formed in the contact hole C1D; and a coupling part VIA formed of the conductive film CF is formed in the through hole TH. Further, a protective film PRO is formed over the source electrode SE, the drain electrode DE, and the like.

By the steps up to this point, it is possible to form the semiconductor device of the present Fourth Embodiment. Incidentally, the steps described above are examples. The semiconductor device of the present Fourth Embodiment may also be manufactured by other steps than the steps described above.

### Fifth Embodiment

In First Embodiment, the coupling part VIA was provided in the element isolation region ISO. However, the coupling part VIA may be provided in the active region AC. For example, in the present Fifth Embodiment, the coupling part VIA is provided under the source electrode SE.

Below, with reference to the drawings, the semiconductor device of the present Fifth Embodiment will be described in details. Incidentally, the same configuration as that of First Embodiment will not be described.

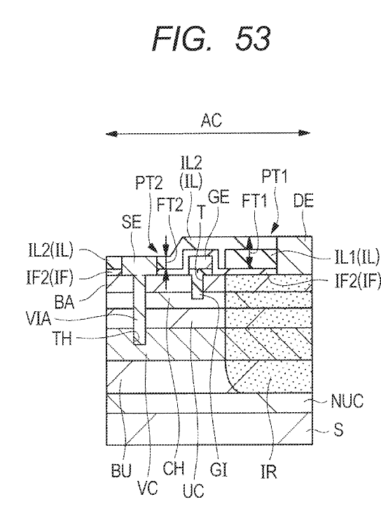

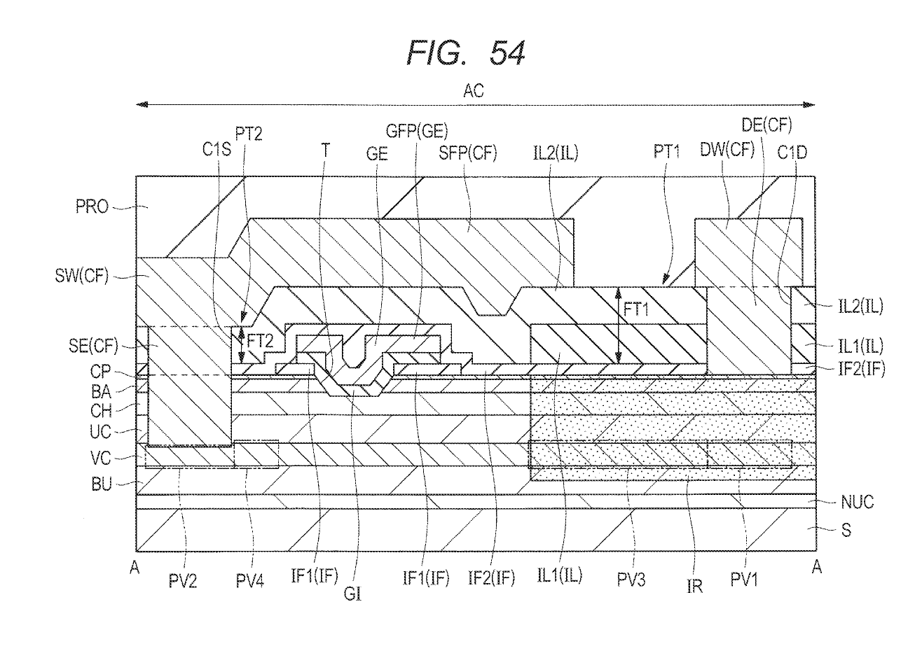

FIG. 53 is a cross sectional view schematically showing a configuration of the semiconductor device of Fifth Embodiment. FIG. 54 is a cross sectional view showing a configuration of the semiconductor device of Fifth Embodiment.

The semiconductor device (semiconductor element) of the present Fifth Embodiment is a MIS type field effect transistor using a nitride semiconductor. The semiconductor device of the present Fifth Embodiment is a so-called recess gate type semiconductor device.

In semiconductor device of the present Fifth Embodiment, as shown in FIGS. 53 and 54, under the source electrode SE in the active region AC, a through hole TH is formed as a trench part penetrating through the barrier layer BA, the channel layer CH, and the channel base layer UC, and reaching the potential fixed layer VC. A coupling part VIA is provided in the through hole TH. The coupling part VIA is formed integrally with the source electrode SE, and is electrically coupled with the source electrode SE. Thus, the potential fixed layer VC is provided, and is coupled with the source electrode SE. As a result, as described in First Embodiment, it is possible to reduce the variations in characteristic such as the threshold potential or the ON resistance. Further, the coupling part VIA is arranged in the active region AC in which electrons are conducted. For this reason, the electrical potential can be fixed more effectively.

Further, in the present Fifth Embodiment, an inactivated region IR is provided under the drain electrode DE, and between the gate electrode GE and the drain electrode DE. The inactivated region IR reaches the potential fixed layer VC in the depth direction. Provision of such an inactivated region IR can improve the drain breakdown voltage.

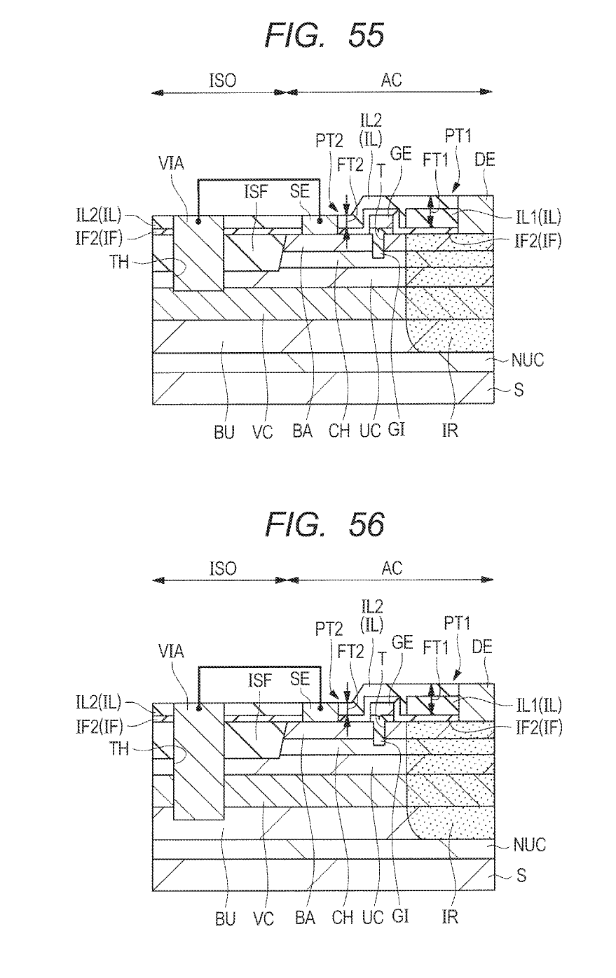

FIGS. 55 and 56 are each a cross sectional view schematically showing another configuration of the semiconductor device of Fifth Embodiment. As shown in FIG. 55, the bottom surface of the through hole TH may be arranged at the same height position as that of the top surface of the potential fixed layer VC, so that the bottom of the coupling part VIA is in contact with the potential fixed layer VC. Alternatively, as shown in FIG. 56, the following configuration may be adopted: the bottom surface of the through hole TH in which the coupling part VIA is arranged is arranged below the bottom surface of the potential fixed layer VC; thus, a part of the side surface of the coupling part VIA is in contact with the potential fixed layer VC. Thus, it is essential only that the coupling part VIA is arranged in such a manner as to be in contact with the potential fixed layer VC.

The semiconductor device of the present Fifth Embodiment (see FIGS. 53, 55, and 56) can be formed by the same steps as those of First Embodiment only by changing the position or the depth of the through hole TH.

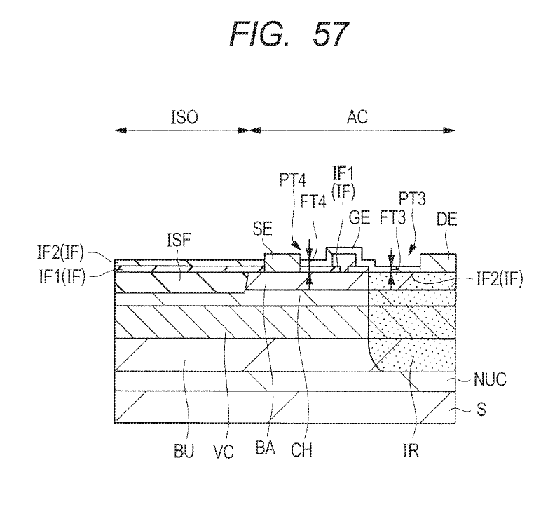

FIG. 57 is a cross sectional view schematically showing another configuration of the semiconductor device of Fifth Embodiment. The semiconductor device shown in FIG. 57 is obtained by omitting the configuration of the channel base layer UC and the coupling part VIA from the semiconductor device shown in FIG. 49. Thus, the channel base layer UC and the coupling part VIA may be omitted (this also applies to First Embodiment, and the like).

Up to this point, the invention completed by the present inventors was specifically described by way of embodiments. However, it is naturally understood that the present invention is not limited to the embodiments, and may be variously changed within the scope not departing from the gist thereof.

For example, the configuration obtained by omitting the coupling part VIA described in the Modified Example of First Embodiment may be applied to any semiconductor device of Second Embodiment to Fourth Embodiment. Alternatively, the coupling part VIA in First Embodiment or Second Embodiment may be arranged under the source electrode SE in the active region AC as described in Fifth Embodiment. Further, the position of the bottom surface of the coupling part VIA of First Embodiment or Second Embodiment may be changed as described in Fifth Embodiment. Furthermore, in addition, various combinations are possible in configuration and manufacturing step of each part described in each embodiment.

What is claimed is:

1. A semiconductor device having:
a substrate;
a first nitride semiconductor layer formed over the substrate, and containing a p type first impurity;
a gate electrode formed over the first nitride semiconductor layer;
a first electrode formed over the first nitride semiconductor layer, and arranged on a first side with respect to the gate electrode in a plan view;
a second electrode formed over the first nitride semiconductor layer, and arranged on the side opposite to the first side with respect to the gate electrode in a plan view; and
a first insulation film formed between the gate electrode and the first electrode, and between the gate electrode and the second electrode,
wherein a first portion of the first nitride semiconductor layer situated under the first electrode contains a first element for inactivating the first impurity,
wherein a second portion of the first nitride semiconductor layer situated under the second electrode contains the first element in a lower concentration than the concentration of the first element in the first portion, or does not contain the first element, and
wherein the film thickness of a third portion of the first insulation film situated between the gate electrode and the first electrode is different from the film thickness of a fourth portion of the first insulation film situated between the gate electrode and the second electrode.

2. The semiconductor device according to claim 1,
wherein a fifth portion of the first nitride semiconductor layer situated under the third portion contains the first element, and
wherein a sixth portion of the first nitride semiconductor layer situated under the fourth portion contains the first element in a lower concentration than the concentration of the first element in the fifth portion, or does not contain the first element.

3. The semiconductor device according to claim 1,
wherein the first insulation film includes:
a second insulation film formed between the gate electrode and the first electrode; and
a third insulation film formed between the gate electrode and the first electrode, and between the gate electrode and the second electrode,
wherein the third insulation film is formed over the second insulation film between the gate electrode and the first electrode,
wherein each of the second insulation film and the third insulation film contains silicon and oxygen, and
wherein the film thickness of the third portion is larger than the film thickness of the fourth portion.

4. The semiconductor device according to claim 3, having
a fourth insulation film formed between the gate electrode and the first electrode,
wherein the second insulation film is formed over the fourth insulation film,
wherein the fourth insulation film contains silicon and nitrogen,
wherein the second insulation film contains the first element, and
wherein the fourth portion contains the first element in a lower concentration than the concentration of the first element in the second insulation film, or does not contain the first element.

5. The semiconductor device according to claim 1,
wherein the first insulation film includes:
a fifth insulation film formed formed between the gate electrode and the second electrode; and
a sixth insulation film formed between the gate electrode and the first electrode, and between the gate electrode and the second electrode,
wherein the sixth insulation film is formed over the fifth insulation film between the gate electrode and the second electrode,
wherein each of the fifth insulation film and the sixth insulation film contains silicon and nitrogen, and
wherein the film thickness of the third portion is smaller than the film thickness of the fourth portion.

6. The semiconductor device according to claim 5, having
a seventh insulation film formed between the gate electrode and the first electrode,
wherein the seventh insulation film is formed over the first insulation film,
wherein a seventh portion of the sixth insulation film formed between the gate electrode and the first electrode contains the first element, and
wherein the fifth insulation film contains the first element in a lower concentration than the concentration of the first element in the seventh portion, or does not contain the first element.

7. The semiconductor device according to claim 1, having
a third electrode electrically coupled with the second electrode,
wherein the third electrode is in contact with the first nitride semiconductor layer.

8. The semiconductor device according to claim 1, having:
a second nitride semiconductor layer formed over the first nitride semiconductor layer;
a third nitride semiconductor layer formed over the second nitride semiconductor layer; and
a fourth nitride semiconductor layer formed over the third nitride semiconductor layer,
wherein the gate electrode, the first electrode, and the second electrode, and the first insulation film are formed over the fourth nitride semiconductor layer,
wherein the electron affinity of the third nitride semiconductor layer is larger than the electron affinity of the second nitride semiconductor layer, and
wherein the electron affinity of the fourth nitride semiconductor layer is smaller than the electron affinity of the second nitride semiconductor layer.

9. The semiconductor device according to claim 8,
wherein the substrate includes:
a first region; and
a second region,
wherein the first nitride semiconductor layer is formed in the first region and the second region,
wherein the gate electrode, the first electrode, and the second electrode are formed in the first region,
the semiconductor device further having:
an element isolation part formed in the fourth nitride semiconductor layer, in the third nitride semiconductor layer, and in the second nitride semiconductor layer in the second region;
a first trench part penetrating through the element isolation part, and reaching the first nitride semiconductor layer; and
a fourth electrode formed in the first trench part,
wherein the fourth electrode is electrically coupled with the second electrode.

10. The semiconductor device according to claim 8, having:
a second trench part penetrating through the fourth nitride semiconductor layer, the third nitride semiconductor layer, and the second nitride semiconductor layer, and reaching the first nitride semiconductor layer; and
a fifth electrode formed in the second trench part,
wherein the fifth electrode is electrically coupled with the second electrode.

11. The semiconductor device according to claim 8, having:
a third trench part penetrating through the fourth nitride semiconductor layer, and reaching some point of the third nitride semiconductor layer; and
a gate insulation film formed at the inner wall of the third trench part,
wherein the gate electrode is formed over the gate insulation film, and
wherein the gate electrode, the gate insulation film, the first electrode, the second electrode, the fourth nitride semiconductor layer, and the third nitride semiconductor layer form a MISFET.

12. The semiconductor device according to claim 8,
wherein the gate electrode, the first electrode, the second electrode, the fourth nitride semiconductor layer, and the third nitride semiconductor layer form a junction FET.

13. The semiconductor device according to claim 8,
wherein the gate electrode, the first electrode, the second electrode, the fourth nitride semiconductor layer, and the third nitride semiconductor layer form a HEMT.

14. The semiconductor device according to claim 1,
wherein the substrate is a semiconductor substrate.

15. The semiconductor device according to claim 3,
wherein the height position of the top surface of the third portion is higher than the height position of the top surface of the fourth portion.

16. The semiconductor device according to claim 5,
wherein the height position of the top surface of the third portion is lower than the height position of the top surface of the fourth portion.

17. A method for manufacturing a semiconductor device, comprising the steps of:
(a) providing a substrate;
(b) forming a first nitride semiconductor layer containing a p type first impurity over the substrate;
(c) forming a gate electrode over the first nitride semiconductor layer;
(d) forming a first insulation film containing a first element for inactivating the first impurity over a first portion of the first nitride semiconductor layer situated on a first side with respect to the gate electrode in a plan view, and over a second portion of the first nitride semiconductor layer situated on the side opposite to the first side with respect to the gate electrode in a plan view;
(e) forming a second insulation film over a third portion of the first insulation film situated over the first portion, and not forming the second insulation film over a fourth portion of the first insulation film situated over the second portion;
(f) after the step (e), heat treating the substrate, and doping the first element contained in the third portion into the first portion;
(g) after the step (f), forming a third insulation film over the first insulation film in such a manner as to cover the second insulation film;
(h) forming a first hole part penetrating through the third insulation film, the second insulation film, and the first insulation film over the first portion, and forming a second hole part penetrating through the third insulation film and the first insulation film over the second portion; and
(i) forming a first electrode in the first hole part, and forming a second electrode in the second hole part,
wherein in the step (f), the first element is doped into the second portion such that the concentration of the first element in the second portion is lower than the concentration of the first element in the first portion, or, the first element is not doped.

18. The method for manufacturing a semiconductor device according to claim 17,
wherein the first insulation film contains silicon and nitrogen, and
wherein each of the second insulation film and the third insulation film contains silicon and oxygen.

19. A method for manufacturing a semiconductor device,
comprising the steps of:
(a) providing a substrate;
(b) forming a first nitride semiconductor layer containing a p type first impurity over the substrate;
(c) forming a gate electrode over the first nitride semiconductor layer, forming a first insulation film over a first portion of the first nitride semiconductor layer situated on a first side with respect to the gate electrode in a plan view, and not forming the first insulation film over a second portion of the first nitride semiconductor layer situated on the side opposite to the first side with respect to the gate electrode in a plan view;
(d) forming a second insulation film containing a first element for inactivating the first impurity over the second portion, and over the first insulation film;
(e) forming a third insulation film over a third portion of the second insulation film situated over the second portion;
(f) after the step (e), heat treating the substrate, and doping the first element contained in the third portion into the second portion;
(g) after the step (f), forming a first hole part penetrating through the third insulation film and the second insulation film over the second portion, and forming a second hole part penetrating through the second insulation film and the first insulation film over the first portion; and
(h) forming a first electrode in the first hole part, and forming a second electrode in the second hole part,
wherein in the step (f), the first element is doped into the first portion such that the concentration of the first element in the first portion is lower than the concentration of the first element in the second portion, or the first element is not doped.

20. The method for manufacturing a semiconductor device according to claim 19,
wherein the step (c) includes:
(c1) forming the first insulation film containing the first element over the first portion; and
(c2) after the step (c1), heat-treating the substrate, and reducing the concentration of the first element in the first insulation film,
wherein in the step (c2), the concentration of the first element in the first insulation film is reduced such that the concentration of the first element in the first insulation film is lower than the concentration of the first element in the second insulation film formed in the step (d).
